(19) United States
(12) Patent Application Publication
(10) Pub. No.: US 2024/0023430 A1
(43) Pub. Date: Jan. 18, 2024

(54) LIGHT EMITTING ELEMENT AND DISPLAY DEVICE INCLUDING THE SAME

(71) Applicant: Samsung Display Co., Ltd., Yongin-si (KR)

(72) Inventors: ILSOO OH, Yongin-si (KR); HYOMIN KO, Yongin-si (KR); BORA LEE, Yongin-si (KR)

(21) Appl. No.: 18/311,769

(22) Filed: May 3, 2023

(30) Foreign Application Priority Data
May 13, 2022 (KR) 10-2022-0058793
Jan. 16, 2023 (KR) 10-2023-0005959

(51) Int. Cl. H10K 85/60; H10K 50/858; H10K 59/35; C09K 11/06

(52) U.S. Cl. CPC H10K 85/633; H10K 50/858; H10K 50/15; C09K 11/06; H10K 59/35

(57) ABSTRACT

A light emitting element includes a first electrode, a hole transport region provided on the first electrode, an emission layer provided on the hole transport region, an electron transport region provided on the emission layer, and a second electrode provided on the electron transport region, wherein the hole transport region includes a first hole transport layer which is provided to be adjacent to the first electrode and includes a first amine compound represented by Formula 1, and a second hole transport layer which is provided between then first hole transport layer and the emission layer and has a larger refractive index than that of the first hole transport layer, and the first hole transport layer has a conductivity of about 6.0×10⁻⁵ cm/(V·sec) to about 10.0×10⁻⁴ cm/(V·sec).

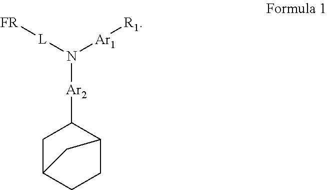

### CROSS-REFERENCE TO RELATED APPLICATIONS

This application claims priority to and the benefit of Korean Patent Application No. 10-2022-0058793, filed on May 13, 2022, and Korean Patent Application No. 10-2023-0005959, filed on Jan. 16, 2023, the entire contents of all of which are hereby incorporated by reference.

### BACKGROUND

One or more aspects of embodiments of the present disclosure herein relate to a light emitting element and a display device including the same, and more particularly, to a light emitting element containing a plurality of hole transport layers and a display device including the same.

Recently, the development of an organic electroluminescence display device as an image display device is being actively conducted. The organic electroluminescence display device includes a self-luminescent light emitting element in which holes and electrons injected from a first electrode and a second electrode recombine in an emission layer, and thus a luminescent material of the emission layer emits light to implement display of images.

In the application of a light emitting element to a display device, there is a demand (or desire) for a light emitting element having low driving voltage, high luminous efficiency, and a long service life, and development of materials for a light emitting element capable of stably or suitable attaining such characteristics is being continuously required or desired.

In addition, in order to implement a light emitting element with high luminous efficiency, studies on optimization of the structure in the light emitting element are being conducted.

### SUMMARY

One or more embodiments of the present disclosure are directed toward a light emitting element exhibiting excellent or improved luminous efficiency and a display device including the same.

One or more embodiments of the present disclosure are directed toward a light emitting element including: a first electrode; a hole transport region provided on the first electrode; an emission layer provided on the hole transport region; an electron transport region provided on the emission layer; and a second electrode provided on the electron transport region, wherein the hole transport region includes a first hole transport layer which is provided to be adjacent to the first electrode and includes a first amine compound represented by Formula 1, and a second hole transport layer which is provided between the first hole transport layer and the emission layer and has a larger refractive index than that of the first hole transport layer, and the first hole transport layer has a conductivity of about 6.0×10⁻⁵ cm/(V·sec) to about 10.0×10⁻⁴ cm/(V·sec):

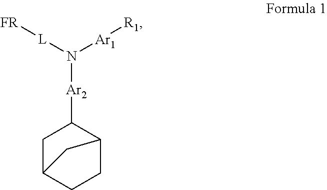

wherein, in Formula 1,
R₁ is a substituted or unsubstituted cycloalkyl group having 6 to 12 ring-forming carbon atoms, Ar₁ and Ar₂ are each independently a substituted or unsubstituted arylene group having 6 to 30 ring-forming carbon atoms or a substituted or unsubstituted heteroarylene group having 2 to 30 ring-forming carbon atoms, L is a direct linkage, a substituted or unsubstituted arylene group having 6 to 30 ring-forming carbon atoms, or a substituted or unsubstituted heteroarylene group having 2 to 30 ring-forming carbon atoms, and FR is represented by Formula 2-1 or Formula 2-2:

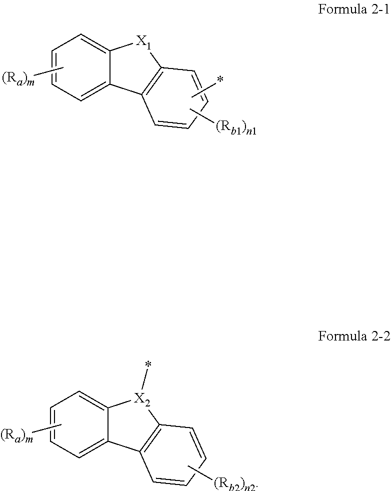

In Formula 2-1 and Formula 2-2,
X₁ is CR_{c}R_{d}, NRₑ, O, or S, X₂ is CR_{f} or N, Rₐ, R_{b1}, R_{b2}, and R_{c} to R_{f} are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, and/or are bonded to an adjacent group to form a ring, m is an integer of 0 to 4, n1 is an integer of 0 to 3, and n2 is an integer of 0 to 4, and in Formula 2-1 and Formula 2-2, “-*” means a position (e.g., site) linked to L in Formula 1.

In one or more embodiments, the first hole transport layer may have a refractive index of about 1.4 to about 1.75.

In one or more embodiments, the second hole transport layer may have a refractive index of about 1.8 to about 2.0.

In one or more embodiments, the light emitting element may further include a third hole transport layer which is provided between the second hole transport layer and the emission layer, and includes a second amine compound represented by Formula 1.

In one or more embodiments, the third hole transport layer may have a refractive index of about 1.4 to about 1.75.

In one or more embodiments, the hole transport region may further include a fourth hole transport layer which is provided between the first hole transport layer and the second hole transport layer, or between the second hole transport layer and the third hole transport layer, or both between the first hole transport layer and the second hole transport layer and between the second hole transport layer and the third hole transport layer, and includes a third amine compound represented by Formula 1.

In one or more embodiments, the refractive index of the fourth hole transport layer may be larger than that of the first hole transport layer and smaller than that of the second hole transport layer.

In one or more embodiments, at least one among the first hole transport layer to the fourth hole transport layer may further include a compound represented by Formula H-1:

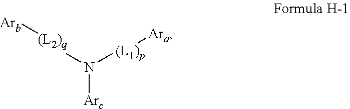

wherein, in Formula H-1,
Arₐ and Ar_{b} are each independently a substituted or unsubstituted aryl group having 6 to 30 ring-forming carbon atoms, or a substituted or unsubstituted heteroaryl group having 2 to 30 ring-forming carbon atoms, Ar_{c} is a substituted or unsubstituted aryl group having 6 to 30 ring-forming carbon atoms, L₁ and L₂ are each independently a direct linkage, a substituted or unsubstituted arylene group having 6 to 30 ring-forming carbon atoms, or a substituted or unsubstituted heteroarylene group having 2 to 30 ring-forming carbon atoms, and p and q are each independently an integer of 0 to 10.

In one or more embodiments, the light emitting element may further include a fourth hole transport layer which is provided between the first hole transport layer and the second hole transport layer or between the second hole transport layer and the emission layer, or both between the first hole transport layer and the second hole transport layer and between the second hole transport layer and the emission layer, and includes a third amine compound represented by Formula 1.

In one or more embodiments, the refractive index of the fourth hole transport layer may be larger than that of the first hole transport layer and smaller than that of the second hole transport layer.

In one or more embodiments, the first hole transport layer may be doped with a p-dopant in an amount of about 1% to about 3%, and the p-dopant may include at least one of a halogenated metal compound, a quinone derivative, a tungsten oxide, a metal oxide, or a cyano group-containing compound.

In one or more embodiments, the first amine compound represented by Formula 1 may be represented by any one among Formula 1-1 to Formula 1-5:

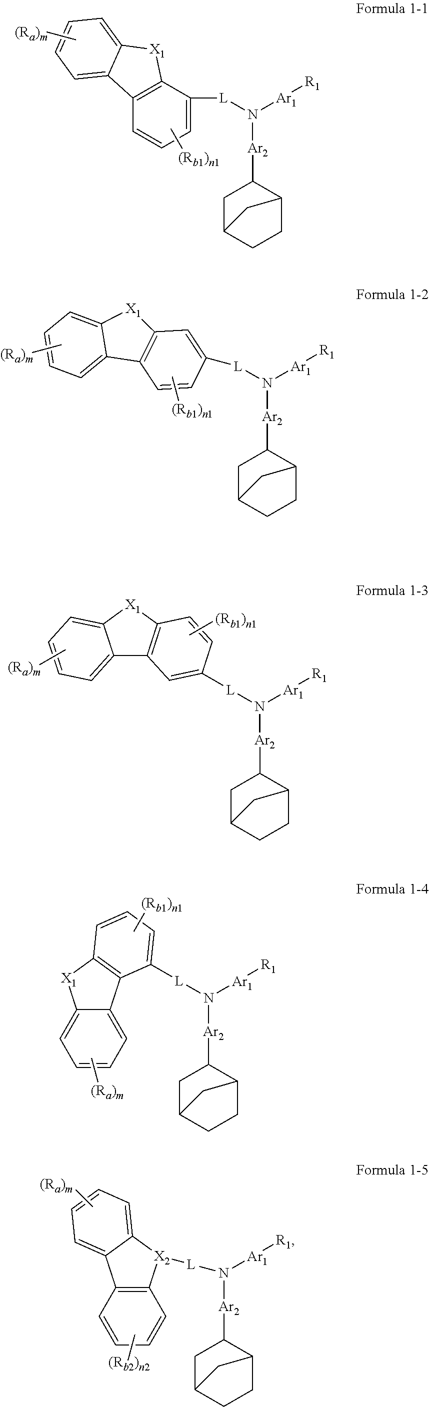

wherein, in Formula 1-1 to Formula 1-5, R₁, L, Ar₁, and Ar₂ are the same as defined in Formula 1, and X₁, X₂, Rₐ, R_{b1}, R_{b2}, m, n1, and n2 are the same as defined in Formula 2-1 and Formula 2-2.

In one or more embodiments, the first amine compound represented by Formula 1 may be represented by Formula 3:

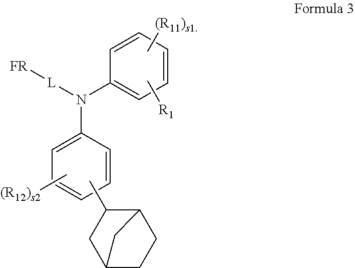

In Formula 3,
R₁₁ and R₁₂ are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and s1 and s2 are each independently an integer of 0 to 4, and R₁, L, and FR are the same as defined in Formula 1.

In one or more embodiments, R₁ may be a substituted or unsubstituted cyclohexyl group, a substituted or unsubstituted bicycloheptyl group, a substituted or unsubstituted bicyclooctyl group, a substituted or unsubstituted bicyclononyl group, or a substituted or unsubstituted adamantyl group.

In one or more embodiments, R_{c} and R_{d} may be each independently a substituted or unsubstituted methyl group, a substituted or unsubstituted heptyl group, a substituted or unsubstituted cyclohexyl group, a substituted or unsubstituted phenyl group, and/or may be bonded to each other to form a cyclopentane or fluorene ring.

In one or more embodiments, R_{f} may be a substituted or unsubstituted aryl group having 6 to 30 ring-forming carbon atoms.

In one or more embodiments of the present disclosure, a light emitting element includes: a first electrode; a hole transport region provided on the first electrode; an emission layer provided on the hole transport region; an electron transport region provided on the emission layer; and a second electrode provided on the electron transport region, wherein the hole transport region includes a first hole transport layer which is provided to be adjacent to the first electrode, includes a first amine compound represented by Formula 1, and has a refractive index of about 1.4 to about 1.75, and the first hole transport layer has a conductivity of about 6.0×10⁻⁵ cm/(V·sec) to about 10.0×10⁻⁴ cm/(V·sec):

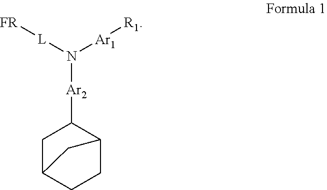

In Formula 1,
R₁ is a substituted or unsubstituted cycloalkyl group having 6 to 12 ring-forming carbon atoms, Ar₁ and Ar₂ are each independently a substituted or unsubstituted arylene group having 6 to 30 ring-forming carbon atoms or a substituted or unsubstituted heteroarylene group having 2 to 30 ring-forming carbon atoms, L is a direct linkage, a substituted or unsubstituted arylene group having 6 to 30 ring-forming carbon atoms, or a substituted or unsubstituted heteroarylene group having 2 to 30 ring-forming carbon atoms, and FR is represented by Formula 2-1 or Formula 2-2:

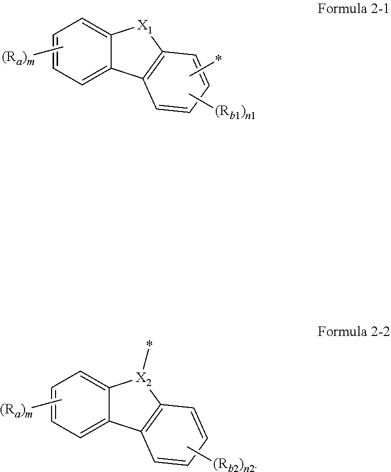

In Formula 2-1 and Formula 2-2,
X₁ is CR_{c}R_{d}, NRₑ, O, or S, X₂ is CR_{f} or N, Rₐ, R_{b1}, R_{b2}, and R_{c} to R_{f} are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, and/or are bonded to an adjacent group to form a ring, m is an integer of 0 to 4, n1 is an integer of 0 to 3, and n2 is an integer of 0 to 4, and in Formula 2-1 and Formula 2-2, “-*” means a position (e.g., site) linked to L in Formula 1.

In one or more embodiments of the present disclosure, a display device includes a plurality of light emitting elements, wherein each of the light emitting elements includes: a first electrode; a hole transport region provided on the first electrode; an emission layer provided on the hole transport region; an electron transport region provided on the emission layer; and a second electrode provided on the electron transport region, and the hole transport region includes a first hole transport layer which is provided to be adjacent to the first electrode and includes a first amine compound represented by Formula 1, and a second hole transport layer which is provided between then first hole transport layer and the emission layer and has a refractive index larger than that of the first hole transport layer, and the first hole transport layer has a conductivity of about 6.0×10⁻⁵ cm/(V·sec) to about 10.0×10⁻⁴ cm/(V·sec):

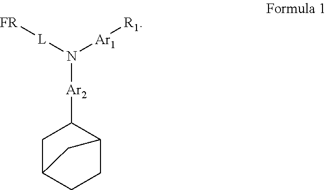

In Formula 1, R₁ is a substituted or unsubstituted cycloalkyl group having 6 to 12 ring-forming carbon atoms, Ar₁ and Ar₂ are each independently a substituted or unsubstituted arylene group having 6 to 30 ring-forming carbon atoms, or a substituted or unsubstituted heteroarylene group having 2 to 30 ring-forming carbon atoms, L is a direct linkage, a substituted or unsubstituted arylene group having 6 to 30 ring-forming carbon atoms, or a substituted or unsubstituted heteroarylene group having 2 to 30 ring-forming carbon atoms, and FR is represented by Formula 2-1 or Formula 2-2:

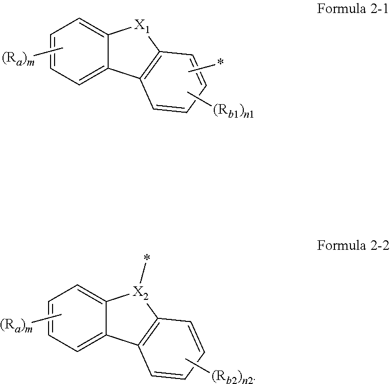

In Formula 2-1 and Formula 2-2,
X₁ is CR_{c}R_{d}, NRₑ, O, or S, X₂ is CR_{f} or N, Rₐ, R_{b1}, R_{b2}, and R_{c} to R_{f} are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, and/or are bonded to an adjacent group to form a ring, m is an integer of 0 to 4, n1 is an integer of 0 to 3, and n2 is an integer of 0 to 4, and in Formula 2-1 and Formula 2-2, “-*” means a position (e.g., site) linked to L in Formula 1.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view illustrating a display device according to one or more embodiments of the present disclosure;

FIG. 2 is a cross-sectional view of a display device according to one or more embodiments of the present disclosure;

FIG. 3 is a cross-sectional view schematically illustrating a light emitting element according to one or more embodiments of the present disclosure;

FIG. 4 is a cross-sectional view schematically illustrating a light emitting element according to one or more embodiments of the present disclosure;

FIG. 5 is a cross-sectional view schematically illustrating a light emitting element according to one or more embodiments of the present disclosure;

FIG. 6 is a cross-sectional view schematically illustrating a light emitting element according to one or more embodiments of the present disclosure;

FIG. 7 is a cross-sectional view schematically illustrating a light emitting element according to one or more embodiments of the present disclosure;

FIG. 8 is a cross-sectional view schematically illustrating a light emitting element according to one or more embodiments of the present disclosure;

FIG. 9 is a cross-sectional view schematically illustrating a light emitting element according to one or more embodiments of the present disclosure;

FIG. 10 is a cross-sectional view of a display device according to one or more embodiments of the present disclosure;

FIG. 11 is a cross-sectional view of a display element layer according to one or more embodiments of the present disclosure;

FIG. 12 is a cross-sectional view of a display device according to one or more embodiments of the present disclosure;

FIGS. 13A, 13B, and 13C are graphs each showing luminous efficiency versus color coordinate; and

FIG. 14 is a graph showing brightnesses of R, G, and B of each light emitting element of Comparative Example and Example.

### DETAILED DESCRIPTION

The present disclosure may be modified in many alternate forms, and thus specific embodiments will be exemplified in the drawings and described in more detail herein below. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are used for referring to like elements. In the accompanying drawings, the dimensions of each structure are exaggeratingly illustrated for clarity of the present disclosure. It will be understood that, although the terms “first,” “second,” etc., may be used herein to describe various components, these components should not be limited by these terms. These terms are only used to distinguish one element from another. For example, a first element could be termed a second element, and, similarly, a second element could be termed a first element, without departing from the scope of example embodiments of the present disclosure. The terms of a singular form may include plural forms unless the context clearly indicates otherwise.

In the present specification, it will be understood that the terms “comprise”, “include,” or “have” specify the presence of a feature, a fixed number, a step, an operation, a component, a part, or a combination thereof disclosed in the specification, but do not exclude the possibility of presence or addition of one or more other features, fixed numbers, steps, operations, components, parts, or combination thereof.

In the present specification, when a layer, a film, a region, or a plate is referred to as being “above” or “in an upper portion of” another layer, film, region, or plate, it can be not only directly on the layer, film, region, or plate (e.g., without any intervening layers, films, regions, or plates therebetween), but one or more intervening layers, films, regions, or plates may also be present. Similarly, when a part such as a layer, a film, a region, or a plate is referred to as being “under” or “on a lower portion of” another part, it can be not only “directly under” the another part (e.g., without any intervening parts therebetween), but one or more intervening parts may also be present. In addition, in the specification, it will be understood that when a part is referred to as being provided “on” another part, it may be provided on an upper portion of the another part, or provided on a lower portion of the another part as well.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the specification, the term “substituted or unsubstituted” may mean a group that is unsubstituted or that is substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, a heterocyclic group, and combinations thereof. In addition, each of the substituents exemplified may itself be substituted or unsubstituted. For example, a biphenyl group may be interpreted as an aryl group or a phenyl group substituted with a phenyl group.

In the specification, the phrase “bonded to an adjacent group to form a ring” may mean that one is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by being bonded to each other may be connected to another ring to form a spiro structure.

In the specification, the term “adjacent group” may refer to a pair of substituent groups where the first substituent is connected to an atom which is directly connected to another atom substituted with the second substituent; a pair of substituent groups connected to the same atom; or a pair of substituent groups where the first substituent is sterically positioned at the nearest position to the second substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the specification, examples of the halogen atom may include a fluorine atom, a chlorine atom, a bromine atom, and an iodine atom.

In the specification, the alkyl group may be a linear, branched or cyclic alkyl group. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiments of the present disclosure are not limited thereto.

In the specification, the hydrocarbon ring group means any functional group or substituent derived from an aliphatic hydrocarbon ring. The hydrocarbon ring group may be a saturated hydrocarbon ring group having 5 to 20 ring-forming carbon atoms.

In the specification, an aryl group means any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiments of the present disclosure are not limited thereto.

In the specification, the fluorenyl group may be substituted, and two substituents may be bonded to each other to form a spiro structure. Examples of the substituted fluorenyl group are as follows. However, the embodiments of the present disclosure are not limited thereto.

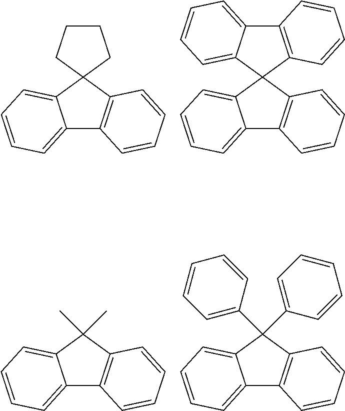

The heterocyclic group herein means any functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. If the heterocyclic group contains two or more heteroatoms, the two or more heteroatoms may be the same or different. The heterocyclic group may be a monocyclic heterocyclic group or a polycyclic heterocyclic group and has the concept including a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the embodiments of the present disclosure are not limited thereto.

In the specification, the heteroaryl group may include at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a triazole group, a pyridine group, a bipyridine group, a pyrimidine group, a triazine group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiments of the present disclosure are not limited thereto.

In the specification, the above description of the aryl group may be applied to an arylene group except that the arylene group is a divalent group. Moreover, the above description of the aryl group may be applied to other suitable polyvalent aryl group(s). The above description of the heteroaryl group may be applied to a heteroarylene group except that the heteroarylene group is a divalent group. Moreover, the above description of the heteroaryl group may be applied to other suitable polyvalent heteroaryl group(s).

In the specification, the silyl group may include an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but the embodiments of the present disclosure are not limited thereto.

In the specification, the thio group may include an alkylthio group and an arylthio group. The thio group may mean that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiments of the present disclosure are not limited thereto.

In the specification, an oxy group may mean that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but the embodiments of the present disclosure are not limited thereto.

In the specification, the alkenyl group may be a linear chain or a branched chain. The number of carbon atoms in the alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but the embodiments of the present disclosure are not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but the embodiments of the present disclosure are not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described above.

In the specification, the aryl group among an aryloxy group, an arylthio group, an arylsulfoxy group, an arylamino group, an arylboron group, an arylsilyl group, an arylamine group is the same as the examples of the aryl group described above.

In the specification, a direct linkage may mean a chemical bond (e.g., a single bond).

Meanwhile, in the specification, “ [symbol] ” and “-*” mean a position to be connected (e.g., a binding site).

Hereinafter, embodiments of the present disclosure will be described with reference to the accompanying drawings.

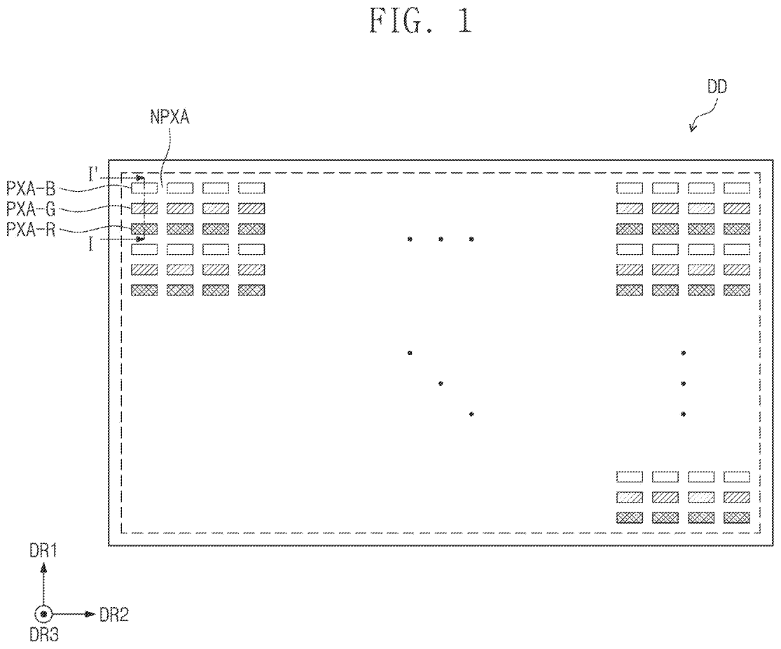

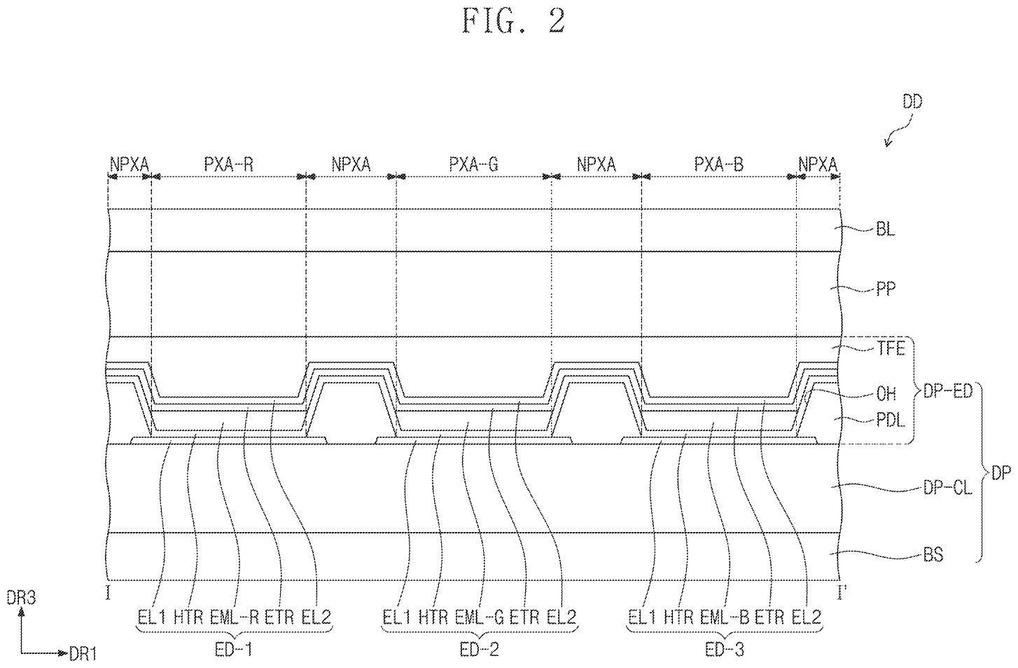

FIG. 1 is a plan view illustrating one or more embodiments of a display device DD. FIG. 2 is a cross-sectional view of the display device DD of one or more embodiments. FIG. 2 is a cross-sectional view illustrating a part taken along line I-I′ of FIG. 1.

The display device DD may include a display panel DP and an optical layer PP provided on the display panel DP. The display panel DP includes light emitting elements ED-1, ED-2, and ED-3. The display device DD may include a plurality of light emitting elements ED-1, ED-2, and ED-3.

The optical layer PP may be provided on the display panel DP to control (e.g., adjust) reflected light in the display panel DP due to external light. The optical layer PP may include, for example, a polarization layer and/or a color filter layer. In some embodiments, the optical layer PP may be omitted (e.g., may not be provided) from the display device DD of one or more embodiments.

A base substrate BL may be provided on the optical layer PP. The base substrate BL may be a member which provides a base surface on which the optical layer PP provided. The base substrate BL may be a glass substrate, a metal substrate, a plastic substrate, etc. However, one or more embodiments of the present disclosure is not limited thereto, and the base substrate BL may be an inorganic layer, an organic layer, or a composite material layer (e.g., including an organic material and an inorganic material). In one or more embodiments, the base substrate BL may be omitted (e.g., may not be provided).

The display device DD according to one or more embodiments may further include a filling layer. The filling layer may be provided between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 provided between portions of the pixel defining film PDL, and an encapsulation layer TFE provided on the light emitting elements ED-1, ED-2, and ED-3.

The base layer BS may be a member which provides a base surface on which the display element layer DP-ED is provided. The base layer BS may be a glass substrate, a metal substrate, a plastic substrate, etc. However, the embodiments are not limited thereto, and the base layer BS may be an inorganic layer, an organic layer, or a composite material layer.

In one or more embodiments, the circuit layer DP-CL is provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display element layer DP-ED.

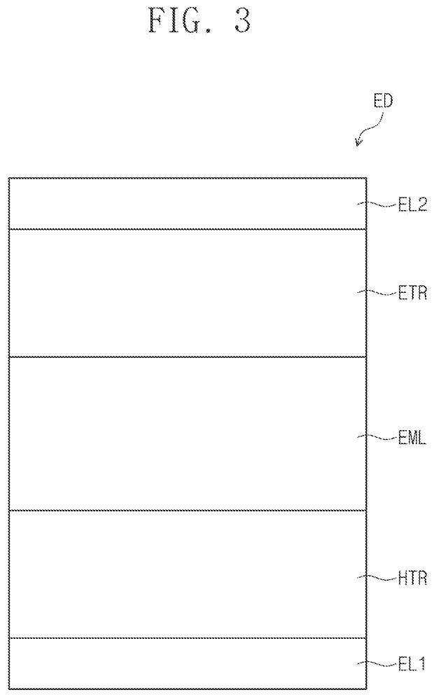

Each of the light emitting elements ED-1, ED-2, and ED-3 may have a structure of a light emitting element ED of one or more embodiments according to FIGS. 3 to 9, which will be described in more detail herein below. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates one or more embodiments in which the emission layers EML-R, EML-G, and EML-B of the light emitting elements ED-1, ED-2, and ED-3 are provided in openings OH defined in the pixel defining film PDL, and the hole transport region HTR, the electron transport region ETR, and the second electrode EL2 are provided as a common layer in the entire light emitting elements ED-1, ED-2, and ED-3. However, the embodiments of the present disclosure are not limited thereto, and in some embodiments, the hole transport region HTR and the electron transport region ETR may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in one or more embodiments may be provided by being patterned in an inkjet printing method.

The encapsulation layer TFE may cover the light emitting elements ED-1, ED-2 and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display element layer DP-ED from moisture/oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, and/or the like, but the embodiments of the present disclosure are not particularly limited thereto. The encapsulation-organic film may include an acrylic-based compound, an epoxy-based compound, or the like. The encapsulation-organic film may include a photopolymerizable organic material, but one or more embodiments of the present disclosure is not particularly limited thereto.

The encapsulation layer TFE may be provided on the second electrode EL2 and may be provided filling the opening OH.

Referring to FIGS. 1 and 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced apart from each other on a plane (e.g., in a plan view).

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In the specification, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3, respectively, may be provided in openings OH defined in the pixel defining film PDL and separated from each other.

The light emitting regions PXA-R, PXA-G, and PXA-B may be divided into a plurality of groups according to the color of light generated from the light emitting elements ED-1, ED-2, and ED-3. In the display device DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display device DD according to one or more embodiments, the plurality of light emitting elements ED-1, ED-2 and ED-3 may emit light beams having wavelengths different from each other. For example, in one or more embodiments, the display device DD may include a first light emitting element ED-1 that emits (e.g., is configured to emit) red light, a second light emitting element ED-2 that emits (e.g., is configured to emit) green light, and a third light emitting element ED-3 that emits (e.g., is configured to emit) blue light. The red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, one or more embodiments of the present disclosure is not limited thereto, and the first to third light emitting elements ED-1, ED-2, and ED-3 may emit light beams in the same wavelength range or at least one light emitting element may emit a light beam in a wavelength range different from the others. For example, the first to third light emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, the plurality of red light emitting regions PXA-R may be arranged with each other along the second direction DR2, the plurality of green light emitting regions PXA-G may be arranged with each other along the second direction DR2, and the plurality of blue light emitting regions PXA-B each may be arranged with each other along the second direction DR2. In addition, the red light emitting region PXA-R, the green light emitting region PXA-G, and the blue light emitting region PXA-B may be alternately arranged with each other in this order along the first direction DR1.

FIGS. 1 and 2 illustrate that all the light emitting regions PXA-R, PXA-G, and PXA-B have similar area, but one or more embodiments of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may mean areas when viewed in a plane defined by the first direction DR1 and the second direction DR2.

An arrangement form of the light emitting regions PXA-R, PXA-G, and PXA-B is not limited to the feature illustrated in FIG. 1, and the order in which the red light emitting region PXA-R, the green light emitting region PXA-G, and the blue light emitting region PXA-B are arranged may be provided in various suitable combinations according to the characteristics of display quality required (or desired) in the display device DD. For example, the arrangement form of the light emitting regions PXA-R, PXA-G, and PXA-B may be a pentile (PENTILE®) arrangement form (PENTILE® is a registered trademark owned by Samsung Display Co., Ltd.) or a diamond (Diamond Pixel™) arrangement form.

In addition, the areas of the light emitting regions PXA-R, PXA-G, and PXA-B may be different from each other. For example, in one or more embodiments, the area of the green light emitting region PXA-G may be smaller than that of the blue light emitting region PXA-B, but one or more embodiments of the present disclosure is not limited thereto.

Hereinafter, FIGS. 3 to 9 are cross-sectional views schematically illustrating light emitting elements according to embodiments. The light emitting elements ED according to embodiments each may include a first electrode EL1, a second electrode EL2 facing the first electrode EL1, and at least one functional layer provided between the first electrode EL1 and the second electrode EL2. The at least one functional layer may include a hole transport region HTR, an emission layer EML, and an electron transport region ETR that are sequentially stacked. For example, each of the light emitting elements ED of embodiments may include the first electrode EL1, the hole transport region HTR, the emission layer EML, the electron transport region ETR, and the second electrode EL2 that are sequentially stacked.

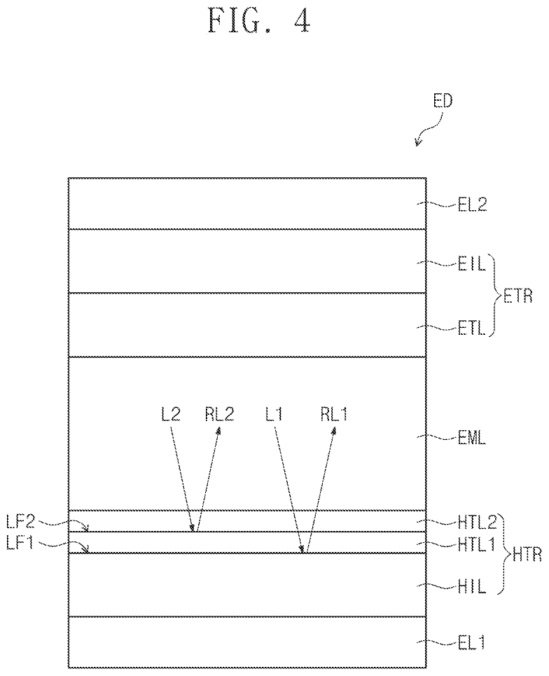

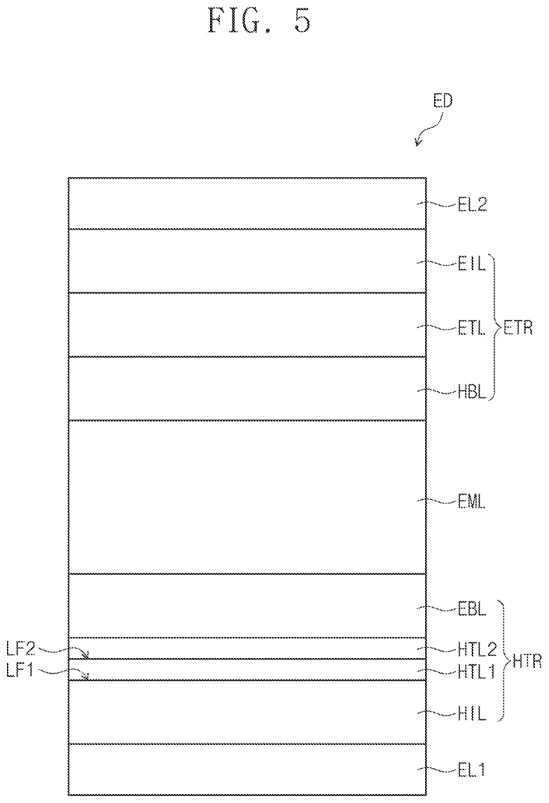

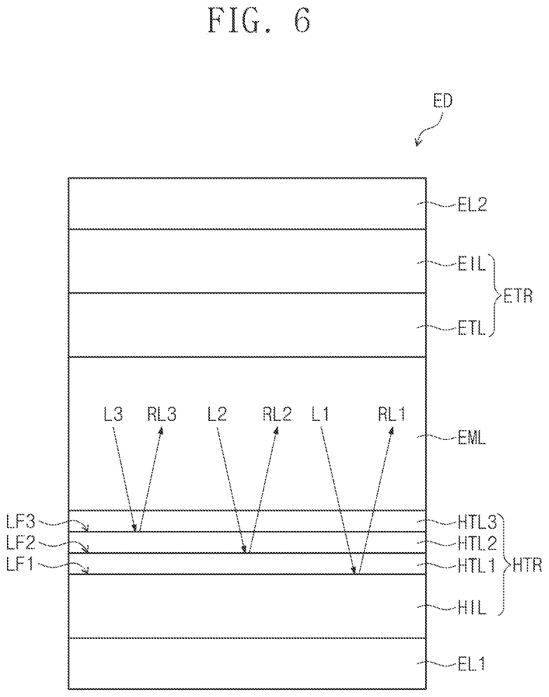

Compared with FIG. 3, FIG. 4 illustrates a cross-sectional view of a light emitting element ED of one or more embodiments, in which a hole transport region HTR includes a hole injection layer HIL, a first hole transport layer HTL1, and a second hole transport layer HTL2, and an electron transport region ETR includes an electron injection layer EIL and an electron transport layer ETL. In addition, compared with FIG. 3, FIG. 5 illustrates a cross-sectional view of a light emitting element ED of one or more embodiments, in which a hole transport region HTR includes a hole injection layer HIL, a first hole transport layer HTL1, a second hole transport layer HTL2, and an electron blocking layer EBL, and an electron transport region ETR includes an electron injection layer EIL, an electron transport layer ETL, and a hole blocking layer HBL. Compared with FIG. 3, FIG. 6 illustrates a cross-sectional view of a light emitting element ED of one or more embodiments, in which a hole transport region HTR includes a hole injection layer HIL, a first hole transport layer HTL1, a second hole transport layer HTL2, and a third hole transport layer HTL3, and an electron transport region ETR includes an electron injection layer EIL and an electron transport layer ETL.

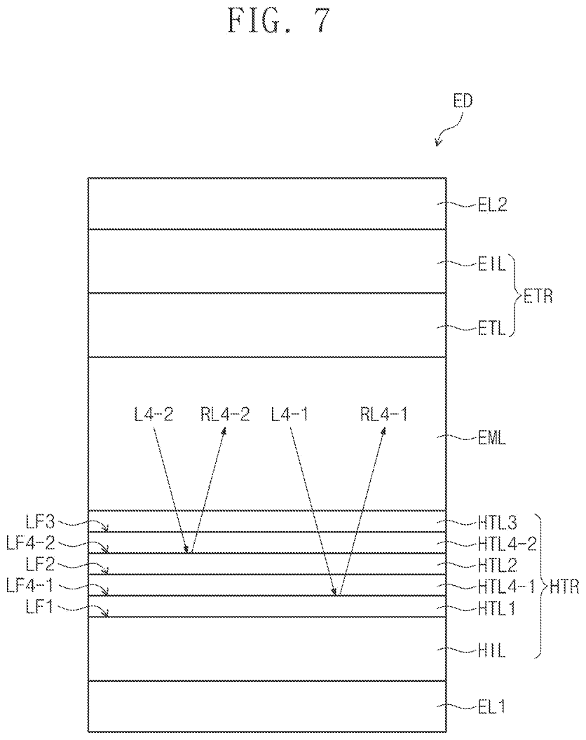

Compared with FIG. 3, FIG. 7 illustrates a cross-sectional view of a light emitting element ED of one or more embodiments, in which a hole transport region HTR includes a hole injection layer HIL, a first hole transport layer HTL1, a second hole transport layer HTL2, a third hole transport layer HTL3, a 4-1 st hole transport layer HTL4-1, and a 4-2nd hole transport layer HTL4-2, and an electron transport region ETR includes an electron injection layer EIL and an electron transport layer ETL.

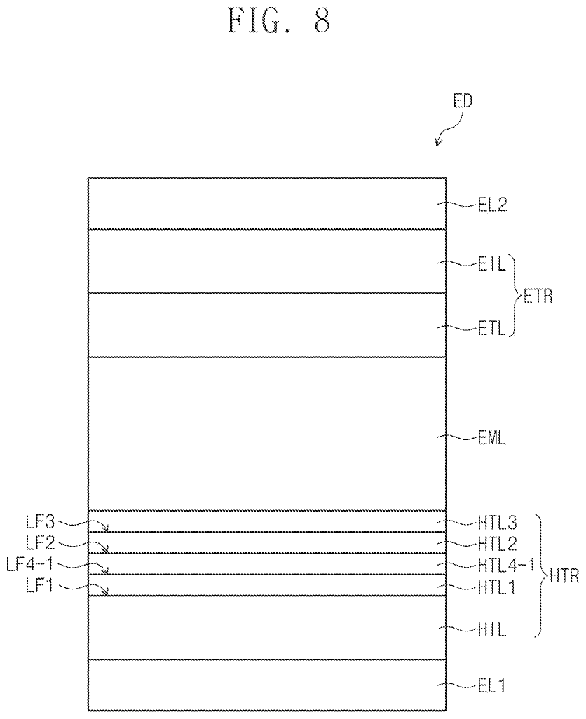

Compared with FIG. 3, FIG. 8 illustrates a cross-sectional view of a light emitting element ED of one or more embodiments, in which a hole transport region HTR includes a hole injection layer HIL, a first hole transport layer HTL1, a second hole transport layer HTL2, a third hole transport layer HTL3, and a 4-1 st hole transport layer HTL4-1, and an electron transport region ETR includes an electron injection layer EIL and an electron transport layer ETL. In some embodiments, the third hole transport layer HTL3 may be omitted (e.g., may not be provided).

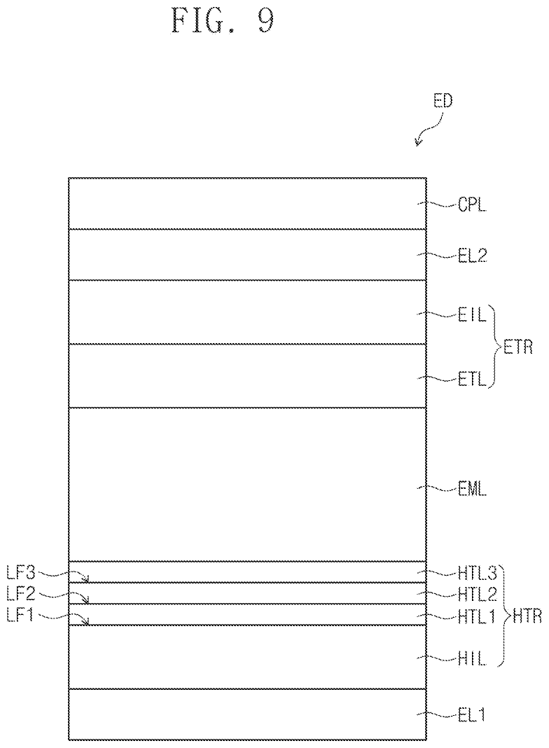

Compared with FIG. 6, FIG. 9 illustrates a cross-sectional view of a light emitting element ED of one or more embodiments including a capping layer CPL provided on a second electrode EL2.

The light emitting element ED of one or more embodiments may include a first amine compound to a third amine compound, which will be described in more detail herein below, of one or more embodiments in the hole transport region HTR.

In the light emitting element ED according to one or more embodiments, the first electrode EL1 has conductivity. The first electrode EL1 may be formed of a metal material, a metal alloy, and/or a conductive compound. The first electrode EL1 may be an anode or a cathode. However, one or more embodiments of the present disclosure is not limited thereto. In some embodiments, the first electrode EL1 may be a pixel electrode. The first electrode EL1 may be a transmissive electrode, a transflective electrode, or a reflective electrode. When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, W, a compound thereof, or a mixture thereof (e.g., a mixture of Ag and Mg). In one or more embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but one or more embodiments of the present disclosure is not limited thereto. However, one or more embodiments of the present disclosure is not limited thereto, and the first electrode EL1 may include any of the above-described metal materials, combinations of at least two metal materials of the above-described metal materials, oxides of any of the above-described metal materials, and/or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include a first hole transport layer HTL1, a second hole transport layer HTL2, and a third hole transport layer HTL3.

The hole transport region HTR may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

FIGS. 4 to 9 illustrate that the hole transport region HTR includes the hole injection layer HIL and the plurality of hole transport layers HTL1, HTL2, HTL3, and HTL4, but the hole transport region HTR may have the plurality of hole transport layers HTL1, HTL2, HTL3, and HTL4 directly provided on the first electrode EL1, without the hole injection layer HIL. For example, any one selected from the plurality of hole transport layers HTL1, HTL2, HTL3, and HTL4 may serve as a hole injection layer. In some embodiments, the hole transport region HTR may further include a structure in which a buffer layer is provided on an upper portion of the plurality of hole transport layers HTL1, HTL2, HTL3, and HTL4.

The hole transport region HTR of the present disclosure includes the first hole transport layer HTL1 provided on the first electrode EL1. The first hole transport layer HTL1 is provided to be adjacent to the first electrode EL1. For example, the first hole transport layer HTL1 may be in contact with the first electrode EL1, and provided on the first electrode EL1.

The first hole transport layer HTL1 may include the first amine compound represented by Formula 1, which will be described in more detail herein below. The first hole transport layer HTL1 may include the first amine compound, thereby exhibiting low or suitable refractive index and excellent or suitable conductivity. The refractive index of the first hole transport layer HTL1 (hereinafter, a first refractive index) may be about 1.4 to about 1.75. For example, the first refractive index may be about 1.5 to about 1.75, and for example, may be about 1.7. The conductivity of the first hole transport layer HTL1 may be about 6.0×10⁻⁵ cm/(V·s) to about 10.0×10⁻⁴ cm/(V·s). For example, the conductivity of the first hole transport layer HTL1 may be about 6.0×10⁻⁵ cm/(V·s) to about 9.0×10⁻⁴ cm/(V·s).

The first hole transport layer HTL1 may further include a charge generating material. The first hole transport layer HTL1 is provided to be adjacent to the first electrode EL1, includes the charge generating material, and thus may serve as a hole injection layer. In this case, the first hole transport layer HTL1 may be provided to be in contact with the first electrode EL1.

The charge generating material may be, for example, a p-dopant. In one or more embodiments, the first hole transport layer HTL1 may be doped with the p-dopant in an amount of about 1% to about 3%. For example, the first hole transport layer HTL1 may be doped with the p-dopant in an amount of about 1% to about 2%.

The p-dopant may include at least one of a halogenated metal compound, a quinone derivative, a tungsten oxide, a metal oxide, or a cyano group-containing compound. For example, the p-dopant may include a halogenated metal compound such as CuI and/or RbI, a quinone derivative such as tetracyanoquinodimethane (TCNQ) and/or 2,3,5,6-tetrafluoro-7,7′8,8-tetracyanoquinodimethane (F4-TCNQ), a metal oxide such as a tungsten oxide and/or a molybdenum oxide, and/or a cyano group-containing compound such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9).

In one or more embodiments, the p-dopant may be NDP9. In one or more embodiments, the first hole transport layer HTL1 may be doped with NDP9 by about 1% to about 3%. However, one or more embodiments of the present disclosure is not limited thereto.

The first hole transport layer HTL1 may further contain a hole transport material represented by Formula H-1, which will be described in more detail herein below.

The hole transport region HTR of the present disclosure further includes the second hole transport layer HTL2 provided on the first hole transport layer HTL1.

The second hole transport layer HTL2 is provided between the first hole transport layer HTL1 and the emission layer EML. The refractive index of the second hole transport layer HTL2 (hereinafter, a second refractive index) is larger than the first refractive index. The second refractive index is about 1.8 to about 2.0. For example, the second refractive index may be about 1.9.

The second hole transport layer HTL2 may include the hole transport material represented by Formula H-1, which will be described in more detail herein below, and have excellent or suitable hole mobility.

The hole transport region HTR of the present disclosure may further include the third hole transport layer HTL3. The third hole transport layer HTL3 may be provided between the second hole transport layer HTL2 and the emission layer EML. The third hole transport layer HTL3 may include the second amine compound represented by Formula 1, which will be described in more detail herein below, thereby exhibiting a conductivity of about 6.0×10⁻⁵ cm/(V·s) to about 10.0×10⁻⁴ cm/(V·s). The second amine compound may be the same as the first amine compound. However, one or more embodiments of the present disclosure is not limited thereto, and the first amine compound and the second amine compound may be different.

The third hole transport layer HTL3 may further include the hole transport material represented by Formula H-1, which will be described in more detail herein below.

The refractive index of the third hole transport layer HTL3 (hereinafter, a third refractive index) may be smaller than the second refractive index. The third refractive index may be about 1.4 to about 1.75. For example, the refractive index of the third hole transport layer may be about 1.7. The electron blocking layer EBL may be further provided between the third hole transport layer HTL3 and the emission layer EML.

The light emitting element ED of one or more embodiments may include the first electrode EL1, the first hole transport layer HTL1 provided on the first electrode EL1, the second hole transport layer HTL2 provided on the first hole transport layer HTL1, the third hole transport layer HTL3 provided on the second hole transport layer HTL2, the emission layer EML provided on the third hole transport layer HTL3, the electron transport region ETR provided on the emission layer EML, and the second electrode EL2.

However, one or more embodiments of the present disclosure is not limited thereto, and the light emitting element ED of one or more embodiments may not include the third hole transport layer HTL3.

The hole transport region HTR of one or more embodiments may further include a fourth hole transport layer HTL4.

The fourth hole transport layer HTL4 may include the third amine compound represented by Formula 1, which will be described in more detail herein below, thereby exhibiting a conductivity of about 6.0×10⁻⁵ cm/(V·s) to about 10.0×10⁻⁴ cm/(V·s). The third amine compound may be the same as the first amine compound. The first amine compound to the third amine compound may all be the same. However, one or more embodiments of the present disclosure is not limited thereto, and at least one selected from the first amine compound to the third amine compound may be different from the others.

The fourth hole transport layer HTL4 may further include the hole transport material represented by Formula H-1, which will be described in more detail herein below.

The refractive index of the fourth hole transport layer HTL4 (hereinafter, a fourth refractive index) may be larger than the first refractive index and smaller than the second refractive index.

The fourth hole transport layer HTL4 may be provided on at least one of the upper portion or lower portion of the second hole transport layer HTL2. For example, the fourth hole transport layer HTL4 may be provided between the first hole transport layer HTL1 and the second hole transport layer HTL2, or between the second hole transport layer HTL2 and the emission layer EML, or both between the first hole transport layer HTL1 and the second hole transport layer HTL2 and between the second hole transport layer HTL2 and the emission layer EML.

At least one fourth hole transport layer HTL4 may be provided, and for example, one or two fourth hole transport layers HTL4 may be provided. The fourth hole transport layer HTL4 of one or more embodiments may include a 4-1 st hole transport layer HTL4-1 and a 4-2nd hole transport layer HTL4-2.

For example, the hole transport region HTR of one or more embodiments may include the first hole transport layer HTL1, the 4-1st hole transport layer HTL4-1, and the second hole transport layer HTL2 which are sequentially stacked on the first electrode EL1.

When the hole transport region HTR includes the third hole transport layer HTL3, the fourth hole transport layer HTL4 may be provided between the first the first hole transport layer HTL1 and the second hole transport layer HTL2, or between the second hole transport layer HTL2 and the third hole transport layer HTL3, or both between the first hole transport layer HTL1 and the second hole transport layer HTL2 and between the second hole transport layer HTL2 and the third hole transport layer HTL3. For example, the hole transport region HTR of one or more embodiments may include the first hole transport layer HTL1, the 4-1 st hole transport layer HTL4-1, the second hole transport layer HTL2, the 4-2nd hole transport layer HTL4-2, and the third hole transport layer HTL3 which are sequentially stacked on the first electrode EL1.

The light emitting element ED of one or more embodiments includes the plurality of hole transport layers HTL1, HTL2, HTL3, and HTL4, and thus the constructive interference of light may occur to increase light extraction efficiency.

For example, referring to FIG. 4, part of first incident light L1, which passes through the second hole transport layer HTL2 from the emission layer EML to enter towards the first hole transport layer HTL1, may be reflected at a first interface LF1 towards the emission layer EML. Part of second incident light L2, which enters from the emission layer EML towards the second hole transport layer HTL2, may be reflected at a second interface LF2 towards the emission layer EML. In the light emitting element ED of one or more embodiments, the constructive interference may occur between first reflected light RL1 reflected at the first interface LF1 and second reflected light RL2 reflected at the second interface LF2. Accordingly, the light emitting element ED of one or more embodiments may exhibit high external light extraction efficiency.

Referring to FIG. 6, part of the first incident light L1, which passes through the third hole transport layer HTL3 and the second hole transport layer HTL2 from the emission layer EML to enter towards the first hole transport layer HTL1, may be reflected at the first interface LF1 towards the emission layer EML. Part of the second incident light L2, which passes through the third hole transport layer HTL3 from the emission layer EML to enter towards the second hole transport layer HTL2, may be reflected at the second interface LF2 towards the emission layer EML. Part of third incident light L3, which enters from the emission layer EML towards the second hole transport layer HTL3 may be reflected at a third interface LF3 towards the emission layer EML.

In the light emitting element ED of one or more embodiments, the constructive interference may occur among the first reflected light RL1 reflected at the first interface LF1, the second reflected light RL2 reflected at the second interface LF2, and the third reflected light RL3 reflected at the third interface LF3. Accordingly, the light emitting element ED of one or more embodiments may exhibit high external light extraction efficiency.

Referring to FIG. 7, the hole transport region HTR of one or more embodiments may further include 4-1st reflected light RL4-1 and 4-2nd reflected light RL4-2 in addition to the first to third reflected light RL1, RL2, and RL3 as described in FIG. 6.

For example, in the emission layer EML, part of 4-1st incident light L4-1, which passes through the third hole transport layer HTL3, the 4-2nd hole transport layer HTL4-2, and the second hole transport layer HTL2 from the emission layer to enter towards the 4-1st hole transport layer HTL4-1, may be reflected at a 4-1st interface LF4-1 towards the emission layer EML. Part of 4-2nd incident light L4-2, which passes through the third hole transport layer HTL3 from the emission layer EML to enter towards the 4-2nd hole transport layer HTL4-2, may be reflected at a 4-2nd interface LF4-2 towards the emission layer EML. In the light emitting element ED of one or more embodiments, the constructive interference may occur among the first reflected light RL1 reflected at the first interface LF1, the 4-1st reflected light RL4-1 reflected at the 4-1 st interface LF4-1, the second reflected light RL2 reflected at the second interface LF2, the 4-2nd reflected light RL4-2 reflected at the 4-2nd interface LF4-2, and the third reflected light RL3 reflected at the third interface LF3. As a result, the light emitting element ED of one or more embodiments may exhibit high or improved external light extraction efficiency.

The light emitting element ED of one or more embodiments includes the plurality of hole transport layers HTL1, HTL2, HTL3, and HTL4 having the above-described first to fourth refractive indices, respectively, thereby exhibiting improved luminous efficiency. The light emitting element ED of one or more embodiments may include the hole transport layers HTL1, HTL2, HTL3, and HTL4 of the hole transport region HTR having different refractive indices, thus minimizing or reducing the extinction of light emitted from the functional layers therein due to destructive interference, and increasing constructive interference of light, thereby exhibiting high or improved light extraction efficiency.

In some embodiments, the hole transport region HTR of one or more embodiments includes the first hole transport layer HTL1 having the first refractive index and having a conductivity of about 6.0×10⁻⁵ cm/(V·s) to about 10.0×10⁻⁴ cm/(V·s) and the second hole transport layer HTL2 having the second refractive index greater than the first refractive index, and thus, may have excellent or improved hole mobility and improved electrical characteristics, thereby preventing or reducing the occurrence of a leakage current when the light emitting element ED is driven. For example, the occurrence of a leakage current may be prevented or reduced when the light emitting element ED is driven in a low gradation region. The hole transport region HTR of one or more embodiments may further include the third hole transport layer HTL3 and the fourth hole transport layer HTL4, each of which has a conductivity of about 6.0×10⁻⁵ cm/(V·s) to about 10.0×10⁻⁴ cm/(V·s), thereby exhibiting improved electrical characteristics.

The light emitting element ED of one or more embodiments may include the hole transport region HTR, thereby having a low or suitable driving voltage and exhibiting excellent or improved luminous efficiency. In some embodiments, the light emitting element ED of one or more embodiments may have improved brightness in the low gradation region, thereby improving color visibility.

In the light emitting element ED according to one or more embodiments, the first amine compound, the second amine compound, and the third amine compound respectively included in the first hole transport layer HTL1, the third hole transport layer HTL3, and the fourth hole transport layer HTL4 may be each independently represented by Formula 1.

Hereinafter, the amine compound represented by Formula 1 will be described. The description of the amine compound may be equally applied to each of the first amine compound, the second amine compound, and the third amine compound.

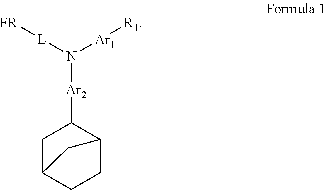

In Formula 1, R₁ is a substituted or unsubstituted cycloalkyl group having 6 to 12 ring-forming carbon atoms. For example, R₁ may be a substituted or unsubstituted cyclohexyl group, a substituted or unsubstituted bicycloheptyl group, a substituted or unsubstituted bicyclooctyl group, a substituted or unsubstituted bicyclononyl group, or a substituted or unsubstituted adamantyl group. For example, R₁ may be a substituted or unsubstituted cyclohexyl group, a substituted or unsubstituted bicyclo[2,2,1]heptyl group, a substituted or unsubstituted bicyclo[2,2,2]octyl group, a substituted or unsubstituted bicyclo[3,2,2]nonyl group, or a substituted or unsubstituted adamantyl group.

Ar₁ and Ar₂ are each independently a substituted or unsubstituted arylene group having 6 to 30 ring-forming carbon atoms, or a substituted or unsubstituted heteroarylene group having 2 to 30 ring-forming carbon atoms. For example, Ar₁ and Ar₂ may be each independently a substituted or unsubstituted arylene group having 6 to 30 ring-forming carbon atoms, and in some embodiments, Ar₁ and Ar₂ may be each independently a substituted or unsubstituted phenylene group.

L is a direct linkage, a substituted or unsubstituted arylene group having 6 to 30 ring-forming carbon atoms, or a substituted or unsubstituted heteroarylene group having 2 to 30 ring-forming carbon atoms. For example, L may be a direct linkage or an unsubstituted phenylene group. When L is a direct linkage, in Formula 1, FR may be directly linked to the nitrogen atom.

The amine compound represented by Formula 1 may include, around the central nitrogen atom, a first substituent, which is a bicycloheptyl group, a second substituent, which is a substituted or unsubstituted cycloalkyl group having 6 to 12 ring-forming carbon atoms, and a third substituent represented by Formula FR. The first to third substituents may be linked to the central nitrogen atom via one or more linkers.

FR is represented by Formula 2-1 or Formula 2-2. In Formula 2-1 and Formula 2-2, “-*” refers to a position to be linked to L in Formula 1.

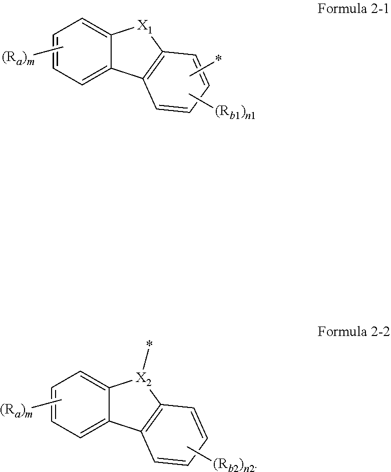

In Formula 2-1 to Formula 2-2, X₁ is CR_{c}R_{d}, NRₑ, O, or S. X₂ is CR_{f}, or N. For example, the substituent FR represented by Formula 2-1 or Formula 2-2 may be a substituted or unsubstituted fluorene derivative, a substituted or unsubstituted carbazole derivative, a substituted or unsubstituted dibenzofuran derivative, or a substituted or unsubstituted dibenzothiophene derivative.

Rₐ, R_{b1}, R_{b2}, and R_{c} to R_{f} are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring.

For example, each of Rₐ, R_{b1}, and R_{b2} may be a hydrogen atom. For example, R_{c} and R_{d} may be each independently a substituted or unsubstituted methyl group, a substituted or unsubstituted heptyl group, a substituted or unsubstituted cyclohexyl group, a substituted or unsubstituted phenyl group, and/or may be bonded to each other to form a cyclopentane or fluorene ring. When R_{c} and R_{d} are bonded to each other to form a cyclopentane or fluorene ring, FR may form a spiro structure such as

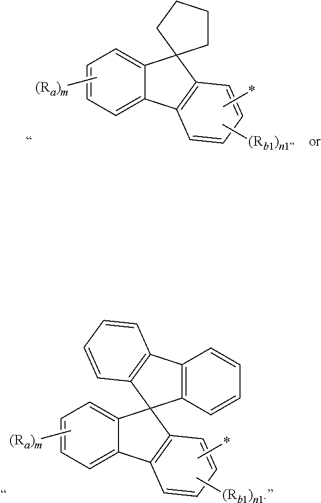

For example, R_{f} may be a substituted or unsubstituted aryl group having 6 to 30 ring-forming carbon atoms, and for example, R_{f} may be an unsubstituted phenyl group.

m is an integer of 0 to 4. If m is an integer of 2 or more, a plurality of Rₐ's may all be the same, or at least one among the plurality of Rₐ's may be different from the others. For example, m may be 0. If m is 0, FR may not be substituted with Rₐ. In FR, the structure in which m is 4 and Rₐ's are all hydrogen atoms may be the same as the structure in which m is 0 in FR.

n1 is an integer of 0 to 3. If n1 is an integer of 2 or more, a plurality of R_{b1}'s may all be the same, or at least one among the plurality of R_{b1}'s may be different from the others. For example, n1 may be 0. If n1 is 0, FR may not be substituted with R_{b1}. In FR, the structure in which n1 is 4 and R_{b1}'s are all hydrogen atoms may be the same as the structure in which n1 is 0 in FR.

n2 is an integer of 0 to 4. If n2 is an integer of 2 or more, a plurality of R_{b2}'s may all be the same, or at least one among the plurality of R_{b2}'s may be different from the others. For example, n2 may be 0. If n2 is 0, FR may not be substituted with R_{b2}. In FR, the structure in which n2 is 4 and R_{b2}'s are all hydrogen atoms may be the same as the structure in which n2 is 0 in FR.

The first hole transport layer HTL1, the third hole transport layer HTL3, and the fourth hole transport layer HTL4 may include the amine compound represented by Formula 1, thereby having a refractive index of about 1.4 to about 1.75.

In one or more embodiments, the amine compound represented by Formula 1 may be represented by Formula 1-1 to Formula 1-5:

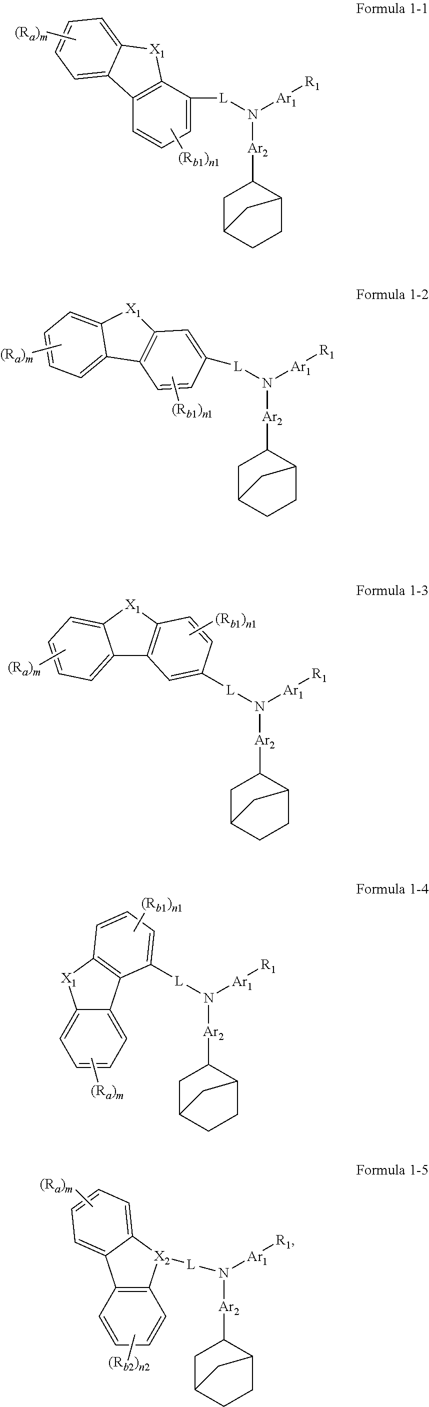

wherein, in Formula 1-1 to Formula 1-5, R₁, L, Ar₁, and Ar₂ are the same as defined in Formula 1, and X₁, X₂, Rₐ, R_{b1}, R_{b2}, m, n1, and n2 are the same as defined in Formula 2-1 and Formula 2-2.

Formula 1-1 to Formula 1-5 are the cases where the linking position of the substituent FR and the linker L is specified.

In one or more embodiments, the amine compound represented by Formula 1 may be represented by Formula 3:

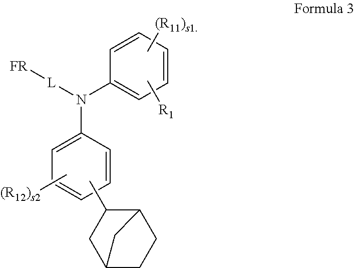

Formula 3 is the case where each of Ar₁ and Ar₂ in Formula 1 is a substituted or unsubstituted phenylene group.

In Formula 3, R₁₁ and R₁₂ may be each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. For example, each of R₁₁ and R₁₂ may be a hydrogen atom.

s1 and s2 may be each independently an integer of 0 to 4. If s1 is an integer of 2 or more, a plurality of R₁₁'s may all be the same, or at least one selected from the plurality of R₁₁'s may be different from the others. For example, s1 may be 0. If s1 is 0, the amine compound represented by Formula 1 may not be substituted with R₁₁. The structure in which s1 in Formula 1 is 4 and R₁₁'s are all hydrogen atoms may be the same as the structure in which s1 is 0 in Formula 1.

If s2 is an integer of 2 or more, a plurality of R₁₂'s may all be the same, or at least one selected from the plurality of R₁₂'s may be different from the others. For example, s2 may be 0. If s2 is 0, the amine compound represented by Formula 1 may not be substituted with R₁₂. The structure in which s2 is 4 and R₁₂'s are all hydrogen atoms in Formula 1 may be the same as the structure in which s2 is 0 in Formula 1.

In Formula 3, R₁, L, and FR are the same as defined in Formula 1, Formula 2-1, and Formula 2-2.

In one or more embodiments, the amine compound represented by Formula 3 may be represented by Formula 3-1:

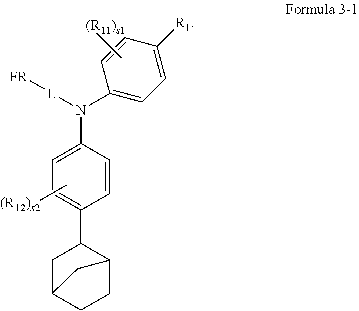

Formula 3-1 is the case where in Formula 3, the positions, at which R₁ and the bicyclo[2,2,1]heptyl group are linked to linkers, are specified. Formula 3-1 is the case where each of R₁ and the bicyclo[2,2,1]heptyl group are linked at the para-position with the nitrogen atom. However, one or more embodiments of the present disclosure is not limited thereto.

In Formula 3-1, the same descriptions as provided in Formula 1 may be applied to R₁, L, and FR.

The amine compound represented by Formula 1 of one or more embodiments may be represented by any one selected from the compounds of Compound Group 1. The first hole transport layer HTL1, the third hole transport layer HTL3, and the fourth hole transport layer HTL4 of the light emitting element ED of one or more embodiments may include at least one selected from the amine compounds in Compound Group 1.

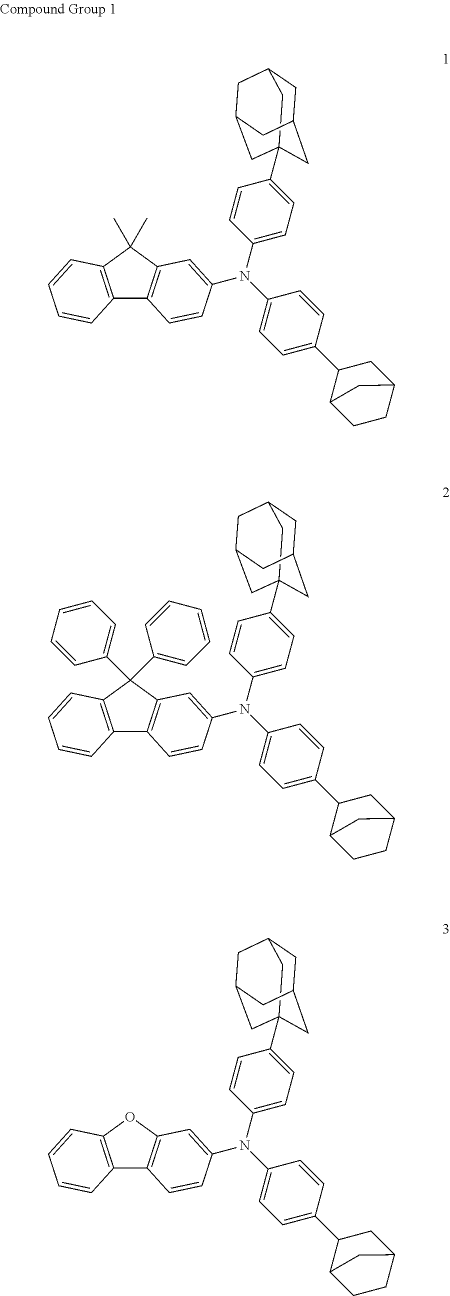 [SMILES: CC1(C)c2ccccc2-c2ccc(N(c3ccc(C4CC5CCC4C5)cc3)c3ccc(C45CC6CC(CC(C6)C4)C5)cc3)cc21 ; c1ccc(C2(c3ccccc3)c3ccccc3-c3ccc(N(c4ccc(C5CC6CCC5C6)cc4)c4ccc(C56CC7CC(CC(C7)C5)C6)cc4)cc32)cc1 ; c1ccc2c(c1)oc1cc(N(c3ccc(C4CC5CCC4C5)cc3)c3ccc(C45CC6CC(CC(C6)C4)C5)cc3)ccc12]

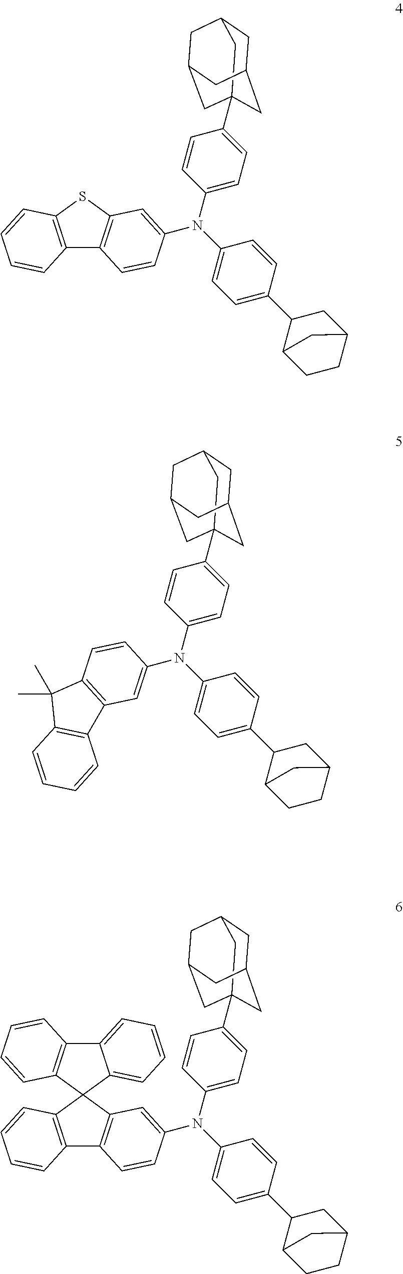 [SMILES: c1ccc2c(c1)sc1cc(N(c3ccc(C4CC5CCC4C5)cc3)c3ccc(C45CC6CC(CC(C6)C4)C5)cc3)ccc12 ; CC1(C)c2ccccc2-c2cc(N(c3ccc(C4CC5CCC4C5)cc3)c3ccc(C45CC6CC(CC(C6)C4)C5)cc3)ccc21 ; c1ccc2c(c1)-c1ccccc1C21c2ccccc2-c2ccc(N(c3ccc(C4CC5CCC4C5)cc3)c3ccc(C45CC6CC(CC(C6)C4)C5)cc3)cc21]

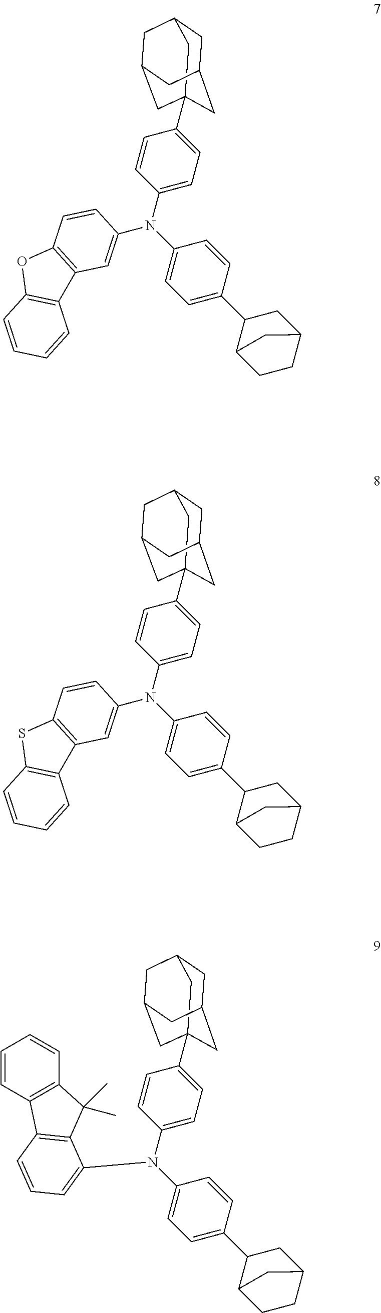 [SMILES: c1ccc2c(c1)oc1ccc(N(c3ccc(C4CC5CCC4C5)cc3)c3ccc(C45CC6CC(CC(C6)C4)C5)cc3)cc12 ; c1ccc2c(c1)sc1ccc(N(c3ccc(C4CC5CCC4C5)cc3)c3ccc(C45CC6CC(CC(C6)C4)C5)cc3)cc12 ; CC1(C)c2ccccc2-c2cccc(N(c3ccc(C4CC5CCC4C5)cc3)c3ccc(C45CC6CC(CC(C6)C4)C5)cc3)c21]

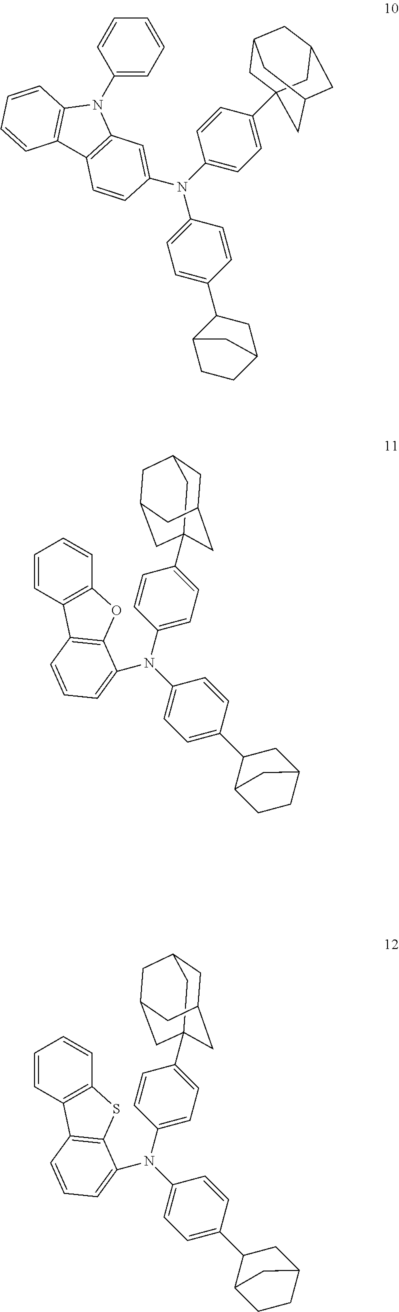 [SMILES: c1ccc(-n2c3ccccc3c3ccc(N(c4ccc(C5CC6CCC5C6)cc4)c4ccc(C56CC7CC(CC(C7)C5)C6)cc4)cc32)cc1 ; c1ccc2c(c1)oc1c(N(c3ccc(C4CC5CCC4C5)cc3)c3ccc(C45CC6CC(CC(C6)C4)C5)cc3)cccc12 ; c1ccc2c(c1)sc1c(N(c3ccc(C4CC5CCC4C5)cc3)c3ccc(C45CC6CC(CC(C6)C4)C5)cc3)cccc12]

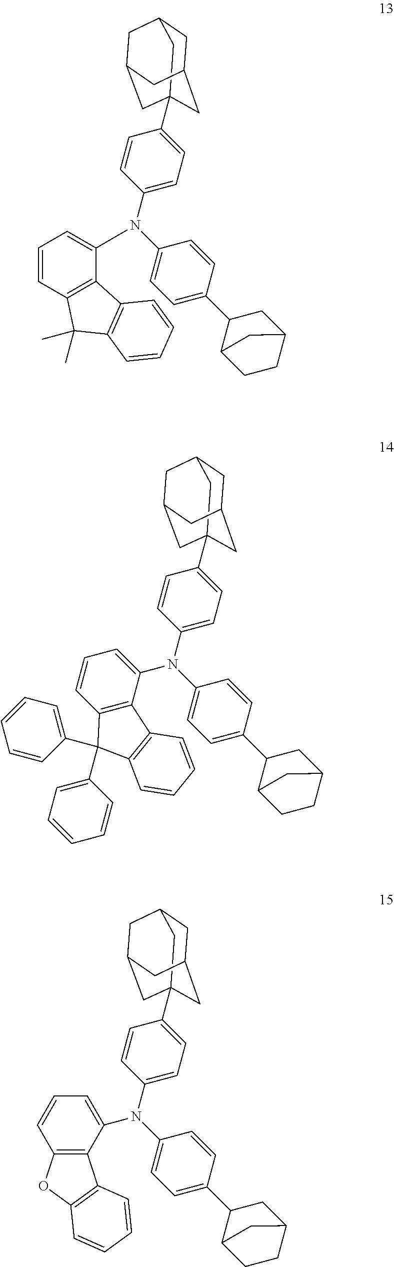 [SMILES: CC1(C)c2ccccc2-c2c(N(c3ccc(C4CC5CCC4C5)cc3)c3ccc(C45CC6CC(CC(C6)C4)C5)cc3)cccc21 ; c1ccc(C2(c3ccccc3)c3ccccc3-c3c(N(c4ccc(C5CC6CCC5C6)cc4)c4ccc(C56CC7CC(CC(C7)C5)C6)cc4)cccc32)cc1 ; c1ccc2c(c1)oc1cccc(N(c3ccc(C4CC5CCC4C5)cc3)c3ccc(C45CC6CC(CC(C6)C4)C5)cc3)c12]

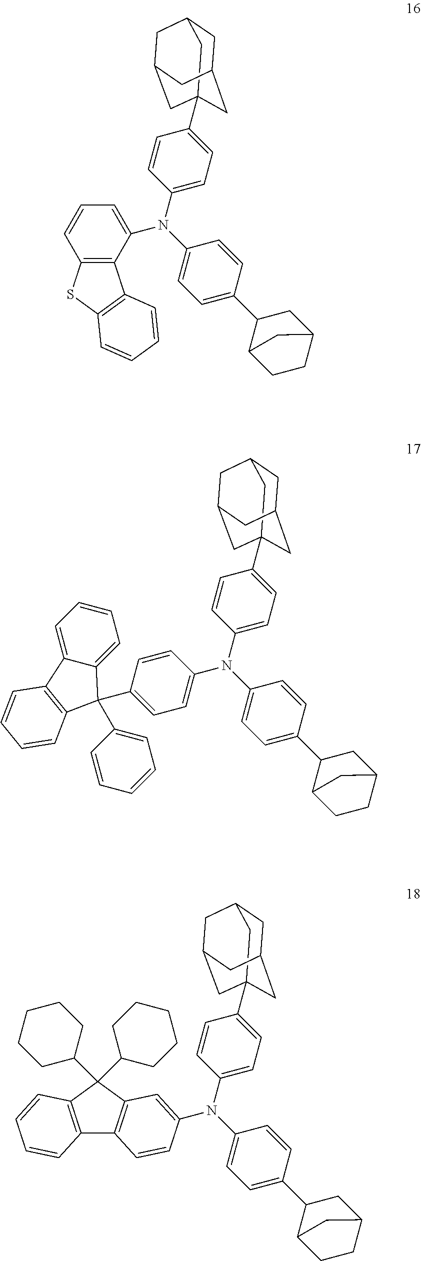 [SMILES: c1ccc2c(c1)sc1cccc(N(c3ccc(C4CC5CCC4C5)cc3)c3ccc(C45CC6CC(CC(C6)C4)C5)cc3)c12 ; c1ccc(C2(c3ccc(N(c4ccc(C5CC6CCC5C6)cc4)c4ccc(C56CC7CC(CC(C7)C5)C6)cc4)cc3)c3ccccc3-c3ccccc32)cc1 ; c1ccc2c(c1)-c1ccc(N(c3ccc(C4CC5CCC4C5)cc3)c3ccc(C45CC6CC(CC(C6)C4)C5)cc3)cc1C2(C1CCCCC1)C1CCCCC1]

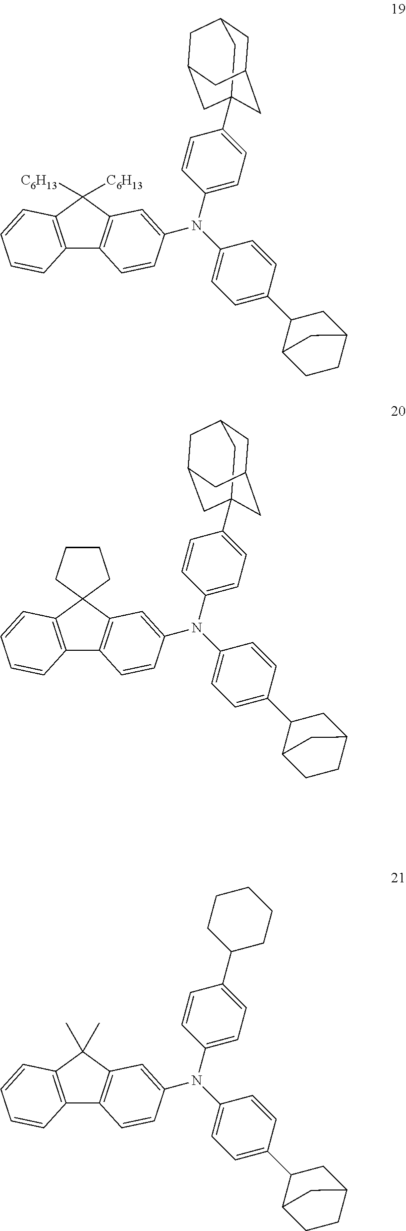

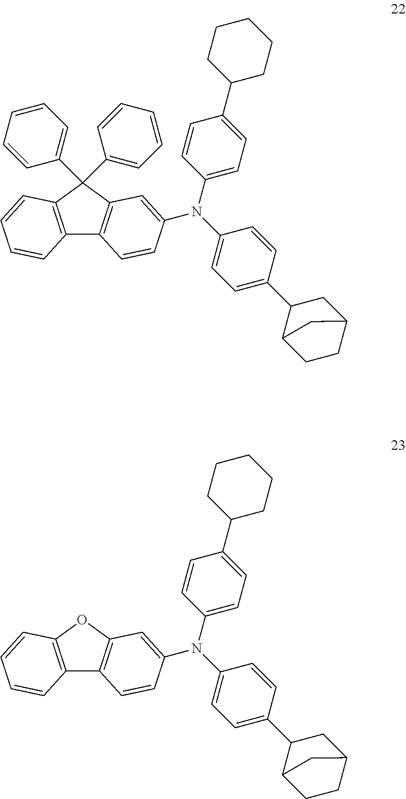 [SMILES: c1ccc(C2(c3ccccc3)c3ccccc3-c3ccc(N(c4ccc(C5CCCCC5)cc4)c4ccc(C5CC6CCC5C6)cc4)cc32)cc1 ; c1ccc2c(c1)oc1cc(N(c3ccc(C4CCCCC4)cc3)c3ccc(C4CC5CCC4C5)cc3)ccc12]

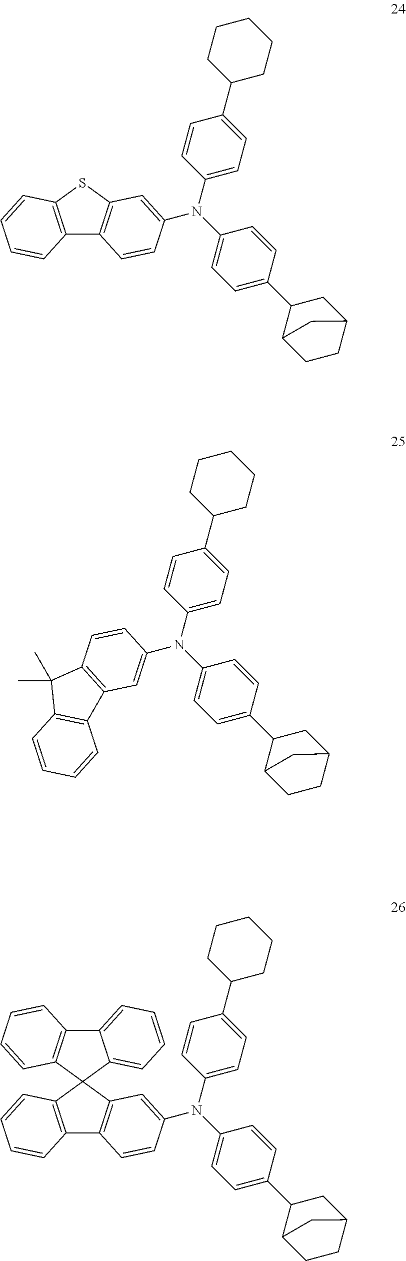 [SMILES: c1ccc2c(c1)sc1cc(N(c3ccc(C4CCCCC4)cc3)c3ccc(C4CC5CCC4C5)cc3)ccc12 ; CC1(C)c2ccccc2-c2cc(N(c3ccc(C4CCCCC4)cc3)c3ccc(C4CC5CCC4C5)cc3)ccc21 ; c1ccc2c(c1)-c1ccccc1C21c2ccccc2-c2ccc(N(c3ccc(C4CCCCC4)cc3)c3ccc(C4CC5CCC4C5)cc3)cc21]

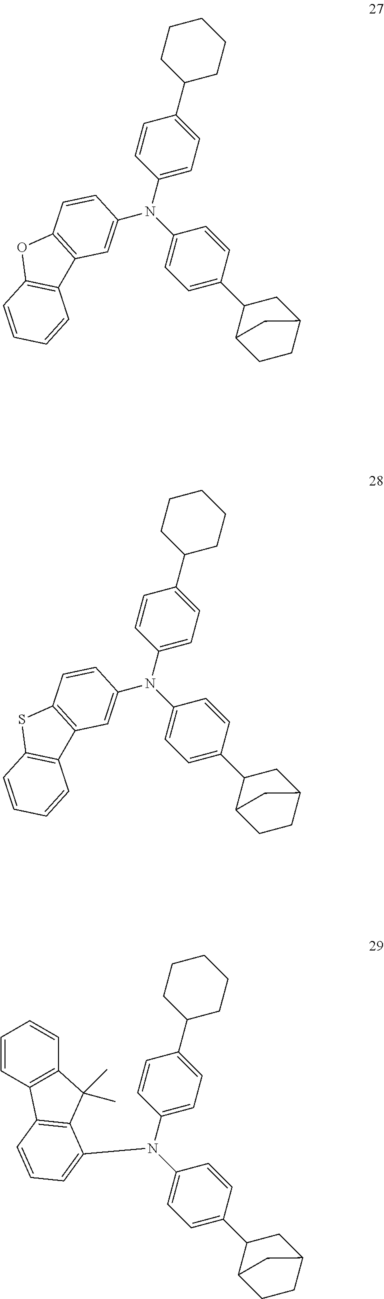 [SMILES: c1ccc2c(c1)oc1ccc(N(c3ccc(C4CCCCC4)cc3)c3ccc(C4CC5CCC4C5)cc3)cc12 ; c1ccc2c(c1)sc1ccc(N(c3ccc(C4CCCCC4)cc3)c3ccc(C4CC5CCC4C5)cc3)cc12 ; CC1(C)c2ccccc2-c2cccc(N(c3ccc(C4CCCCC4)cc3)c3ccc(C4CC5CCC4C5)cc3)c21]

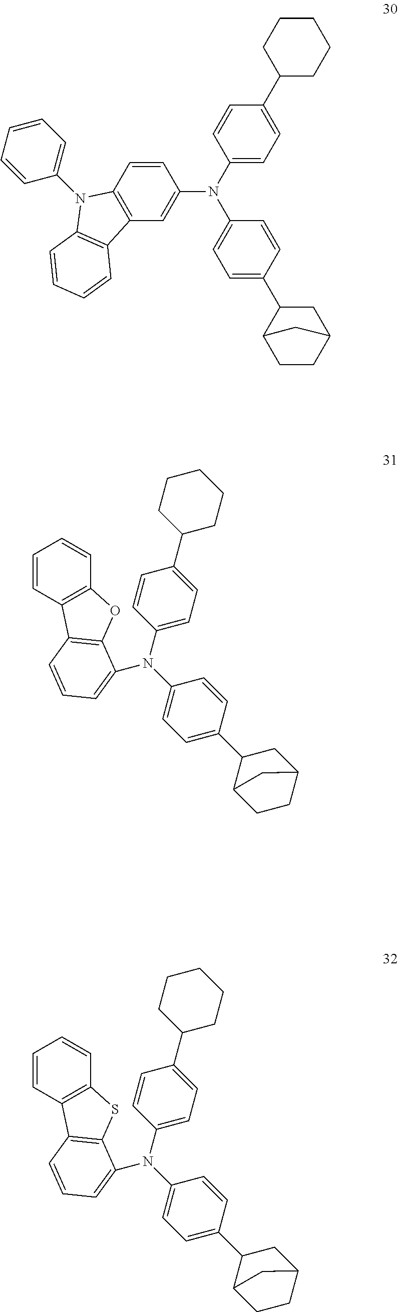 [SMILES: c1ccc(-n2c3ccccc3c3cc(N(c4ccc(C5CCCCC5)cc4)c4ccc(C5CC6CCC5C6)cc4)ccc32)cc1 ; c1ccc2c(c1)oc1c(N(c3ccc(C4CCCCC4)cc3)c3ccc(C4CC5CCC4C5)cc3)cccc12 ; c1ccc2c(c1)sc1c(N(c3ccc(C4CCCCC4)cc3)c3ccc(C4CC5CCC4C5)cc3)cccc12]

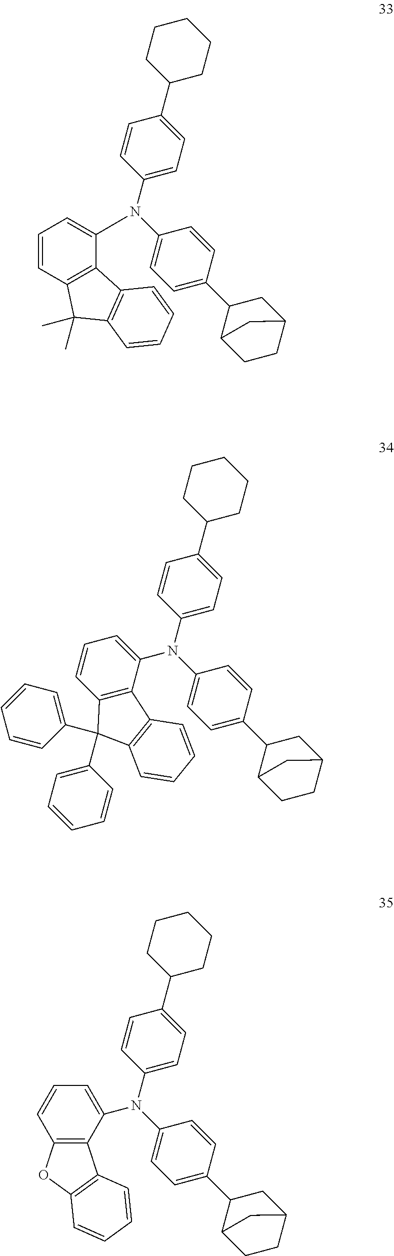 [SMILES: CC1(C)c2ccccc2-c2c(N(c3ccc(C4CCCCC4)cc3)c3ccc(C4CC5CCC4C5)cc3)cccc21 ; c1ccc(C2(c3ccccc3)c3ccccc3-c3c(N(c4ccc(C5CCCCC5)cc4)c4ccc(C5CC6CCC5C6)cc4)cccc32)cc1 ; c1ccc2c(c1)oc1cccc(N(c3ccc(C4CCCCC4)cc3)c3ccc(C4CC5CCC4C5)cc3)c12]

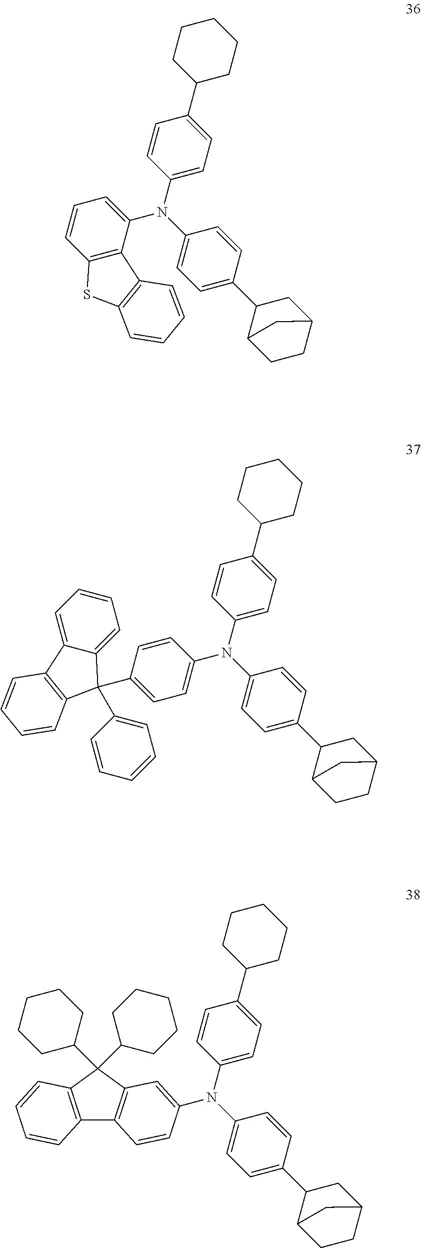 [SMILES: c1ccc2c(c1)sc1cccc(N(c3ccc(C4CCCCC4)cc3)c3ccc(C4CC5CCC4C5)cc3)c12 ; c1ccc(C2(c3ccc(N(c4ccc(C5CCCCC5)cc4)c4ccc(C5CC6CCC5C6)cc4)cc3)c3ccccc3-c3ccccc32)cc1 ; c1ccc2c(c1)-c1ccc(N(c3ccc(C4CCCCC4)cc3)c3ccc(C4CC5CCC4C5)cc3)cc1C2(C1CCCCC1)C1CCCCC1]

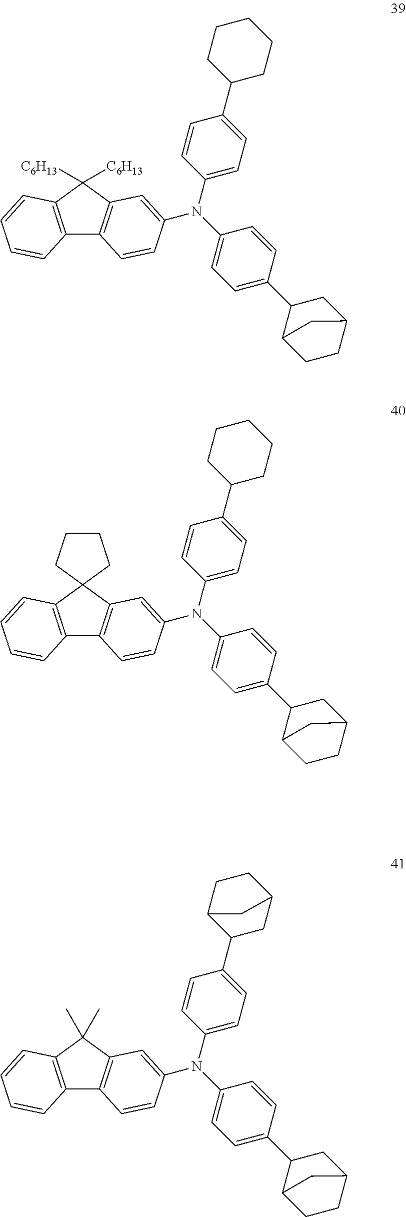

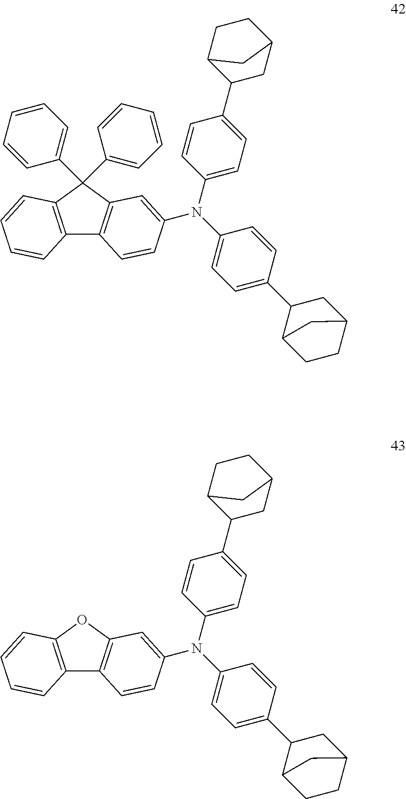 [SMILES: c1ccc(C2(c3ccccc3)c3ccccc3-c3ccc(N(c4ccc(C5CC6CCC5C6)cc4)c4ccc(C5CC6CCC5C6)cc4)cc32)cc1 ; c1ccc2c(c1)oc1cc(N(c3ccc(C4CC5CCC4C5)cc3)c3ccc(C4CC5CCC4C5)cc3)ccc12]

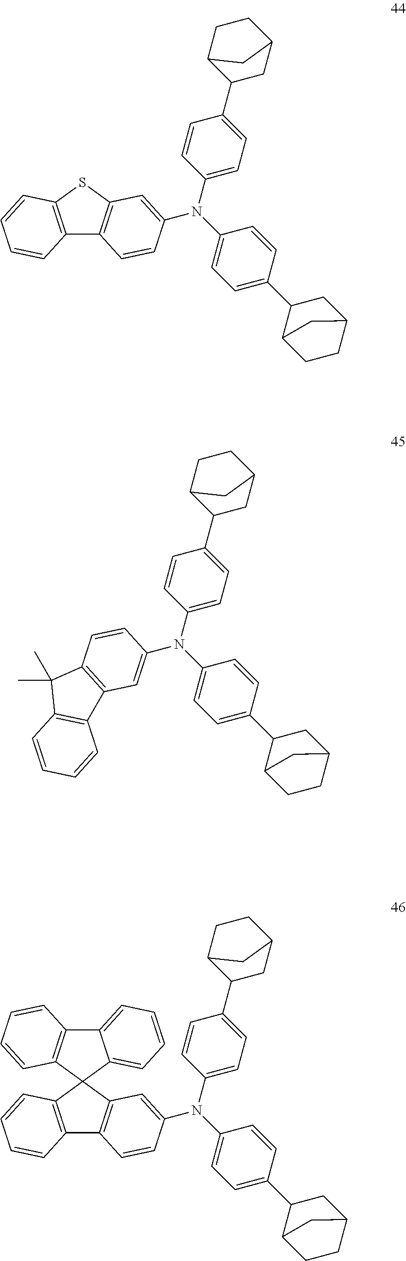 [SMILES: c1ccc2c(c1)sc1cc(N(c3ccc(C4CC5CCC4C5)cc3)c3ccc(C4CC5CCC4C5)cc3)ccc12 ; CC1(C)c2ccccc2-c2cc(N(c3ccc(C4CC5CCC4C5)cc3)c3ccc(C4CC5CCC4C5)cc3)ccc21 ; c1ccc2c(c1)-c1ccccc1C21c2ccccc2-c2ccc(N(c3ccc(C4CC5CCC4C5)cc3)c3ccc(C4CC5CCC4C5)cc3)cc21]

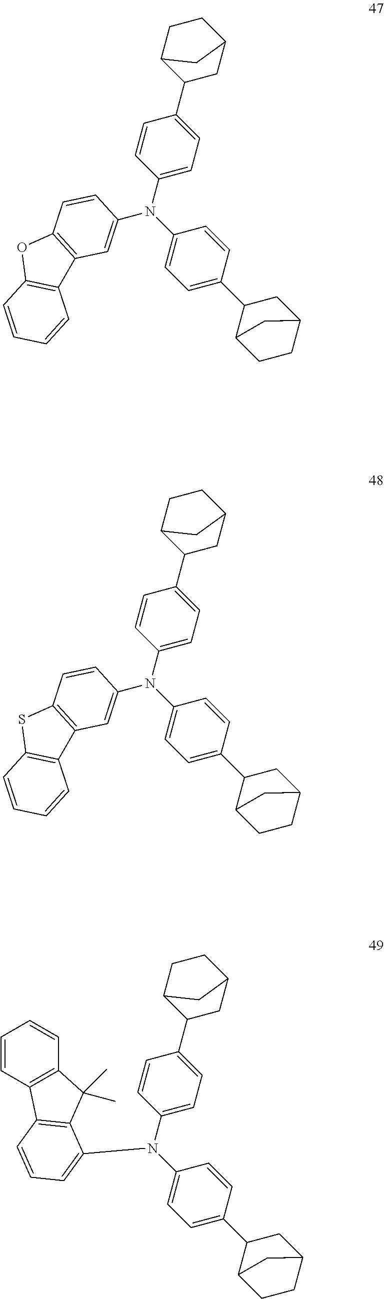 [SMILES: c1ccc2c(c1)oc1ccc(N(c3ccc(C4CC5CCC4C5)cc3)c3ccc(C4CC5CCC4C5)cc3)cc12 ; c1ccc2c(c1)sc1ccc(N(c3ccc(C4CC5CCC4C5)cc3)c3ccc(C4CC5CCC4C5)cc3)cc12 ; CC1(C)c2ccccc2-c2cccc(N(c3ccc(C4CC5CCC4C5)cc3)c3ccc(C4CC5CCC4C5)cc3)c21]

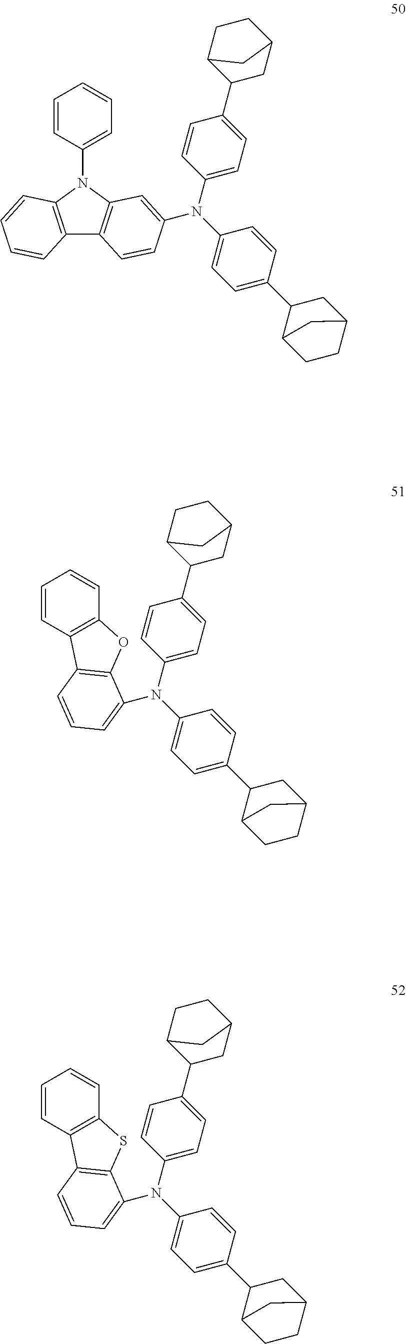 [SMILES: c1ccc(-n2c3ccccc3c3ccc(N(c4ccc(C5CC6CCC5C6)cc4)c4ccc(C5CC6CCC5C6)cc4)cc32)cc1 ; c1ccc2c(c1)oc1c(N(c3ccc(C4CC5CCC4C5)cc3)c3ccc(C4CC5CCC4C5)cc3)cccc12 ; c1ccc2c(c1)sc1c(N(c3ccc(C4CC5CCC4C5)cc3)c3ccc(C4CC5CCC4C5)cc3)cccc12]

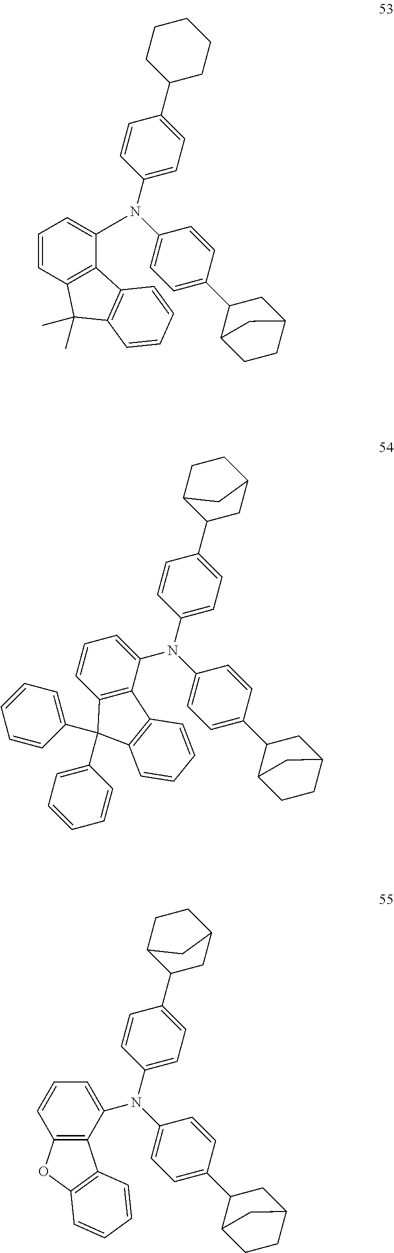 [SMILES: CC1(C)c2ccccc2-c2c(N(c3ccc(C4CCCCC4)cc3)c3ccc(C4CC5CCC4C5)cc3)cccc21 ; c1ccc(C2(c3ccccc3)c3ccccc3-c3c(N(c4ccc(C5CC6CCC5C6)cc4)c4ccc(C5CC6CCC5C6)cc4)cccc32)cc1 ; c1ccc2c(c1)oc1cccc(N(c3ccc(C4CC5CCC4C5)cc3)c3ccc(C4CC5CCC4C5)cc3)c12]

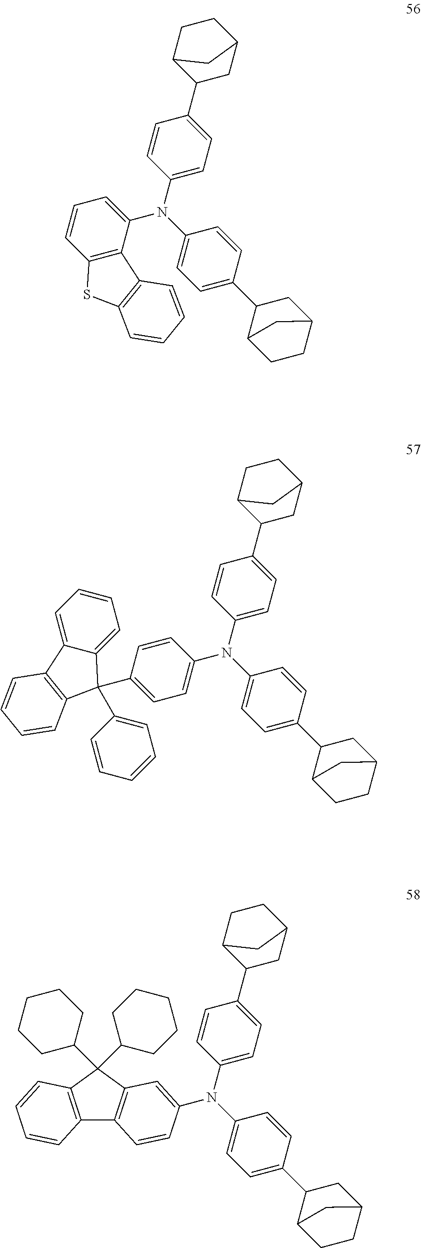 [SMILES: c1ccc2c(c1)sc1cccc(N(c3ccc(C4CC5CCC4C5)cc3)c3ccc(C4CC5CCC4C5)cc3)c12 ; c1ccc(C2(c3ccc(N(c4ccc(C5CC6CCC5C6)cc4)c4ccc(C5CC6CCC5C6)cc4)cc3)c3ccccc3-c3ccccc32)cc1 ; c1ccc2c(c1)-c1ccc(N(c3ccc(C4CC5CCC4C5)cc3)c3ccc(C4CC5CCC4C5)cc3)cc1C2(C1CCCCC1)C1CCCCC1]

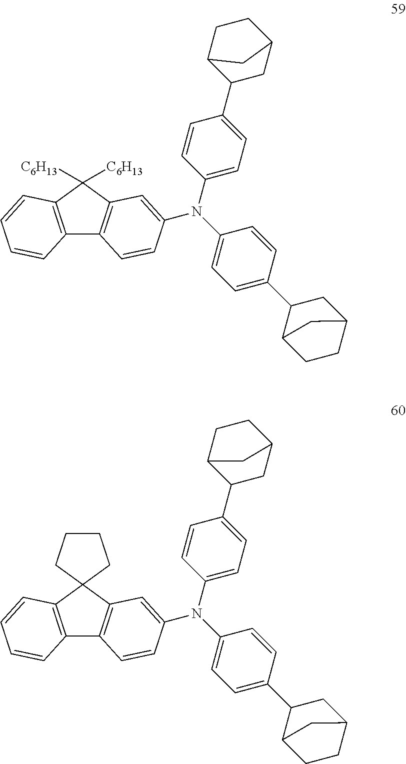

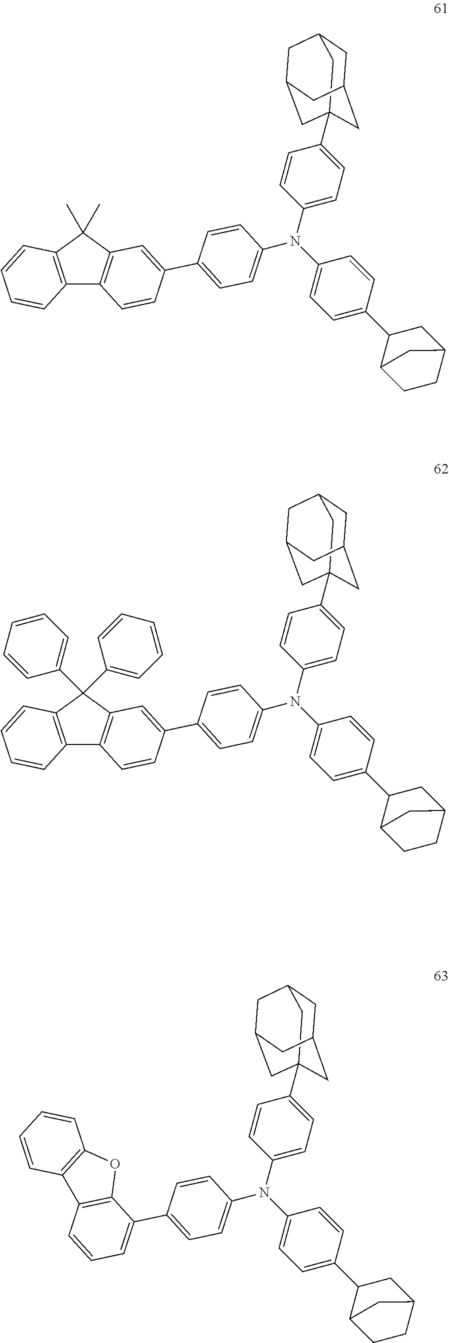 [SMILES: CC1(C)c2ccccc2-c2ccc(-c3ccc(N(c4ccc(C5CC6CCC5C6)cc4)c4ccc(C56CC7CC(CC(C7)C5)C6)cc4)cc3)cc21 ; c1ccc(C2(c3ccccc3)c3ccccc3-c3ccc(-c4ccc(N(c5ccc(C6CC7CCC6C7)cc5)c5ccc(C67CC8CC(CC(C8)C6)C7)cc5)cc4)cc32)cc1 ; c1ccc2c(c1)oc1c(-c3ccc(N(c4ccc(C5CC6CCC5C6)cc4)c4ccc(C56CC7CC(CC(C7)C5)C6)cc4)cc3)cccc12]

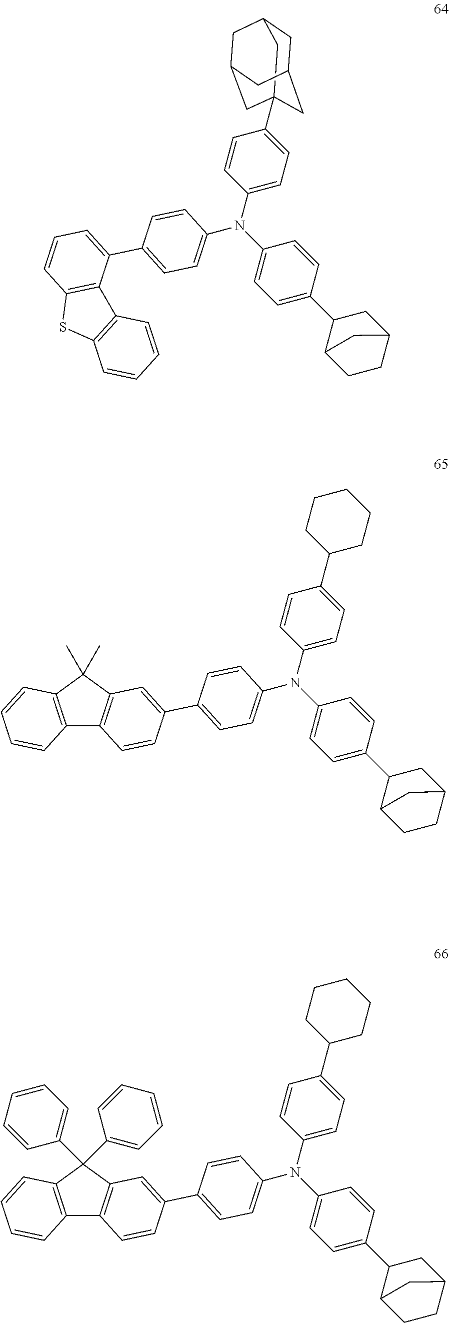 [SMILES: c1ccc2c(c1)sc1cccc(-c3ccc(N(c4ccc(C5CC6CCC5C6)cc4)c4ccc(C56CC7CC(CC(C7)C5)C6)cc4)cc3)c12 ; CC1(C)c2ccccc2-c2ccc(-c3ccc(N(c4ccc(C5CCCCC5)cc4)c4ccc(C5CC6CCC5C6)cc4)cc3)cc21 ; c1ccc(C2(c3ccccc3)c3ccccc3-c3ccc(-c4ccc(N(c5ccc(C6CCCCC6)cc5)c5ccc(C6CC7CCC6C7)cc5)cc4)cc32)cc1]

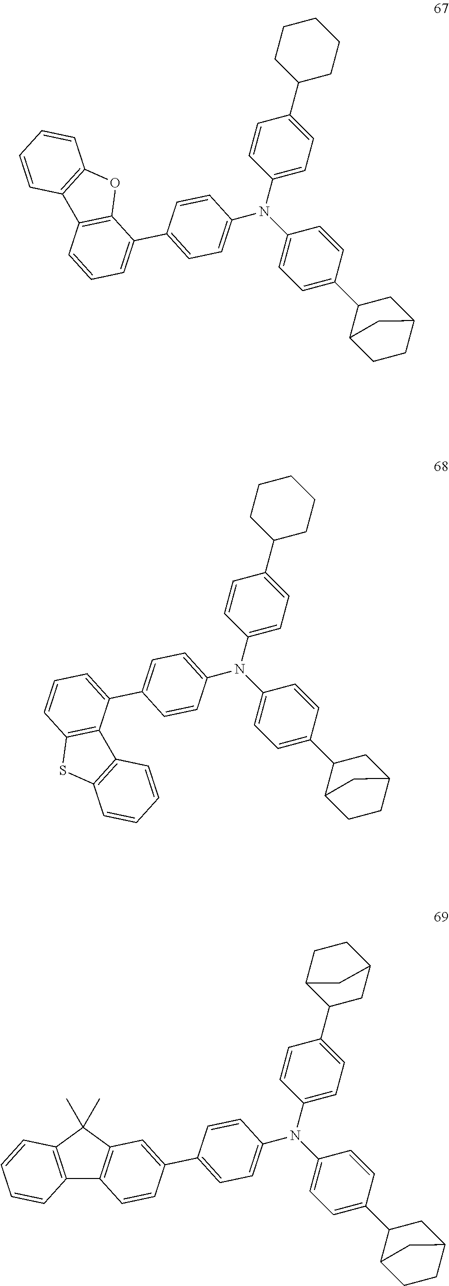 [SMILES: c1ccc2c(c1)oc1c(-c3ccc(N(c4ccc(C5CCCCC5)cc4)c4ccc(C5CC6CCC5C6)cc4)cc3)cccc12 ; c1ccc2c(c1)sc1cccc(-c3ccc(N(c4ccc(C5CCCCC5)cc4)c4ccc(C5CC6CCC5C6)cc4)cc3)c12 ; CC1(C)c2ccccc2-c2ccc(-c3ccc(N(c4ccc(C5CC6CCC5C6)cc4)c4ccc(C5CC6CCC5C6)cc4)cc3)cc21]

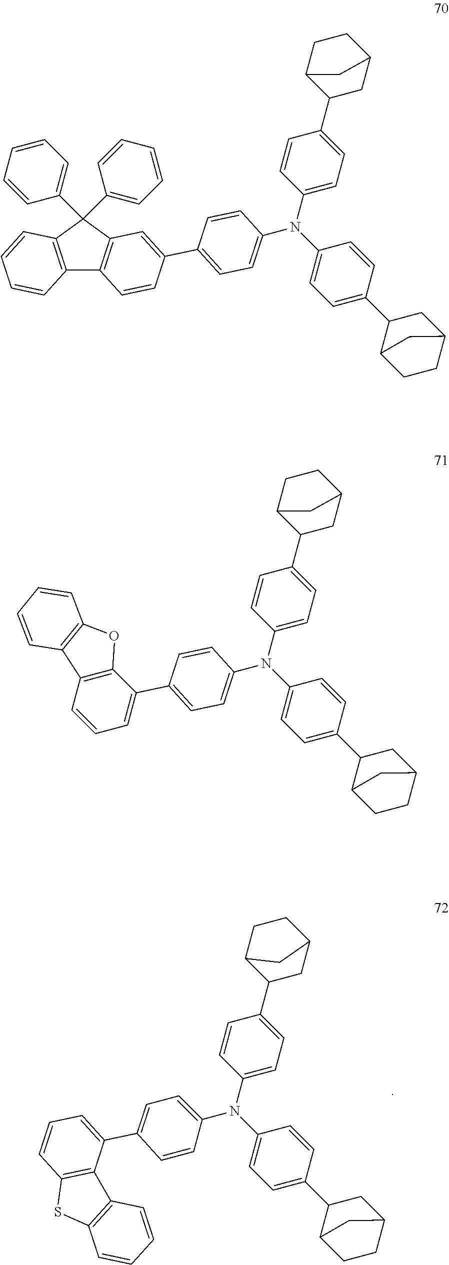 [SMILES: c1ccc(C2(c3ccccc3)c3ccccc3-c3ccc(-c4ccc(N(c5ccc(C6CC7CCC6C7)cc5)c5ccc(C6CC7CCC6C7)cc5)cc4)cc32)cc1 ; c1ccc2c(c1)oc1c(-c3ccc(N(c4ccc(C5CC6CCC5C6)cc4)c4ccc(C5CC6CCC5C6)cc4)cc3)cccc12 ; c1ccc2c(c1)sc1cccc(-c3ccc(N(c4ccc(C5CC6CCC5C6)cc4)c4ccc(C5CC6CCC5C6)cc4)cc3)c12]

The light emitting element ED of the present disclosure may include hole transport layers HTL1, HTL3, and HTL4, each including the amine compound represented by Formula 1, thereby having a low refractive index.

In some embodiments, the light emitting element ED may further include a hole transport region material in the hole transport region HTR.

In the hole transport region HTR, the first to fourth hole transport layers HTL1, HTL2, HTL3, and HTL4 may include a compound represented by Formula H-1.

Each of the first hole transport layer HTL1, the third hole transport layer HTL3, and the fourth hole transport HTL4 may include the amine compound represented by Formula 1 and the compound represented by Formula H-1, thereby satisfying a refractive index of about 1.4 to about 1.75. The first hole transport layer HTL1, the third hole transport layer HTL3, and the fourth hole transport HTL4 may have the values of the first refractive index, the third refractive index, and the fourth refractive index, respectively, by adjusting the content ratio of the compound represented by Formula H-1 and the amine compound represented by Formula 1.

The second hole transport layer HTL2 may include the compound represented by Formula H-1, thereby having a refractive index of about 1.8 to about 2.0.

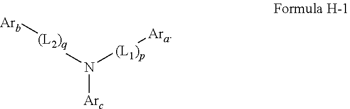

In Formula H-1, Arₐ and Ar_{b} may be each independently a substituted or unsubstituted aryl group having 6 to 30 ring-forming carbon atoms, or a substituted or unsubstituted heteroaryl group having 2 to 30 ring-forming carbon atoms.

Ar_{c} may be a substituted or unsubstituted aryl group having 6 to 30 ring-forming carbon atoms.

L₁ and L₂ may be each independently a direct linkage, a substituted or unsubstituted arylene group having 6 to 30 ring-forming carbon atoms, or a substituted or unsubstituted heteroarylene group having 2 to 30 ring-forming carbon atoms.

p and q may be each independently an integer of 0 to 10. When p or q is an integer of 2 or greater, a plurality of L₁'s and L₂'s may be each independently a substituted or unsubstituted arylene group having 6 to 30 ring-forming carbon atoms, or a substituted or unsubstituted heteroarylene group having 2 to 30 ring-forming carbon atoms.

The compound represented by Formula H-1 may be a monoamine compound. In one or more embodiments, the compound represented by Formula H-1 may be a diamine compound in which at least one selected from Arₐ to Ar_{c} contains an amine group as a substituent. In some embodiments, the compound represented by Formula H-1 may be a carbazole-based compound containing a substituted or unsubstituted carbazole group in at least one of Arₐ or Ar_{b}, or a fluorene-based compound containing a substituted or unsubstituted fluorene group in at least one of Arₐ or Ar_{b}.

The compound represented by Formula H-1 may be represented by any one selected from the compounds of Compound Group H. However, the compounds listed in Compound Group H are examples, and the compounds represented by Formula H-1 are not limited to those represented by Compound Group H:

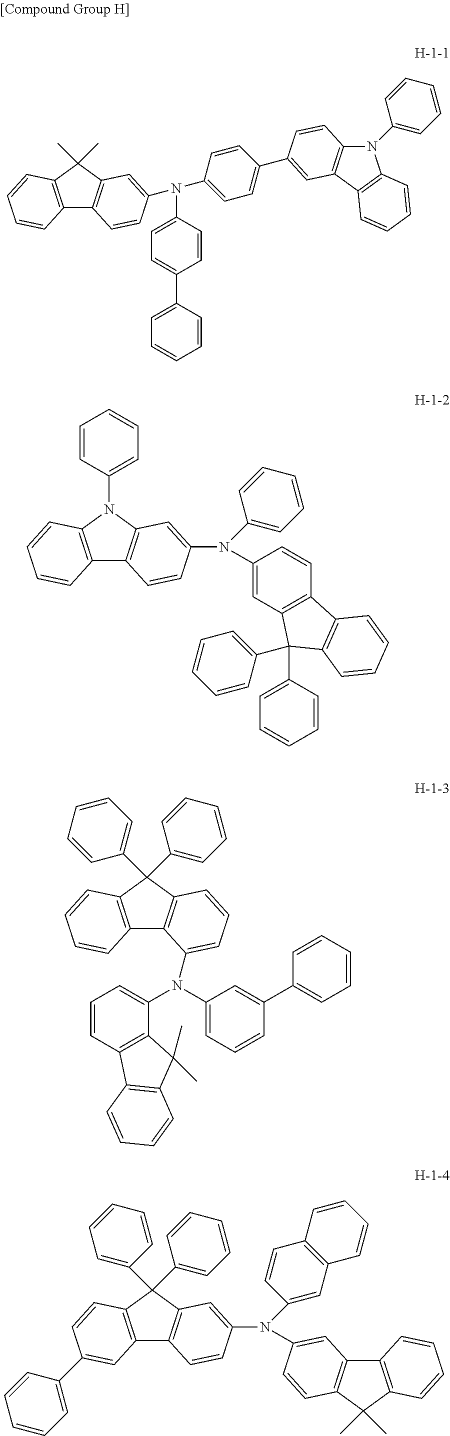 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

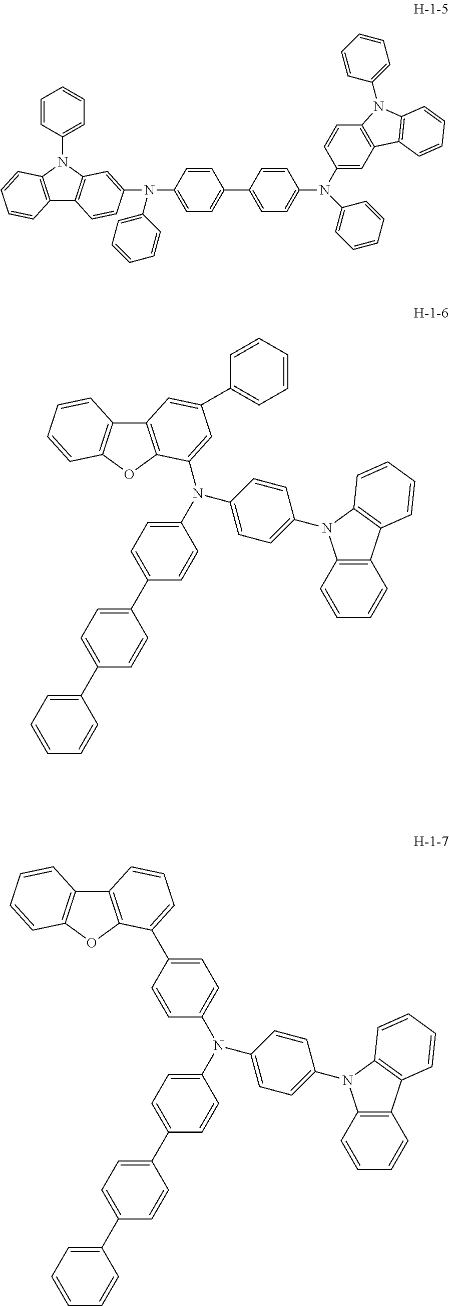 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

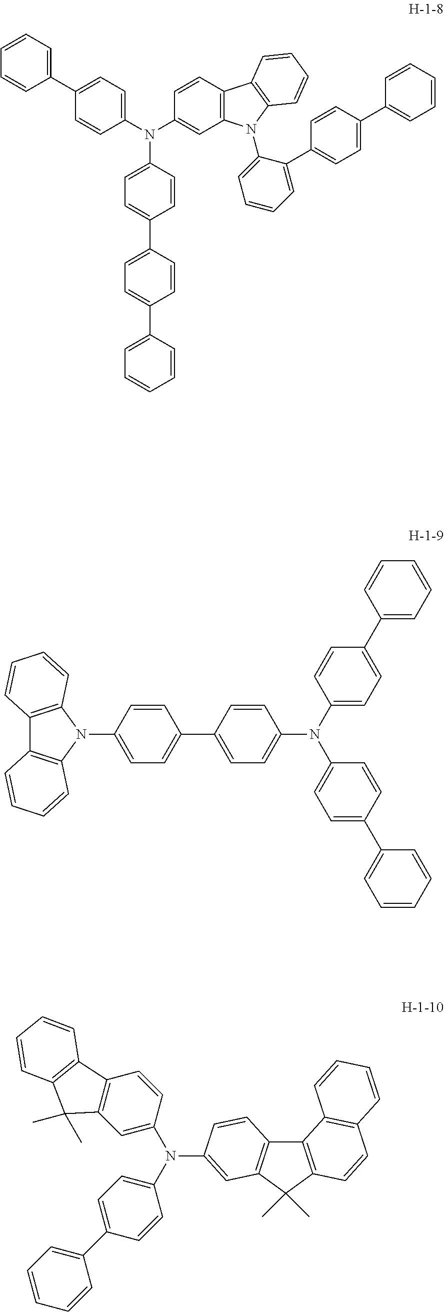 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

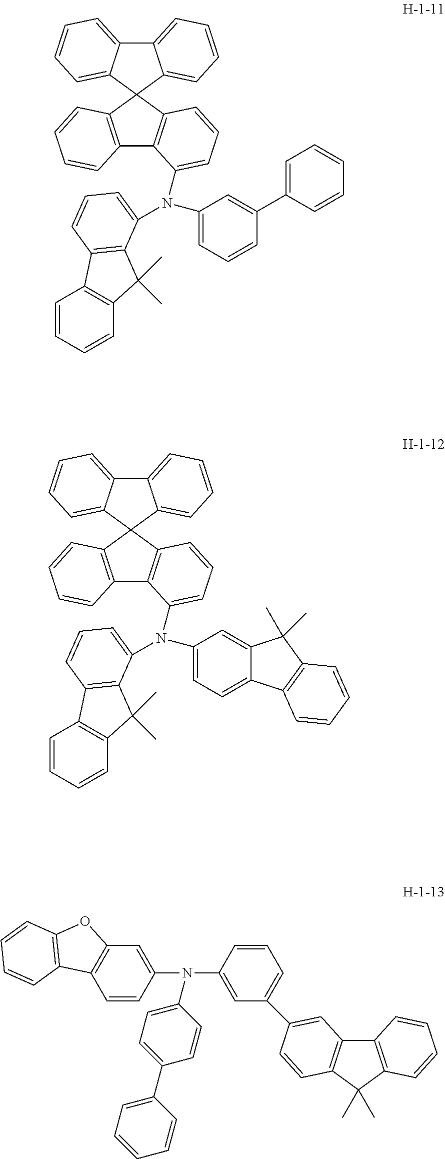 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

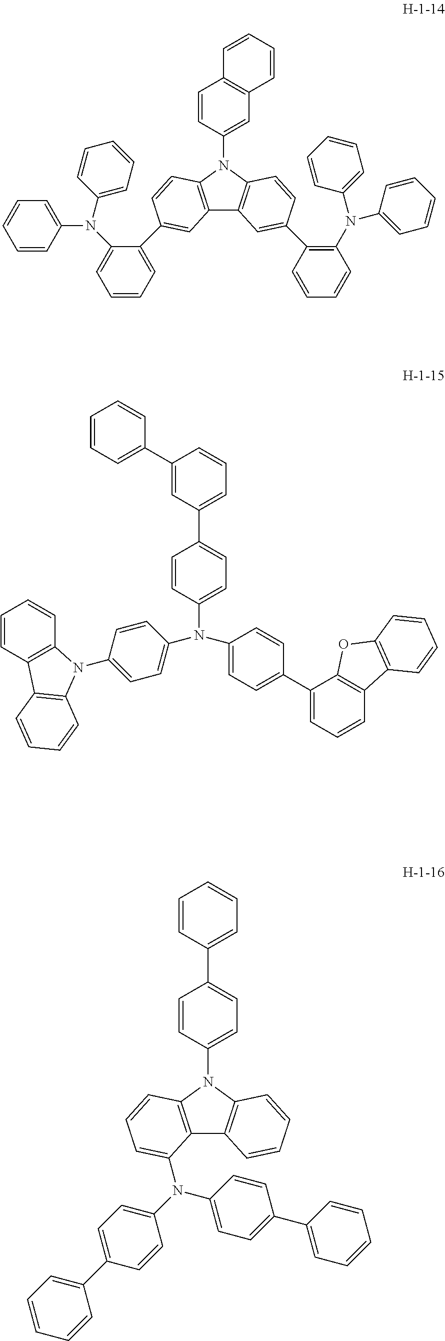 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

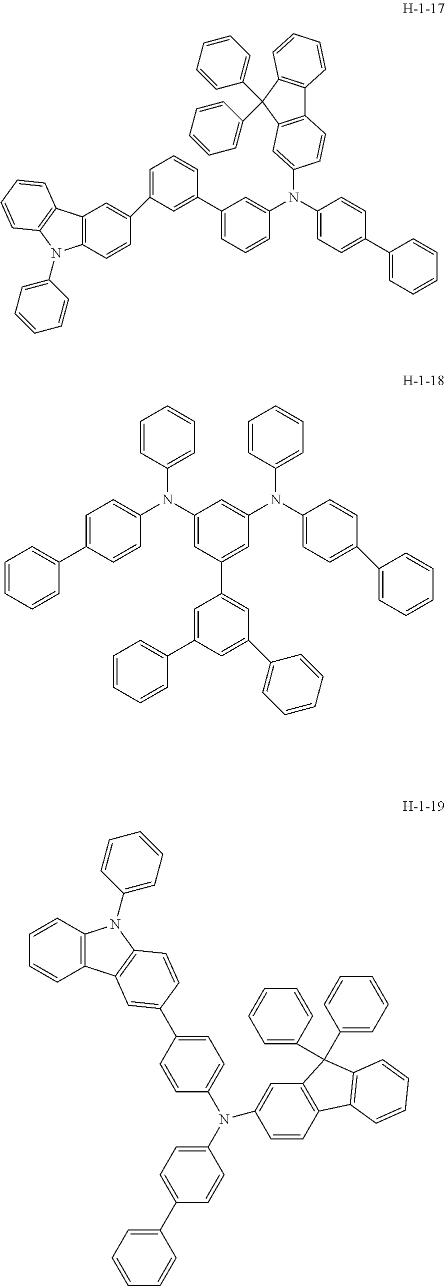 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

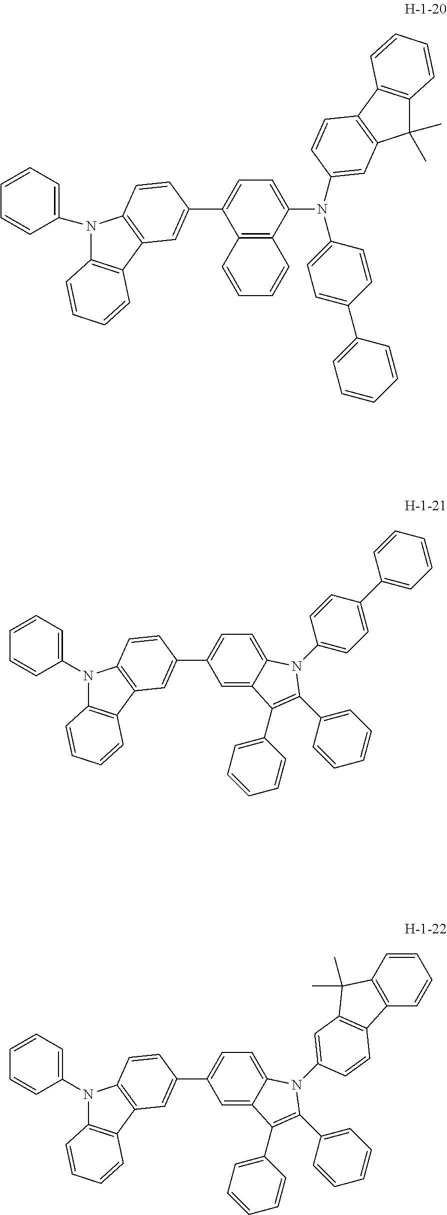 [SMILES: CC1(C)c2ccccc2-c2ccc(N(c3ccc(-c4ccccc4)cc3)c3ccc(-c4ccc5c(c4)c4ccccc4n5-c4ccccc4)c4ccccc34)cc21 ; c1ccc(-c2ccc(-n3c(-c4ccccc4)c(-c4ccccc4)c4cc(-c5ccc6c(c5)c5ccccc5n6-c5ccccc5)ccc43)cc2)cc1 ; CC1(C)c2ccccc2-c2ccc(-n3c(-c4ccccc4)c(-c4ccccc4)c4cc(-c5ccc6c(c5)c5ccccc5n6-c5ccccc5)ccc43)cc21]

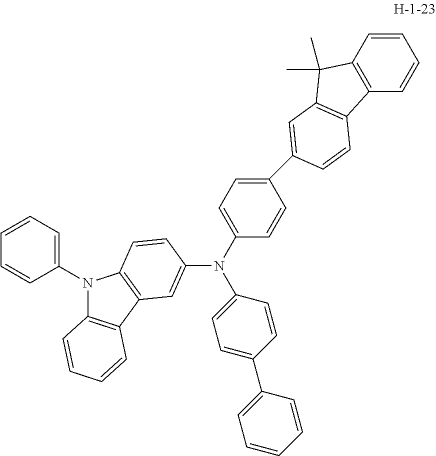 [SMILES: CC1(C)c2ccccc2-c2ccc(-c3ccc(N(c4ccc(-c5ccccc5)cc4)c4ccc5c(c4)c4ccccc4n5-c4ccccc4)cc3)cc21]

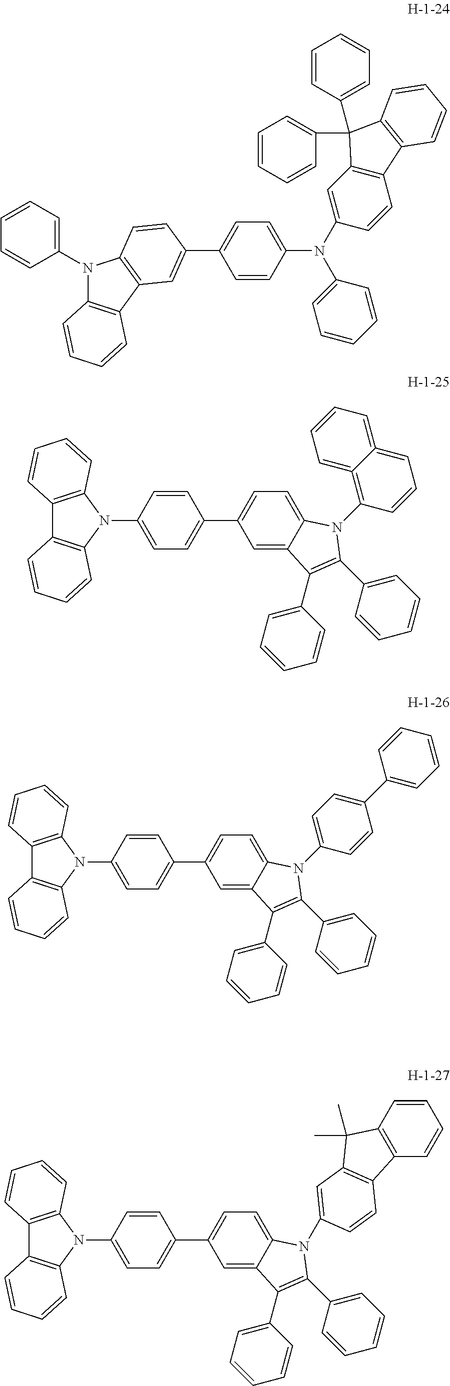

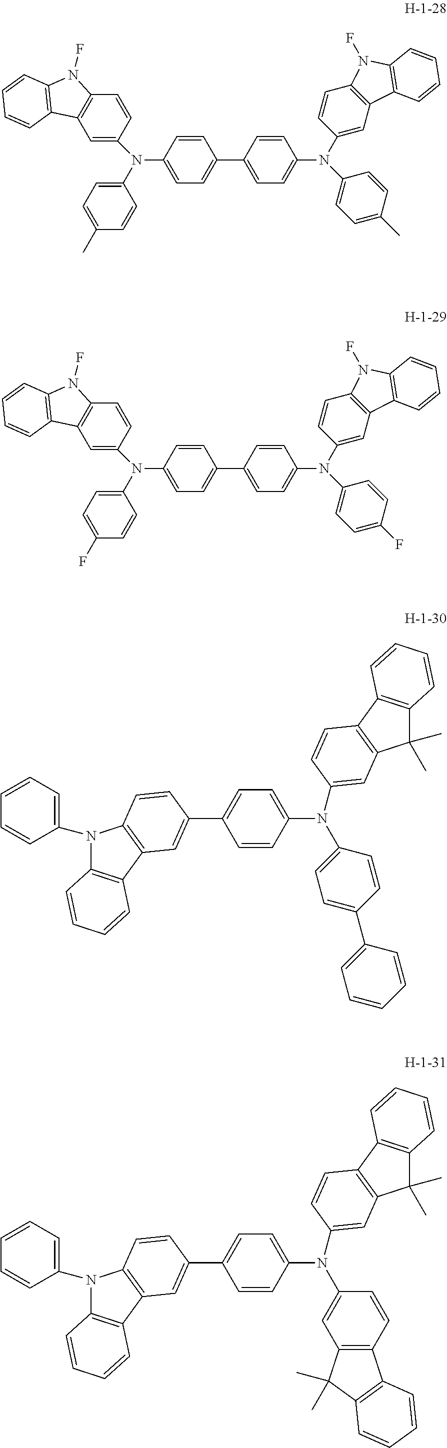 [SMILES: Cc1ccc(N(c2ccc(-c3ccc(N(c4ccc(C)cc4)c4ccc5c(c4)c4ccccc4n5F)cc3)cc2)c2ccc3c(c2)c2ccccc2n3F)cc1 ; Fc1ccc(N(c2ccc(-c3ccc(N(c4ccc(F)cc4)c4ccc5c(c4)c4ccccc4n5F)cc3)cc2)c2ccc3c(c2)c2ccccc2n3F)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

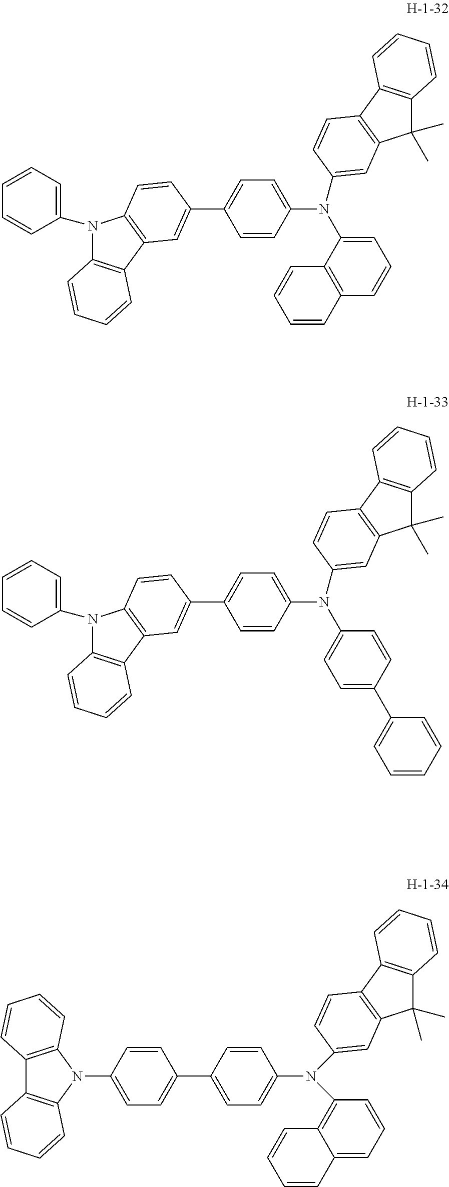 [SMILES: CC1(C)c2ccccc2-c2ccc(N(c3ccc(-c4ccc5c(c4)c4ccccc4n5-c4ccccc4)cc3)c3cccc4ccccc34)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccc(-n5c6ccccc6c6ccccc65)cc4)cc3)c3cccc4ccccc34)cc21]

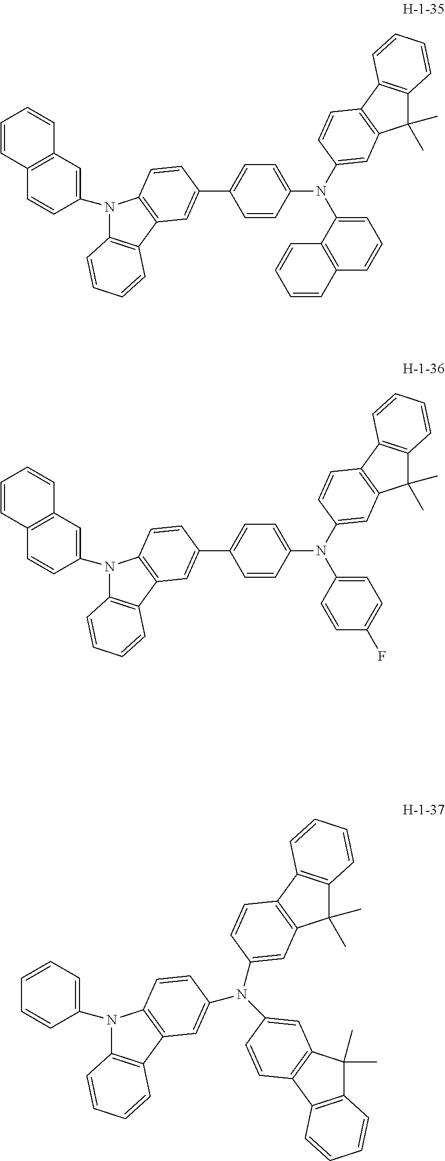 [SMILES: CC1(C)c2ccccc2-c2ccc(N(c3ccc(-c4ccc5c(c4)c4ccccc4n5-c4ccc5ccccc5c4)cc3)c3cccc4ccccc34)cc21 ; CC1(C)c2ccccc2-c2ccc(N(c3ccc(F)cc3)c3ccc(-c4ccc5c(c4)c4ccccc4n5-c4ccc5ccccc5c4)cc3)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

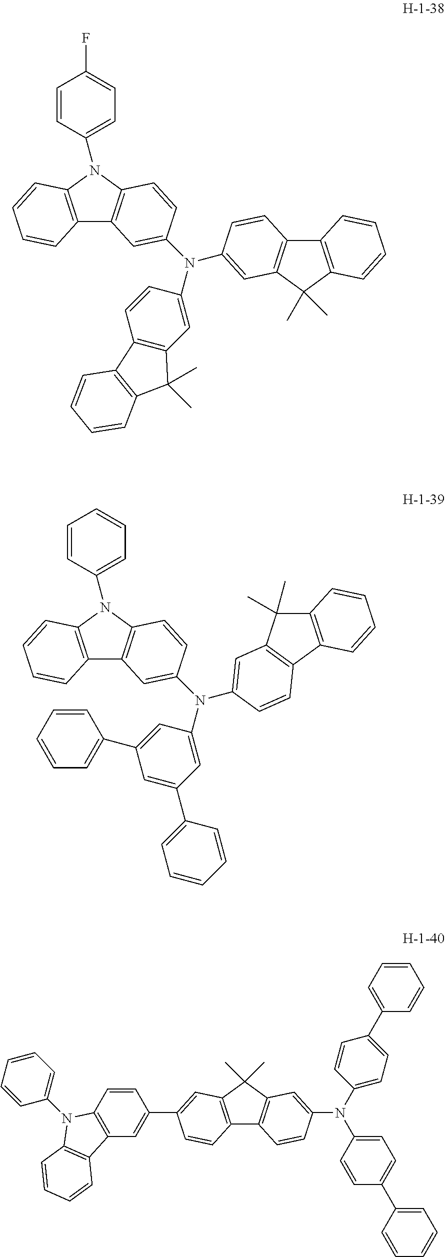 [SMILES: CC1(C)c2ccccc2-c2ccc(N(c3ccc4c(c3)C(C)(C)c3ccccc3-4)c3ccc4c(c3)c3ccccc3n4-c3ccc(F)cc3)cc21 ; CC1(C)c2ccccc2-c2ccc(N(c3cc(-c4ccccc4)cc(-c4ccccc4)c3)c3ccc4c(c3)c3ccccc3n4-c3ccccc3)cc21 ; CC1(C)c2cc(-c3ccc4c(c3)c3ccccc3n4-c3ccccc3)ccc2-c2ccc(N(c3ccc(-c4ccccc4)cc3)c3ccc(-c4ccccc4)cc3)cc21]

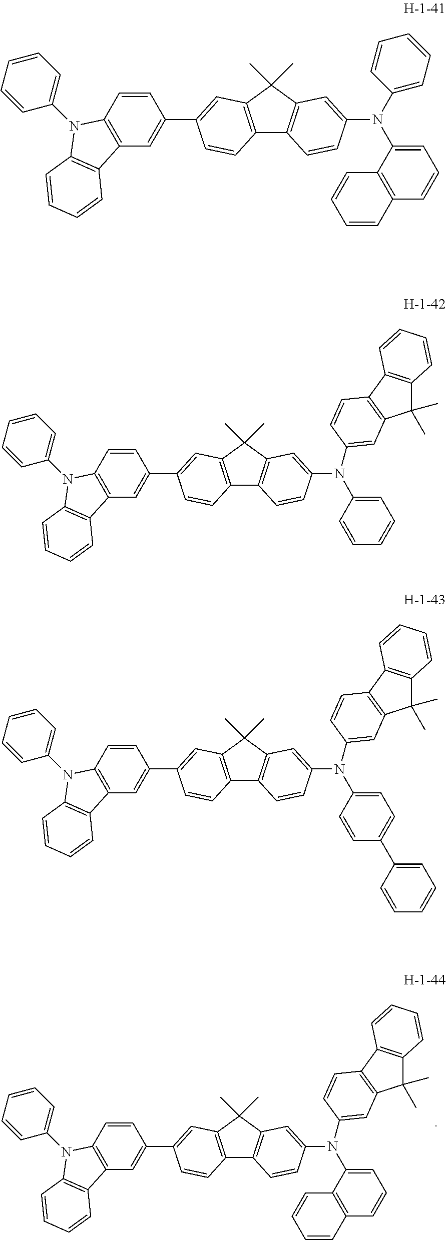 [SMILES: CC1(C)c2cc(-c3ccc4c(c3)c3ccccc3n4-c3ccccc3)ccc2-c2ccc(N(c3ccccc3)c3cccc4ccccc34)cc21 ; CC1(C)c2ccccc2-c2ccc(N(c3ccccc3)c3ccc4c(c3)C(C)(C)c3cc(-c5ccc6c(c5)c5ccccc5n6-c5ccccc5)ccc3-4)cc21 ; CC1(C)c2ccccc2-c2ccc(N(c3ccc(-c4ccccc4)cc3)c3ccc4c(c3)C(C)(C)c3cc(-c5ccc6c(c5)c5ccccc5n6-c5ccccc5)ccc3-4)cc21 ; CC1(C)c2ccccc2-c2ccc(N(c3ccc4c(c3)C(C)(C)c3cc(-c5ccc6c(c5)c5ccccc5n6-c5ccccc5)ccc3-4)c3cccc4ccccc34)cc21]

The first to fourth hole transport layers HTL1, HTL2, HTL3, and HTL4 of the present disclosure may include the compound represented by Formula H-1, thereby exhibiting excellent or improved hole mobility.

In some embodiments, the hole transport region HTR may further include a suitable hole transport material.

For example, the hole transport region HTR may include a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (mDCP), etc.

The hole transport region HTR may include any of the above-described compounds of the hole transport region in at least one of the hole injection layer HIL, the plurality of hole transport layers HTL1, HTL2, HTL3, and HTL4, or the electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer, the hole transport layer may have a thickness of about 30 Å to about 2,000 Å. For example, each of the plurality of hole transport layers HTL1, HTL2, HTL3, and HTL4 may have a thickness of about 30 Å to about 2,000 Å.

For example, when the hole transport region HTR includes the electron blocking layer EBL, the electron blocking layer EBL may have a thickness of about 10 Å to about 1,000 Å. If the thicknesses of the hole transport region HTR, the hole injection layer HIL, the hole transport layer HTL and/or the electron blocking layer EBL satisfy their respective above-described ranges, satisfactory or suitable hole transport properties may be achieved without a substantial increase in driving voltage.

The hole transport region HTR may further include a charge generating material to increase conductivity in addition to the above-described materials. The charge generating material may be dispersed substantially uniformly or substantially non-uniformly in the hole transport region HTR. In one or more embodiments, any one selected from the plurality of hole transport layers HTL1, HTL2, HTL3, and HTL4 may include a charge generating material.

The charge generating material may be, for example, a p-dopant. The p-dopant may include at least one of a halogenated metal compound, a quinone derivative, a metal oxide, or a cyano group-containing compound, but one or more embodiments of the present disclosure is not limited thereto. For example, the p-dopant may include a metal halide compound such as CuI and/or RbI, a quinone derivative such as tetracyanoquinodimethane (TCNQ) and/or 2,3,5,6-tetrafluoro-7,7′8,8-tetracyanoquinodimethane (F4-TCNQ), a metal oxide such as tungsten oxide and/or molybdenum oxide, a cyano group-containing compound such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but one or more embodiments of the present disclosure is not limited thereto.

In one or more embodiments, the hole transport region HTR may further include at least one of the buffer layer or the electron blocking layer EBL, in addition to the hole injection layer HIL and the plurality of hole transport layers HTL1, HTL2, HTL3, and HTL4. The buffer layer may compensate for a resonance distance according to the wavelength of light emitted from the emission layer EML and may thus increase light emission efficiency. A material that may be included in the hole transport region HTR may be used as a material to be included in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In the light emitting element ED of one or more embodiments, the emission layer EML may include an anthracene derivative, a pyrene derivative, a fluoranthene derivative, a chrysene derivative, a dihydrobenzanthracene derivative, or a triphenylene derivative. For example, the emission layer EML may include the anthracene derivative and/or the pyrene derivative.

In each of the light emitting elements ED of embodiments illustrated in FIGS. 3 to 9, the emission layer EML may include a host and a dopant, and the emission layer EML may include a compound represented by Formula E-1. The compound represented by Formula E-1 may be used as a fluorescent host material.

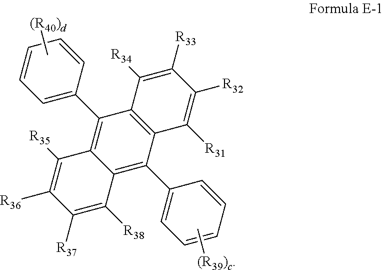

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may be each independently an integer of 0 to 5.

Formula E-1 may be represented by any one selected from Compound E1 to Compound F19:

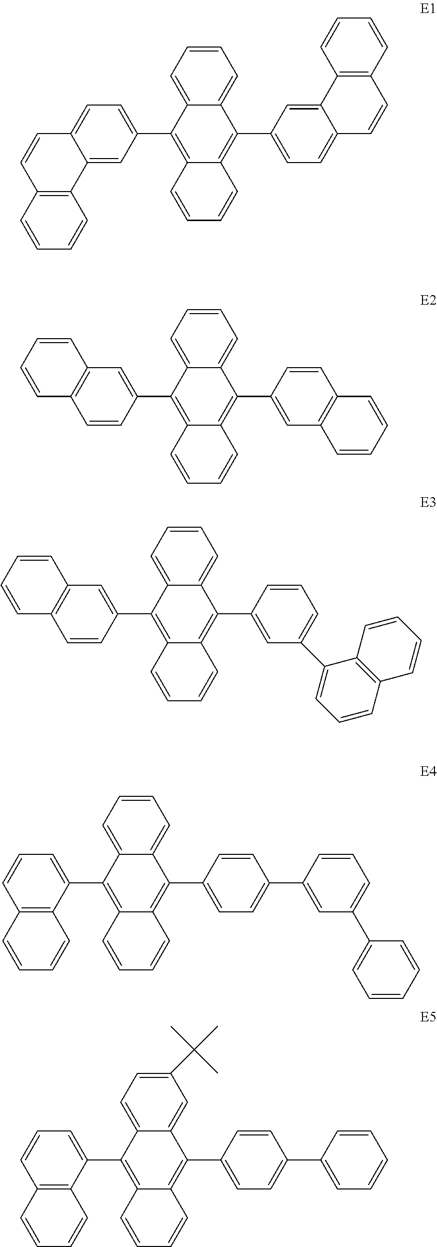

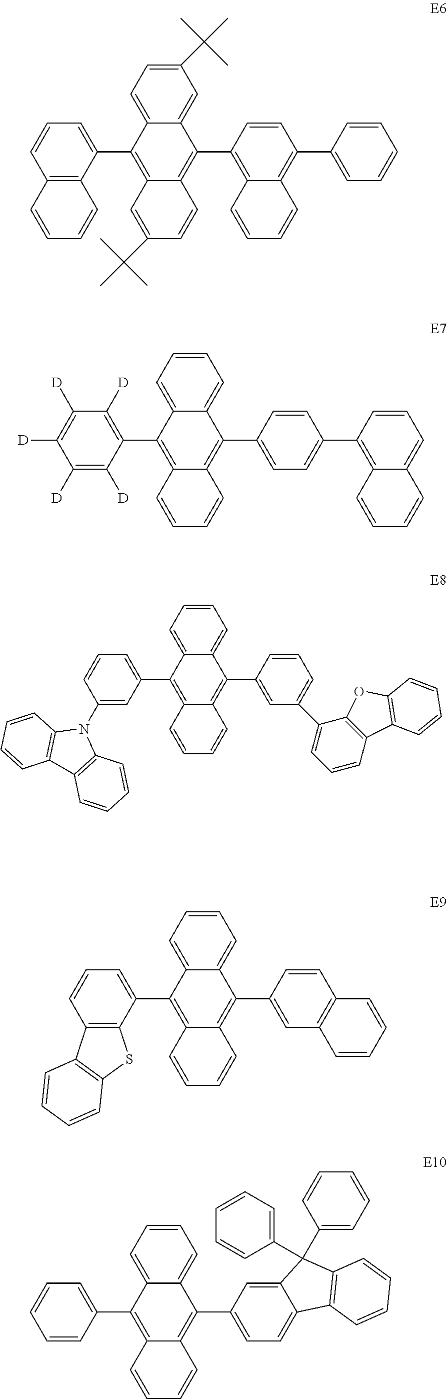

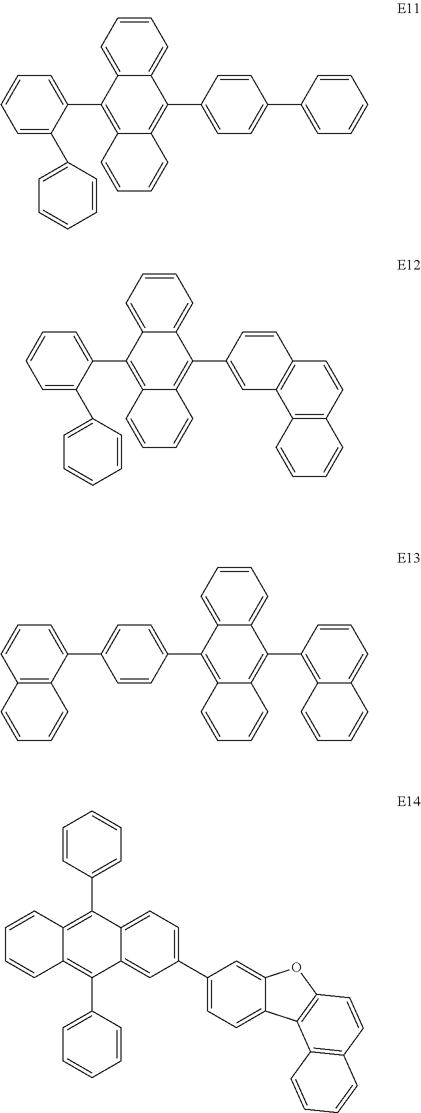

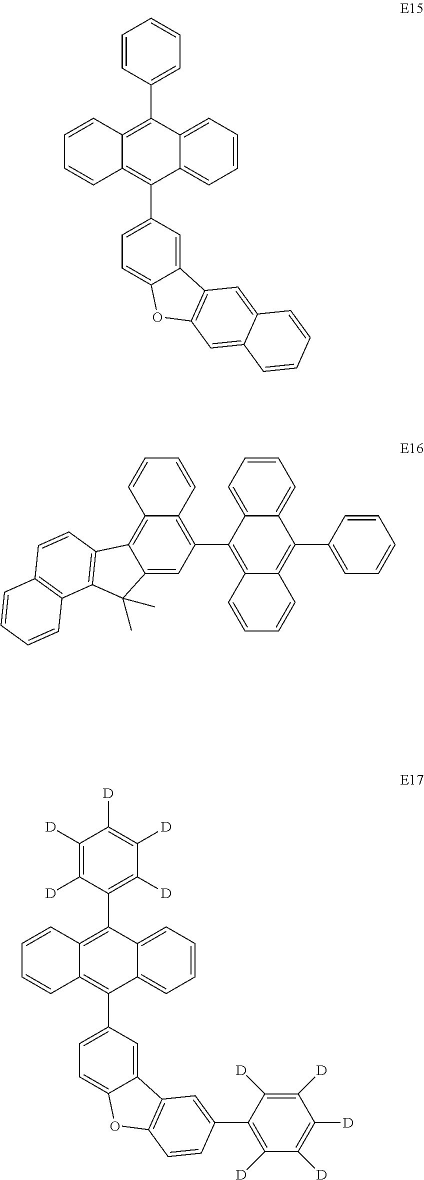

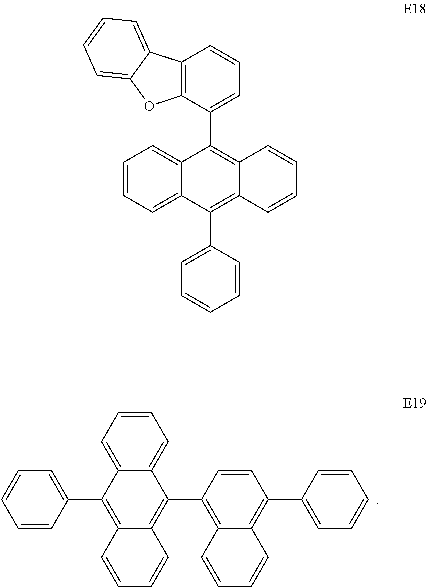

In one or more embodiments, the emission layer EML may include a compound represented by Formula E-2a or Formula E-2b. The compound represented by Formula E-2a or Formula E-2b may be used as a phosphorescent host material.

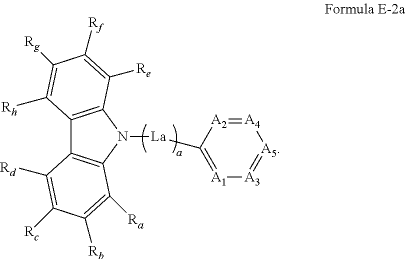

In Formula E-2a, a may be an integer of 0 to 10, Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is an integer of 2 or more, a plurality of Lₐ's may be each independently a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a heterocycle containing N, O, S, etc., as a ring-forming atom.

In Formula E-2a, two or three selected from A₁ to A₅ may be N, and the rest may be CRᵢ.

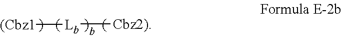

In Formula E-2b, Cbz1 and Cbz2 may be each independently an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. b is an integer of 0 to 10, and when b is an integer of 2 or more, a plurality of L_{b}'s may be each independently a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from the compounds of Compound Group E-2. However, the compounds listed in Compound Group E-2 are examples, and the compound represented by Formula E-2a or Formula E-2b is not limited to those represented in Compound Group E-2.

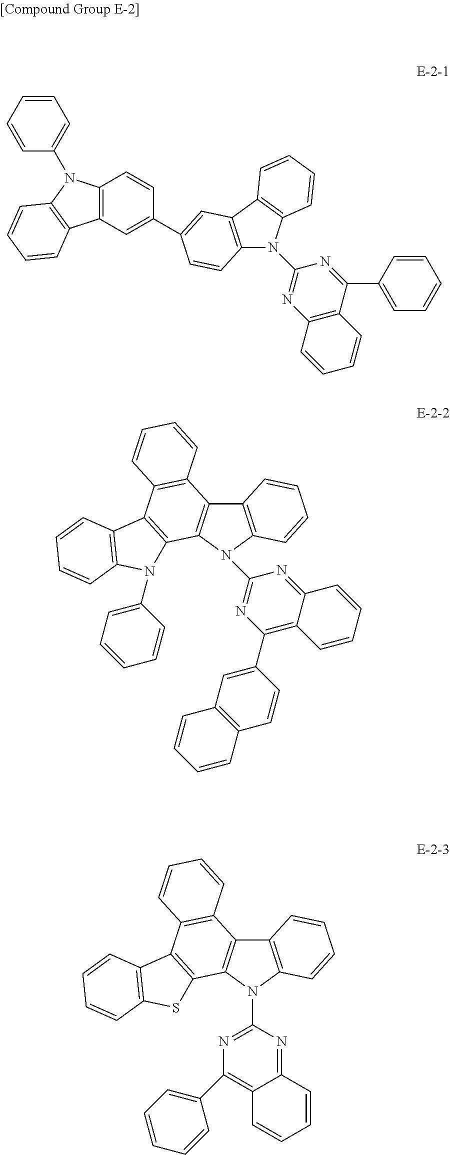 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

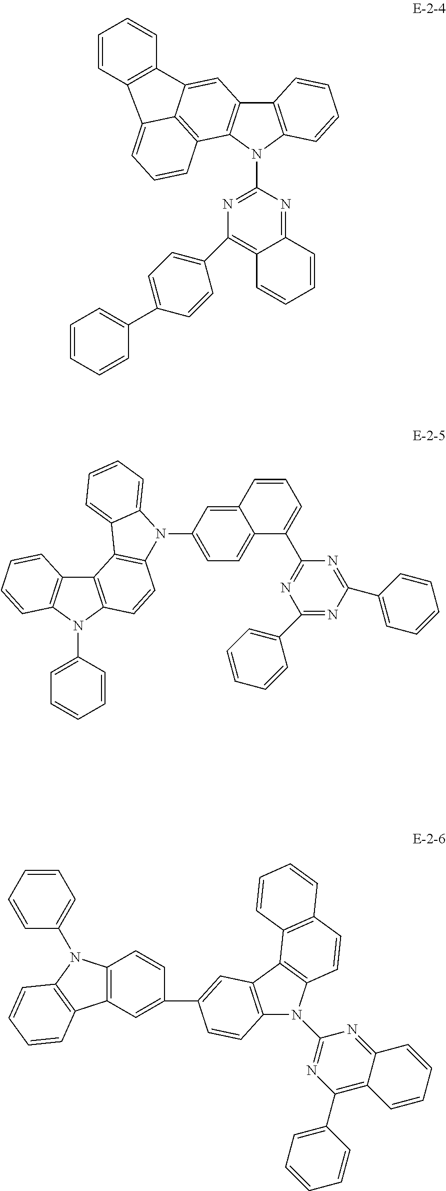 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

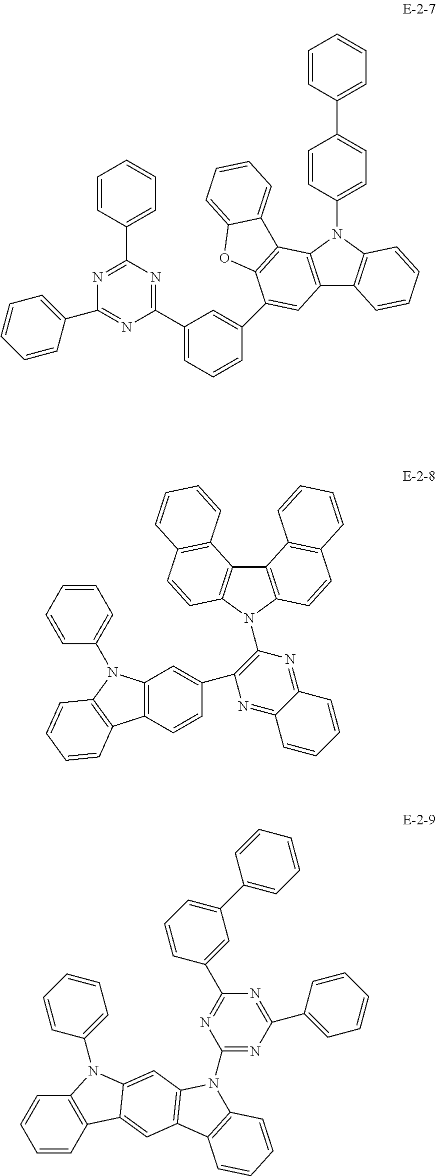 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

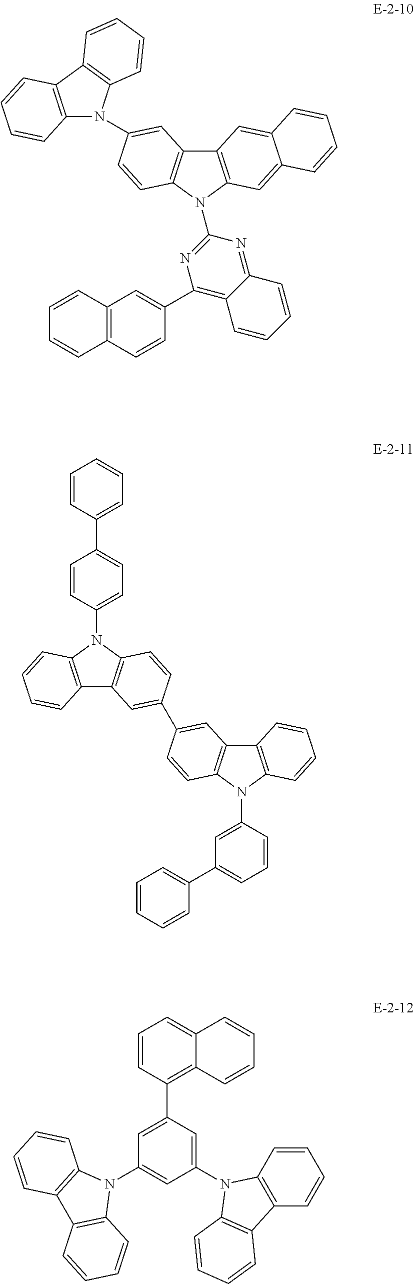 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

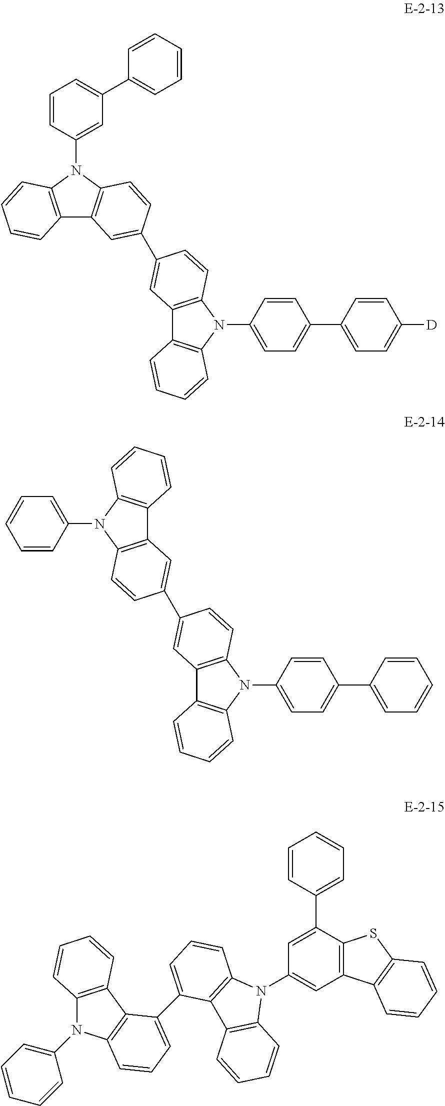 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

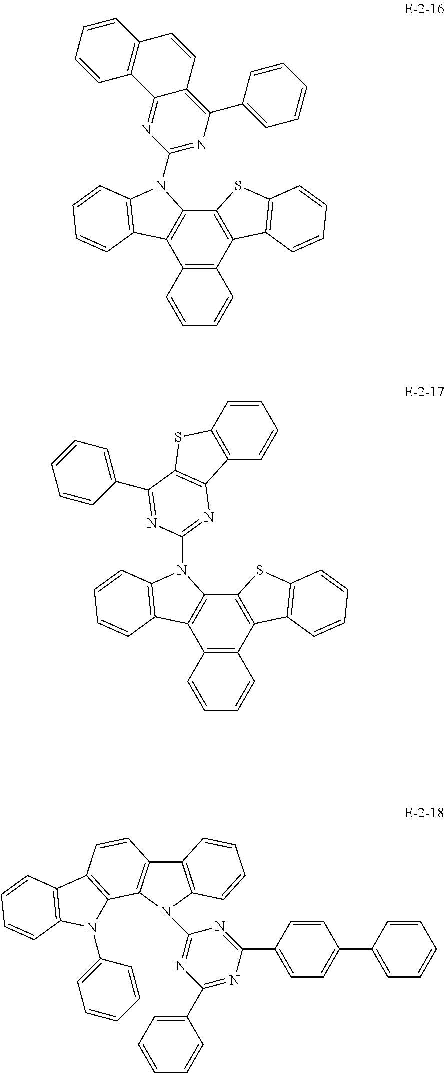 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

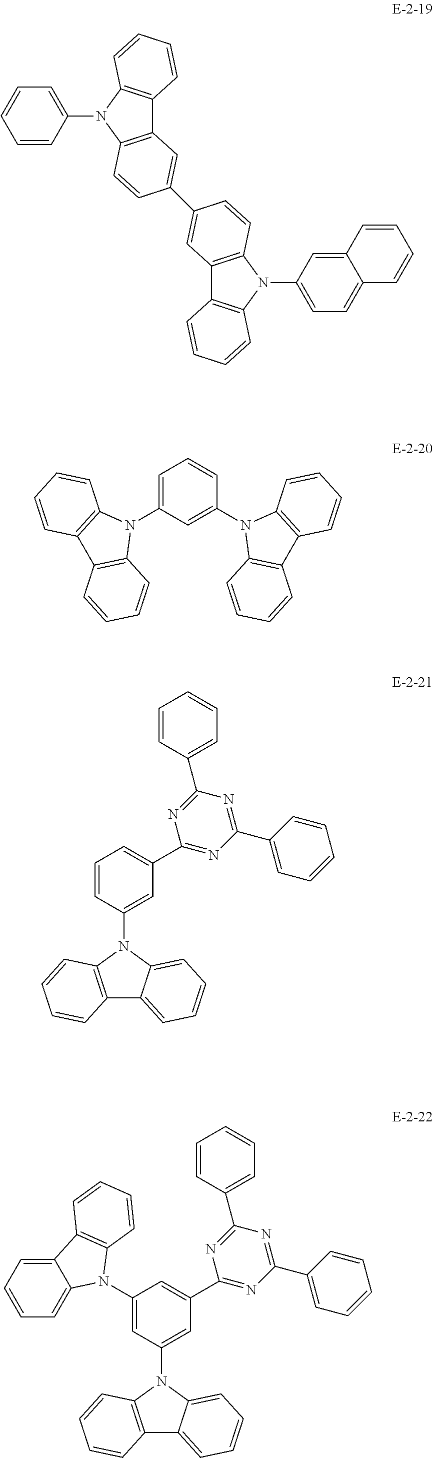 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

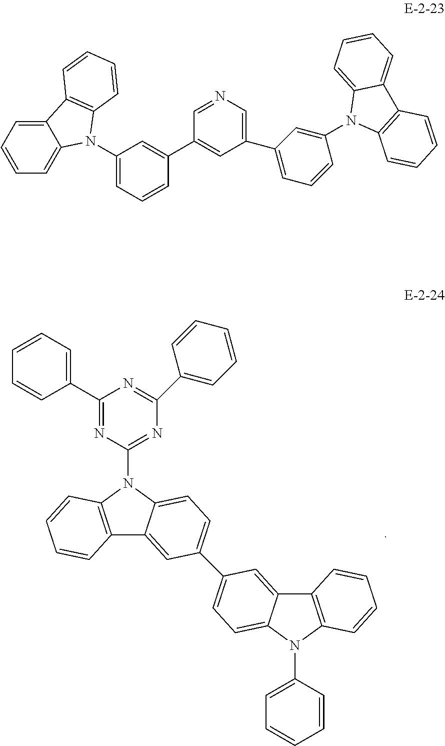 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a suitable host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, one or more embodiments of the present disclosure is not limited thereto, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc., may be used as a host material.

The emission layer EML may include a compound represented by Formula M-a or Formula M-b. The compound represented by Formula M-a or Formula M-b may be used as a phosphorescent dopant material.

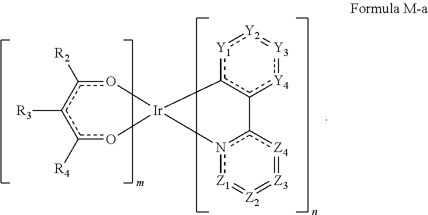

In Formula M-a, Y₁ to Y₄ and Z₁ to Z₄ may be each independently CR₁ or N, R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be used as a phosphorescent dopant.

The compound represented by Formula M-a may be represented by any one selected from Compound M-a1 to Compound M-a25. However, Compounds M-a1 to M-a25 are examples, and the compound represented by Formula M-a is not limited to those represented by Compounds M-a1 to M-a25.

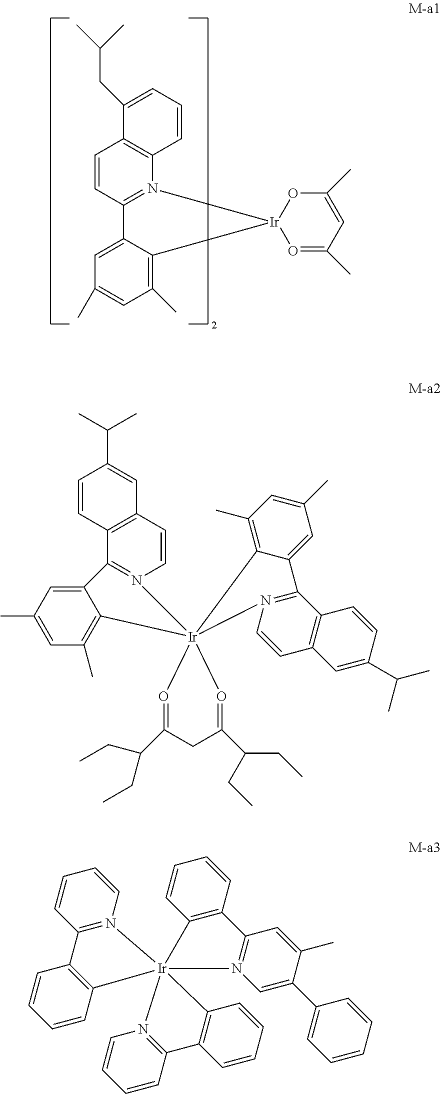

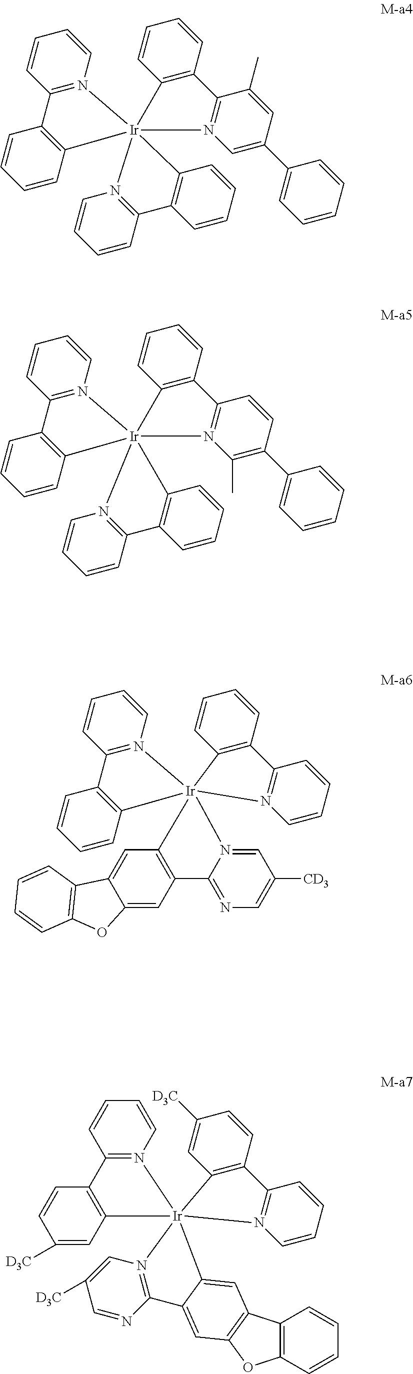

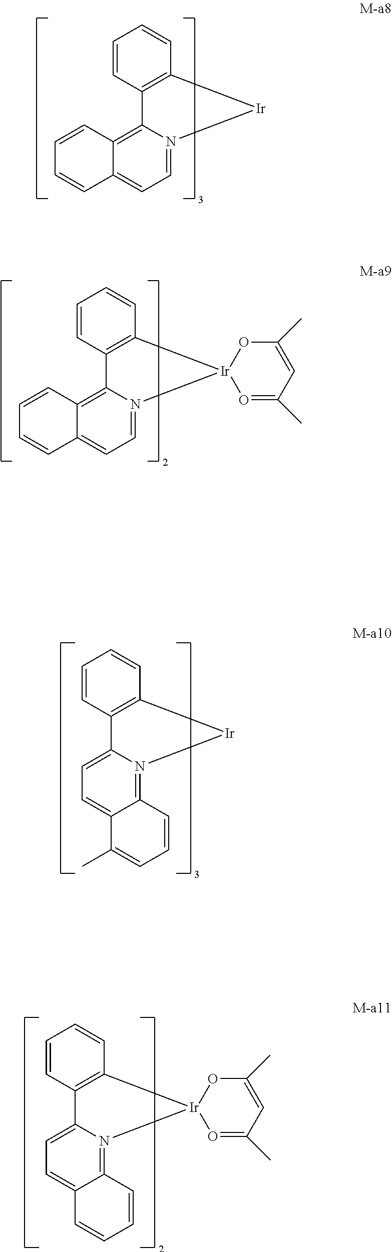

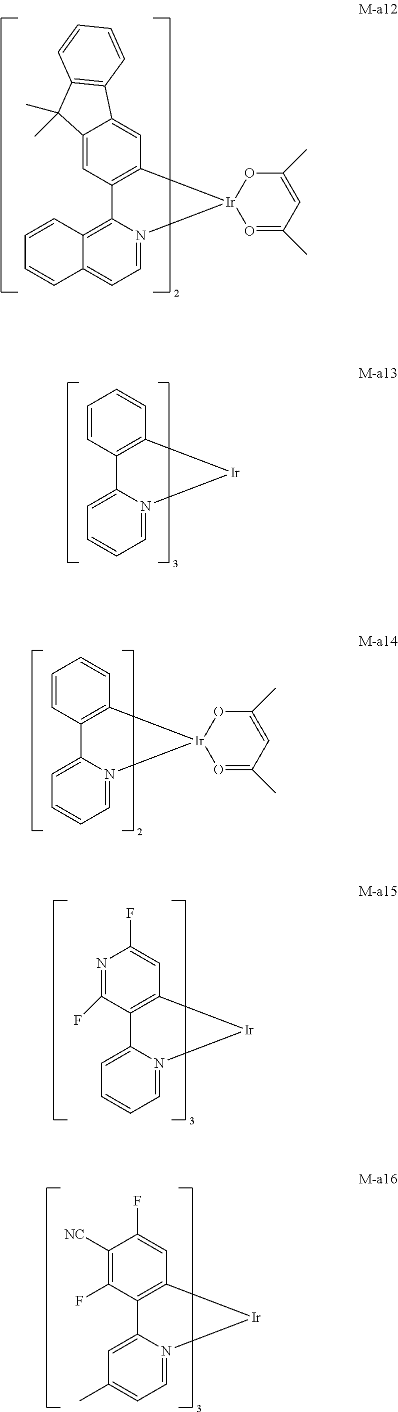

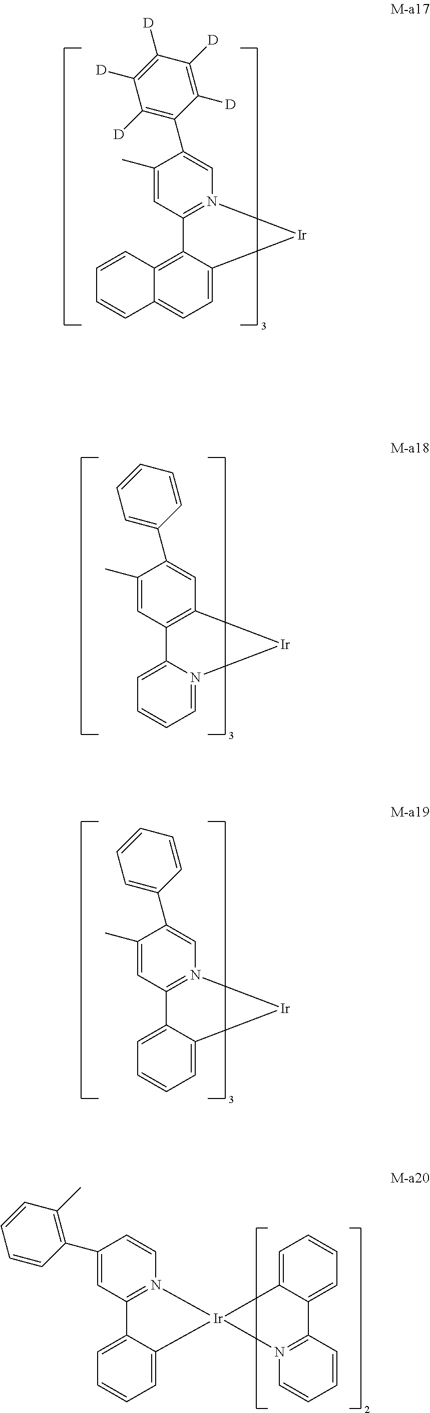

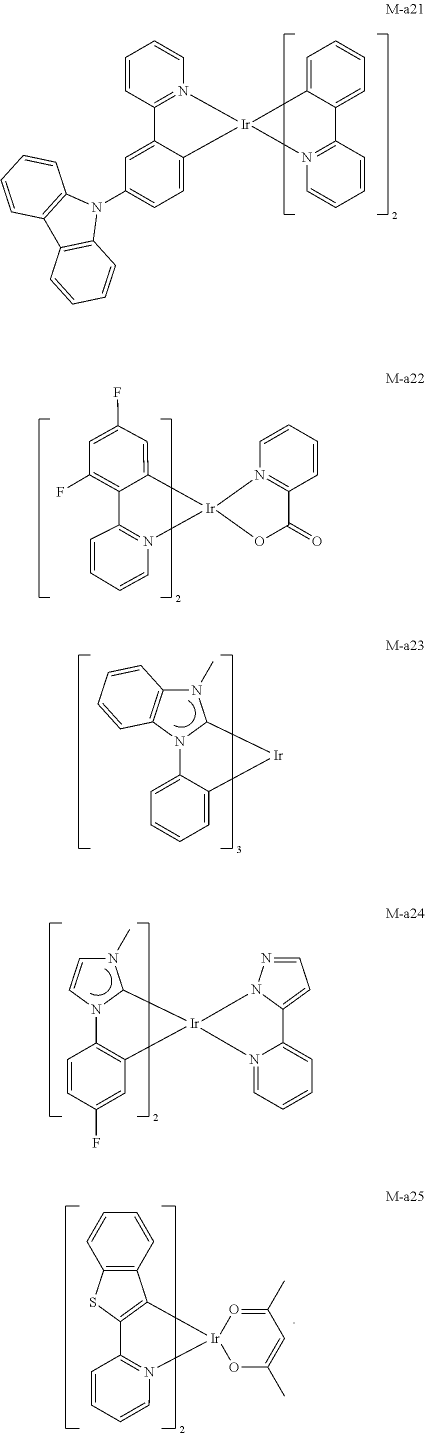

Compound M-a1 and Compound M-a2 may be used as a red dopant material, and Compound M-a3 to Compound M-a7 may be used as a green dopant material.

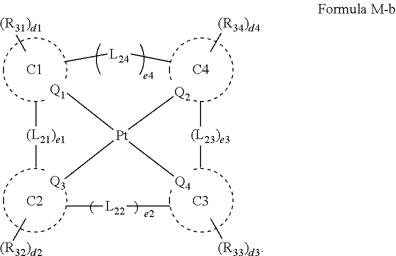

In Formula M-b, Q₁ to Q₄ are each independently C or N, and C₁ to C₄ are each independently a substituted or unsubstituted hydrocarbon ring having 5 to 30 ring-forming carbon atoms, or a substituted or unsubstituted heterocycle having 2 to 30 ring-forming carbon atoms. L₂₁ to L₂₄ are each independently a direct linkage,

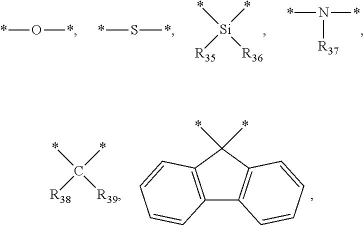

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and e1 to e4 are each independently 0 or 1. R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring, and d1 to d4 are each independently an integer of 0 to 4.

The compound represented by Formula M-b may be used as a blue phosphorescent dopant or a green phosphorescent dopant.

The compound represented by Formula M-b may be represented by any one selected from Compounds M-b-1 to M-b-11. However, the following compounds are examples, and the compounds represented by Formula M-b are not limited to Compounds M-b-1 to M-b-11:

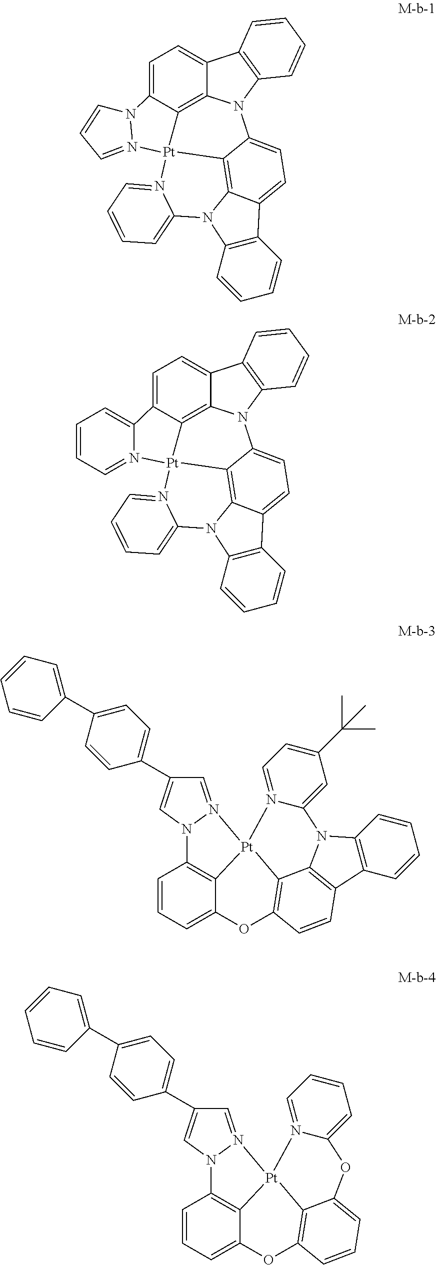

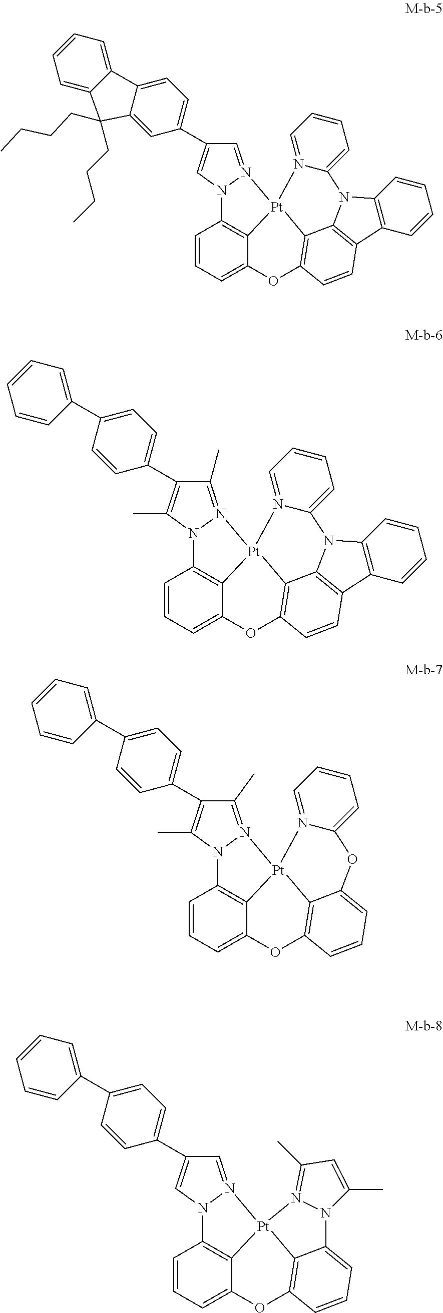

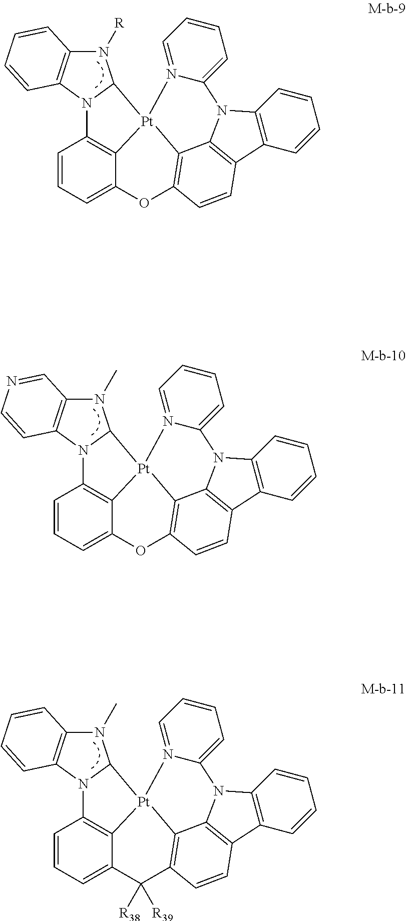

In the compounds above, R, R₃₈, and R₃₉ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may include a compound represented by any one selected from Formula F-a to Formula F-c. The compound represented by Formula F-a or Formula F-c may be used as a fluorescence dopant material.

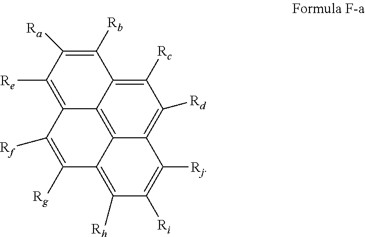

In Formula F-a, two selected from Rₐ to Rⱼ may each independently be substituted with *—NAr₁Ar₂. The others, which are not substituted with *—NAr₁Ar₂, selected from Rₐ to Rⱼ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

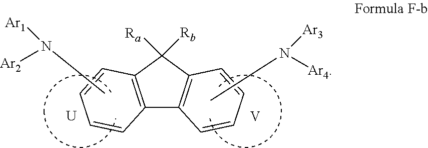

In Formula F-b, Ar₁ to Ar₄ may be each independently a substituted or unsubstituted aryl group having 6 to 30 ring-forming carbon atoms, or a substituted or unsubstituted heteroaryl group having 2 to 30 ring-forming carbon atoms.

In Formula F-b, Rₐ and R_{b} may be each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In Formula F-b, U and V may be each independently a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may be each independently 0 or 1. For example, in Formula F-b, it means that when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

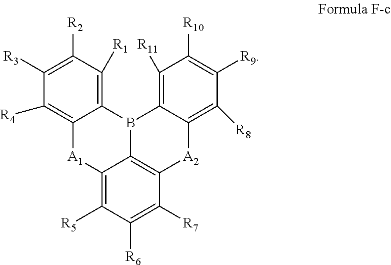

In Formula F-c, A₁ and A₂ may be each independently O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring.

In Formula F-c, A₁ and A₂ may each independently be bonded to substituents of an adjacent ring to form a condensed ring. For example, when A₁ and A₂ are each independently NRₘ, A₁ may be bonded to R₄ or R₅ to form a ring. In some embodiments, A₂ may be bonded to R₇ or R₈ to form a ring.

In one or more embodiments, the emission layer EML may include, as a suitable dopant material, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and/or N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene and/or a derivative thereof (e.g., 2,5,8,11-tetra-t-butylperylene (TBP)), pyrene and/or a derivative thereof (e.g., 1,1-dipyrene, 1,4-dipyrenylbenzene, 1,4-bis(N,N-diphenylamino)pyrene), etc.

The emission layer EML may include a suitable phosphorescent dopant material. For example, a metal complex containing iridium (Ir), platinum (Pt), osmium (Os), aurum (Au), titanium (Ti), zirconium (Zr), hafnium (Hf), europium (Eu), terbium (Tb), and/or thulium (Tm) may be used as a phosphorescent dopant. For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), and/or platinum octaethyl porphyrin (PtOEP) may be used as a phosphorescent dopant. However, one or more embodiments of the present disclosure is not limited thereto.

The emission layer EML may include a quantum dot material. The core of the quantum dot may be selected from a Group II-VI compound, a Group III-VI compound, a Group I-III-IV compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and/or In₂Se₃, a ternary compound such as InGaS₃ and/or InGaSes, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof; or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; and a quaternary compound selected from the group consisting of GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and a mixture thereof. The Group III-V compound may further include a Group II metal. For example, InZnP, etc., may be selected as a Group III-II-V compound.

The Group IV-VI compound may be selected from the group consisting of a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound, and/or the quaternary compound may be present in a particle with a substantially uniform concentration distribution, or may be present in the same particle with a partially different concentration distribution. In some embodiments, the quantum dot may have a core/shell structure in which one quantum dot surrounds the other quantum dot. The core/shell structure may have a concentration gradient in which the concentration of elements present in the shell decreases toward the core.

In some embodiments, the quantum dot may have the above-described core/shell structure including a core containing nanocrystals and a shell surrounding the core. The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An example of the shell of the quantum dot may include a metal oxide, a non-metal oxide, a semiconductor compound, or a combination thereof.

For example, examples of the metal oxide and the non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and a ternary compound such as MgAl₂O₄, CoFe₂O₄, NiFe₂O₄, and/or CoMn₂O₄, but one or more embodiments of the present disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but one or more embodiments of the present disclosure is not limited thereto.

The quantum dot may have a full width of half maximum (FWHM) of a light emitting wavelength spectrum of about 45 nm or less, for example, about 40 nm or less, or about 30 nm or less, and color purity and/or color reproducibility may be improved in the above range. In some embodiments, light emitted through such a quantum dot is emitted in all directions, and thus a wide viewing angle may be improved.

In some embodiments, although the form of the quantum dot is not particularly limited as long as it is a suitable form, for example, the quantum dot in the form of spherical, pyramidal, multi-arm, and/or cubic nanoparticles, nanotubes, nanowires, nanofibers, nanoplate particles, etc., may be used.

The quantum dot may control the color of emitted light according to the particle size thereof. Accordingly, the quantum dot may have various light emission colors such as blue, red, and/or green.

In each of the light emitting elements ED of embodiments illustrated in FIGS. 3 to 9, the electron transport region ETR is provided on the emission layer EML. The electron transport region ETR may include at least one of the hole blocking layer HBL, the electron transport layer ETL, or the electron injection layer EIL, but one or more embodiments of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but one or more embodiments of the present disclosure is not limited thereto. The electron transport region ETR may have a thickness, for example, from about 1,000 Å to about 1,500 Å.

The electron transport region ETR may be formed by using one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1:

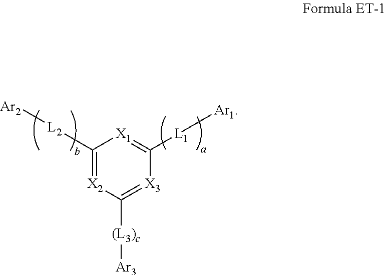

In Formula ET-1, at least one selected from X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may be each independently an integer of 0 to 10. In Formula ET-1, L₁ to L₃ may be each independently a direct linkage, a substituted or unsubstituted arylene group having 6 to 30 ring-forming carbon atoms, or a substituted or unsubstituted heteroarylene group having 2 to 30 ring-forming carbon atoms. When a to c are an integer of 2 or more, L₁ to L₃ may be each independently a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, one or more embodiments of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-Bis[3,5-di(pyridin-3-yl)phenyl]benzene (BmPyPhB), or a mixture thereof.

In some embodiments, the electron transport regions ETR may include a metal halide such as LiF, NaCl, CsF, RbCl, RbI, CuI, and/or KI, a lanthanide metal such as Yb, and/or a co-deposited material of the metal halide and the lanthanide metal. For example, the electron transport region ETR may include KI:Yb, RbI:Yb, LiF:Yb, etc., as a co-deposited material. In one or more embodiments, the electron transport region ETR may be formed using a metal oxide such as Li₂O and/or BaO, and/or 8-hydroxyl-lithium quinolate (Liq), etc., but one or more embodiments of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the-described materials, but one or more embodiments of the present disclosure is not limited thereto.

The electron transport region ETR may include the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. If the thickness of the electron transport layer ETL satisfies the aforementioned range, satisfactory or suitable electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. If the thickness of the electron injection layer EIL satisfies the above-described range, satisfactory or suitable electron injection characteristics may be obtained without a substantial increase in driving voltage.

The second electrode EL2 is provided on the electron transport region ETR. The second electrode EL2 may be a common electrode. The second electrode EL2 may be a cathode or an anode, but one or more embodiments of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, and/or MgAg). In one or more embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include any of the above-described metal materials, combinations of at least two metal materials of any of the above-described metal materials, oxides of any of the above-described metal materials, and/or the like.

In some embodiments, the second electrode EL2 may be connected with an auxiliary electrode. If the second electrode EL2 is connected with the auxiliary electrode, the resistance of the second electrode EL2 may be decreased.

A capping layer CPL may further be provided on the second electrode EL2 of the light emitting element ED of one or more embodiments. The capping layer CPL may include a multilayer or a single layer. In one or more embodiments, the capping layer CPL may include the above-described amine compound of one or more embodiments.

In one or more embodiments, the capping layer CPL may be an organic layer or an inorganic layer. For example, when the capping layer CPL contains an inorganic material, the inorganic material may include an alkaline metal compound (for example, LiF), an alkaline earth metal compound (for example, MgF₂), SiON, SiNₓ, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., and/or an epoxy resin, and/or acrylate such as methacrylate. However, one or more embodiments of the present disclosure is not limited thereto, and the capping layer CPL may include at least one selected from Compounds P1 to P5:

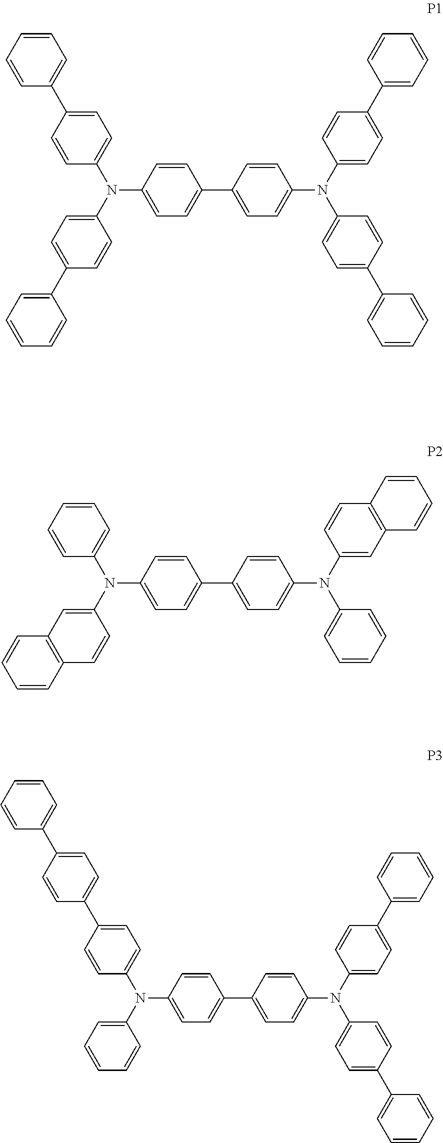 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

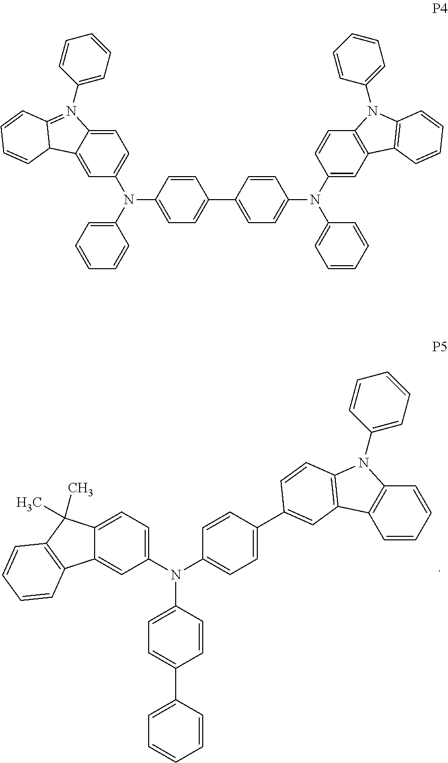

The refractive index of the capping layer CPL may be about 1.6 or more. For example, the refractive index of the capping layer CPL may be 1.6 or more with respect to light in a wavelength range of about 550 nm to about 660 nm.

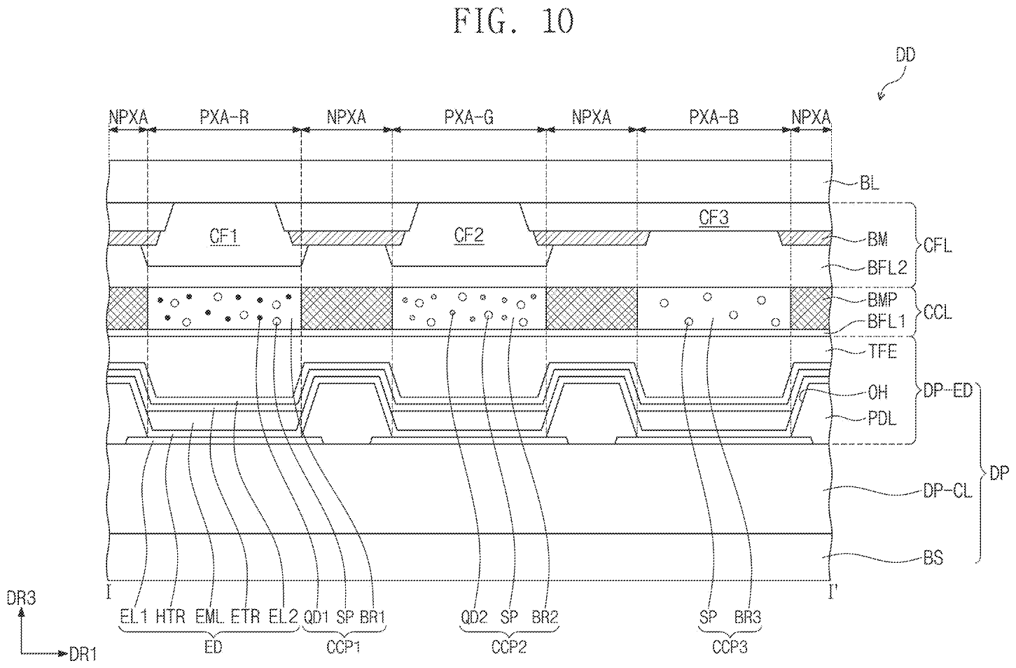

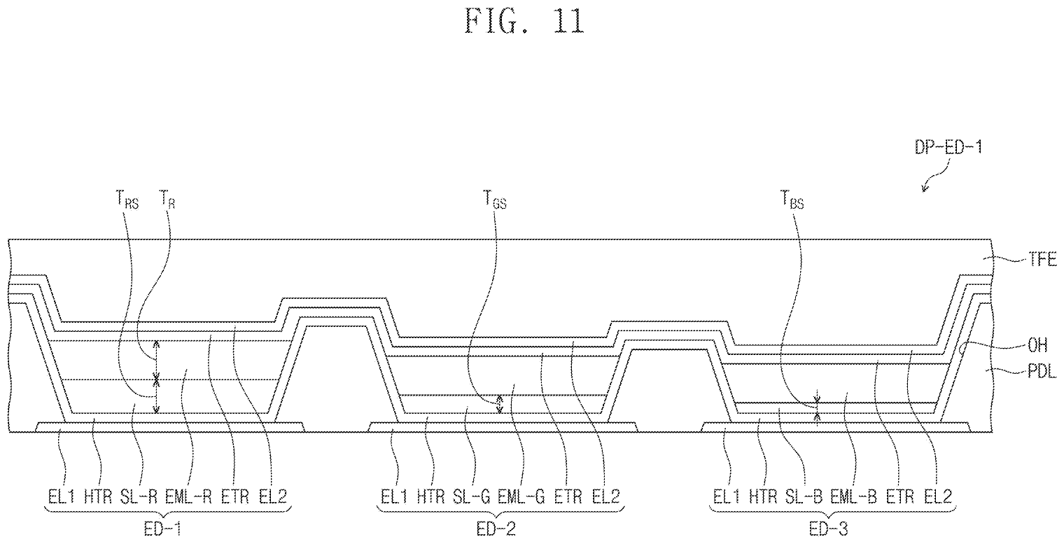

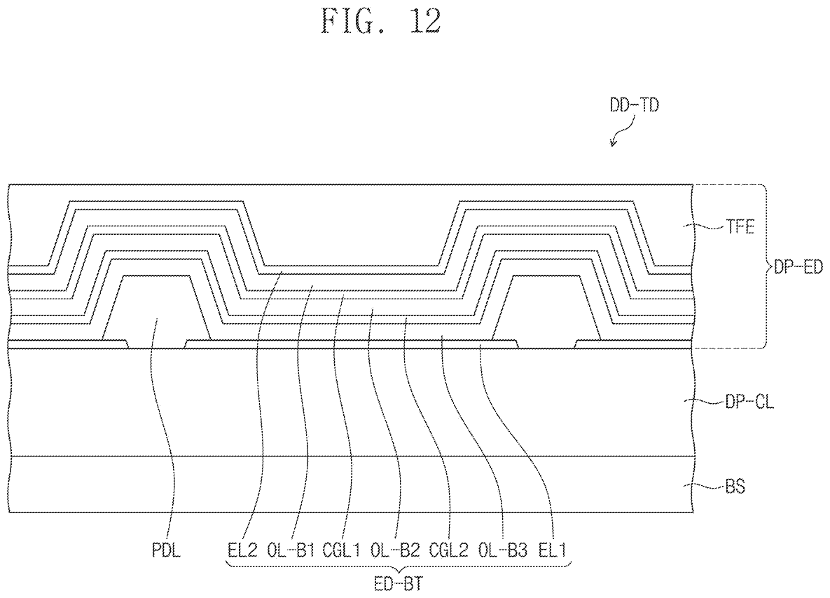

Each of FIGS. 10 and 12 is a cross-sectional view of a display device according to one or more embodiments, and FIG. 11 is a cross-sectional view of a display element layer according to one or more embodiments. Hereinafter, in describing the display devices of embodiments with reference to FIGS. 10 to 12, the duplicated features which have been described in FIGS. 1 to 9 will not be described again, but their differences will be mainly described.

Referring to FIG. 10, the display device DD according to one or more embodiments may include a display panel DP including a display element layer DP-ED, a light control layer CCL provided on the display panel DP, and a color filter layer CFL.

In one or more embodiments illustrated in FIG. 10, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR provided on the first electrode EL1, an emission layer EML provided on the hole transport region HTR, an electron transport region ETR provided on the emission layer EML, and a second electrode EL2 provided on the electron transport region ETR. The structures of the light emitting elements of FIGS. 3 to 9 as described above may be equally applied to the structure of the light emitting element ED illustrated in FIG. 10.

Referring to FIG. 10, the emission layer EML may be provided in an opening OH defined in a pixel defining film PDL. For example, the emission layer EML which is divided by the pixel defining film PDL and provided corresponding to each light emitting regions PXA-R, PXA-G, and PXA-B may emit light in the same wavelength range. In the display device DD of one or more embodiments, the emission layer EML may emit blue light. In one or more embodiments, the emission layer EML may be provided as a common layer in the entire light emitting regions PXA-R, PXA-G, and PXA-B.

The light control layer CCL may be provided on the display panel DP. The light control layer CCL may include a light conversion body. The light conversion body may be a quantum dot, a phosphor, and/or the like. The light conversion body may emit provided light by converting the wavelength thereof. For example, the light control layer CCL may a layer containing the quantum dot and/or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 10, divided patterns BMP may be provided between the light control parts CCP1, CCP2 and CCP3 which are spaced apart from each other, but one or more embodiments of the present disclosure is not limited thereto. FIG. 10 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts (e.g., is configured to covert) first color light provided from the light emitting element ED into second color light, a second light control part CCP2 containing a second quantum dot QD2 which converts (e.g., is configured to covert) the first color light into third color light, and a third light control part CCP3 which transmits (e.g., is configured to transmit) the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same description as provided above may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from TiO₂, ZnO, Al₂O₃, SiO₂, and hollow sphere silica, or may be a mixture of at least two materials selected from TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may be provided on the light control parts CCP1, CCP2, and CCP3 to block or reduce the exposure of the light control parts CCP1, CCP2 and CCP3 to moisture/oxygen. The barrier layer BFL1 may cover the light control parts CCP1, CCP2, and CCP3. In some embodiments, a barrier layer BFL2 may be provided between the light control parts CCP1, CCP2, and CCP3 and filters CF1, CF2, and CF3.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may further include an organic film. The barrier layers BFL1 and BFL2 may be formed of a single layer or a plurality of layers.

In the display device DD of one or more embodiments, the color filter layer CFL may be provided on the light control layer CCL. For example, the color filter layer CFL may be directly provided on the light control layer CCL. In this case, the barrier layer BFL2 may be omitted (e.g., may not be provided).

The color filter layer CFL may include a light shielding part BM and color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment and/or dye. The first filter CF1 may include a red pigment and/or dye, the second filter CF2 may include a green pigment and/or dye, and the third filter CF3 may include a blue pigment and/or dye. However, one or more embodiments of the present disclosure is not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

Furthermore, in one or more embodiments, the first filter CF1 and the second filter CF2 may be a yellow filter. The first filter CF1 and the second filter CF2 may not be separated but be provided as one filter.

The light shielding part BM may be a black matrix. The light shielding part BM may include an organic light shielding material and/or an inorganic light shielding material containing a black pigment or dye. The light shielding part BM may prevent or reduce light leakage, and may separate boundaries between the adjacent filters CF1, CF2, and CF3. In one or more embodiments, the light shielding part BM may be formed of a blue filter.

The first to third filters CF1, CF2, and CF3 may be provided corresponding to the red light emitting region PXA-R, the green light emitting region PXA-G, and the blue light emitting region PXA-B, respectively.

A base substrate BL may be provided on the color filter layer CFL. The base substrate BL may be a member which provides a base surface in which the color filter layer CFL, the light control layer CCL, and/or the like are provided. The base substrate BL may be a glass substrate, a metal substrate, a plastic substrate, etc. However, one or more embodiments of the present disclosure is not limited thereto, and the base substrate BL may be an inorganic layer, an organic layer, or a composite material layer. In one or more embodiments, the base substrate BL may be omitted (e.g., may not be provided).

A display element layer DP-ED-1 of one or more embodiments illustrated in FIG. 11 may further include resonance auxiliary layers SL-R, SL-G, and SL-B respectively provided between emission layers EML-R, EML-G, and EML-B and a hole transport region HTR. In one or more embodiments, first to third emission layers EML-R, EML-G, and EML-B may be provided to be spaced apart from each other on a plane. The first emission layer EML-R may be provided to be spaced apart from the second emission layer EML-G, and the second emission layer EML-G may be provided to be spaced apart from the third emission layer EML-B. The resonance auxiliary layers SL-R, SL-G, and SL-B may be a layer which assists in the constructive interference of light emitted from the emission layers EML-R, EML-G, and EML-B and light reflected in a first electrode EL1 by adjusting the distance between the first electrode EL1 and a second electrode EL2.

The display device DD of one or more embodiments may have a structure in which the light emitted from the emission layers EML-R, EML-G, and EML-B resonates. The resonance structure may have a resonance distance varying with the wavelength of the light emitted from the emission layers EML-R, EML-G, and EML-B. Thus, the resonance auxiliary layers SL-R, SL-G, and SL-B may be provided on lower portions of the emission layers EML-R, EML-G, and EML-B, respectively, thereby adjusting the resonance distance. The resonance auxiliary layers SL-R, SL-G, and SL-B may have different thicknesses depending on the wavelengths of the light beams emitted from the emission layers EML-R, EML-G, and EML-B. The thickness TRS of a first resonance auxiliary layer SL-R may be greater than the thickness TGS of a second resonance auxiliary layer SL-G, and the thickness TGS of the second resonance auxiliary layer SL-G may be greater than the thickness TBS of a third resonance auxiliary layer SL-B. For example, the thickness may get smaller in the order of the first resonance auxiliary layer SL-R, the second resonance auxiliary layer SL-G, and the third resonance auxiliary layer SL-B. However, this is merely an example, and one or more embodiments of the present disclosure is not limited thereto. In some embodiments, when the emission layers EML-R, EML-G, and EML-B emit light in the same wavelength, the resonance auxiliary layers SL-R, SL-G, and SL-B may have the same thickness.

FIG. 12 is a cross-sectional view of a part of a display device DD-TD according to one or more embodiments. FIG. 12 illustrates a cross-sectional view of the part corresponding to the display panel DP of FIG. 10. In the display device DD-TD of one or more embodiments, the light emitting element ED-BT may include a plurality of light emitting structures OL-B1, OL-B2, and OL-B3. The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 10) and a hole transport region HTR and an electron transport region ETR provided with the emission layer EML (FIG. 10) located therebetween.

For example, the light emitting element ED-BT included in the display device DD-TD of one or more embodiments may be a light emitting element having a tandem structure and including a plurality of emission layers.

In one or more embodiments illustrated in FIG. 12, all light beams respectively emitted from the light emitting structures OL-B1, OL-B2, and OL-B3 may be blue light. However, one or more embodiments of the present disclosure is not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may emit white light.

A charge generation layer CGL may be provided between the neighboring light emitting structures OL-B1, OL-B2, and OL-B3. The charge generation layer CGL may include a p-type (e.g., p−) charge generation layer and/or an n-type (e.g., n−) charge generation layer. For example, the charge generation layer CGL may include a first charge generation layer CGL-1 between OL-B1 and OL-B2 and a second charge generation layer CGL-2 between OL-B2 and OL-B3.

At least one of the light emitting structures OL-B1, OL-B2, or OL-B3 included in the display device DD-TD of one or more embodiments may include the above-described amine compound of one or more embodiments.

The light emitting element ED according to one or more embodiments may include a first hole transport layer HTL1 having a low refractive index and satisfying a conductivity of about 6.0×10⁻⁵ cm/(V·s) to about 10.0×10⁻⁴ cm/(V·s), and a second hole transport layer HTL2 having a high refractive index, thereby improving brightness and color visibility in the low gradation region.

In some embodiments, the light emitting element ED according to one or more embodiments may include a plurality of hole transport layers HTL1, HTL3, and HTL4 having a low refractive index and including the amine compound represented by Formula 1, and the second hole transport layer HTL2 having a high refractive index, resulting in the constructive interference of light inside the light emitting element ED, thereby improving external light efficiency characteristics.

Hereinafter, with reference to Examples and Comparative Examples, an amine compound according to one or more embodiments of the present disclosure and a light emitting element of one or more embodiments of the present disclosure will be described in more detail. However, Examples described below are only illustrations to assist the understanding of the present disclosure, and the scope of the present disclosure is not limited thereto.

### 1. Manufacture of Light Emitting Element

### (1) Manufacture of Light Emitting Element of Example 1

A substrate, in which ITO/Ag/ITO were stacked on a glass substrate in thicknesses of about 70 Å/1,500 Å/70 Å, was washed with ultrapure water and cleansed by ultrasonic waves, and then was irradiated with ultraviolet rays for about 30 minutes and treated with ozone to prepare a first electrode. Thereafter, Compound 1 and Compound H-1-31 were co-deposited to form a 110 Å-thick hole injection layer.

On the hole injection layer, Compound 1 and NDP9 were co-deposited in a mass ratio of about 98:2 to form a 43 Å-thick first hole transport layer; on the first hole transport layer, Compound 1 and Compound H-1-31 were mixed in a mass ratio of about 5:5, then the mixture was deposited to form a 276 Å-thick 4-1st hole transport layer; on the 4-1st hole transport layer, Compound H-1-31 was deposited to form a 300 Å-thick second hole transport layer; on the second hole transport layer, Compound 1 and Compound H-1-31 were mixed in a mass ratio of about 5:5, then the mixture was deposited to form a 276 Å-thick 4-2nd hole transport layer; and on the 4-2nd hole transport layer, Compound 1 was deposited to form a 155 Å-thick third hole transport layer, thereby forming a hole transport region. On the hole transport region, ADN and DPAVBi as a blue fluorescent dopant were co-deposited in a weight ratio of about 98:2 to form a 300 Å-thick emission layer. Then, Alq₃ was deposited to form a 300 Å-thick electron transport layer, and LiF was deposited to form a 10 Å-thick electron injection layer. Then, Al was provided to form a 3000 Å-thick second electrode.

In the manufacture of the light emitting element of Example 1, the hole injection layer, the hole transport layer, the emission layer, the electron transport layer, the electron injection layer, and the second electrode were formed by using a vacuum deposition apparatus.

### (2) Manufacture of Light Emitting Element of Comparative Example 1

The light emitting element of Comparative Example 1 was manufactured in the same manner as the light emitting element of Example as described above, except that Compound H-1-31 was deposited to form a single 1150 Å-thick hole transport layer.

### (3) Manufacture of Light Emitting Elements of Comparative Examples 2 to 4

The light emitting elements of Comparative Examples 2 to 4 were manufactured in substantially the same manner as the light emitting element of Example 1, except that Comparative Example Compounds C1 to C3 were used instead of Compound 1, respectively.

Compounds used for manufacturing the light emitting elements of Examples and Comparative Examples are disclosed below. The materials below were used to manufacture the elements by subjecting commercial products to sublimation purification.

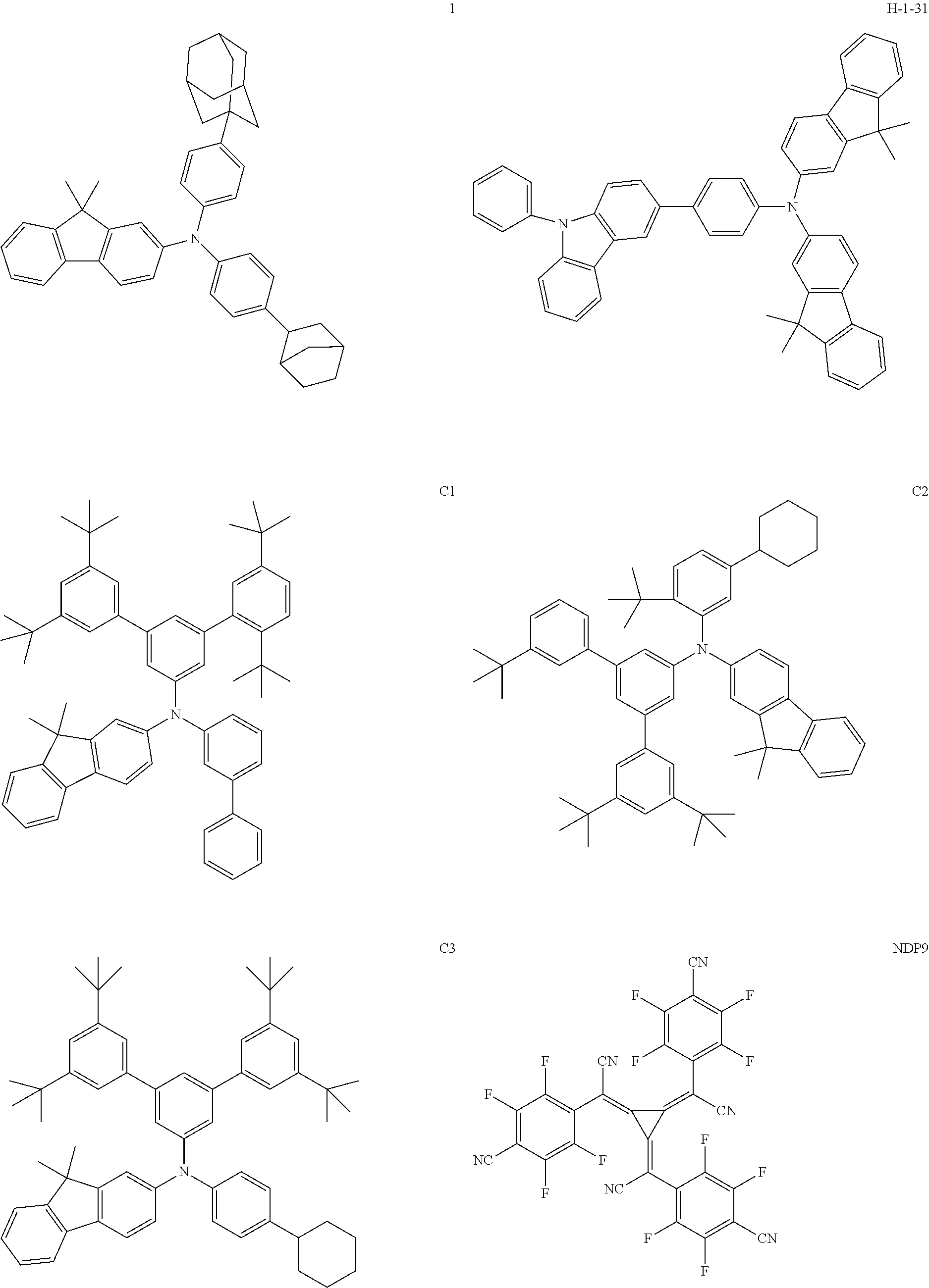

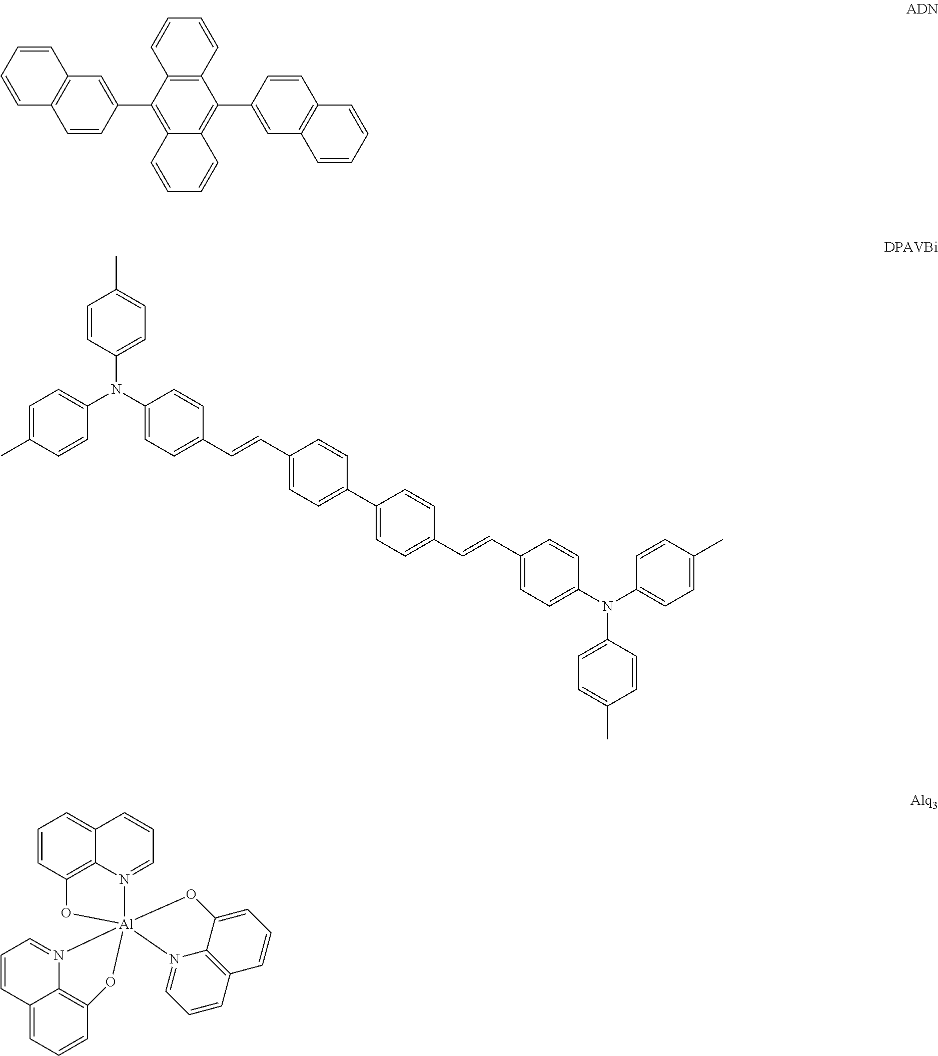

### 2. Evaluation of Light Emitting Element (1)

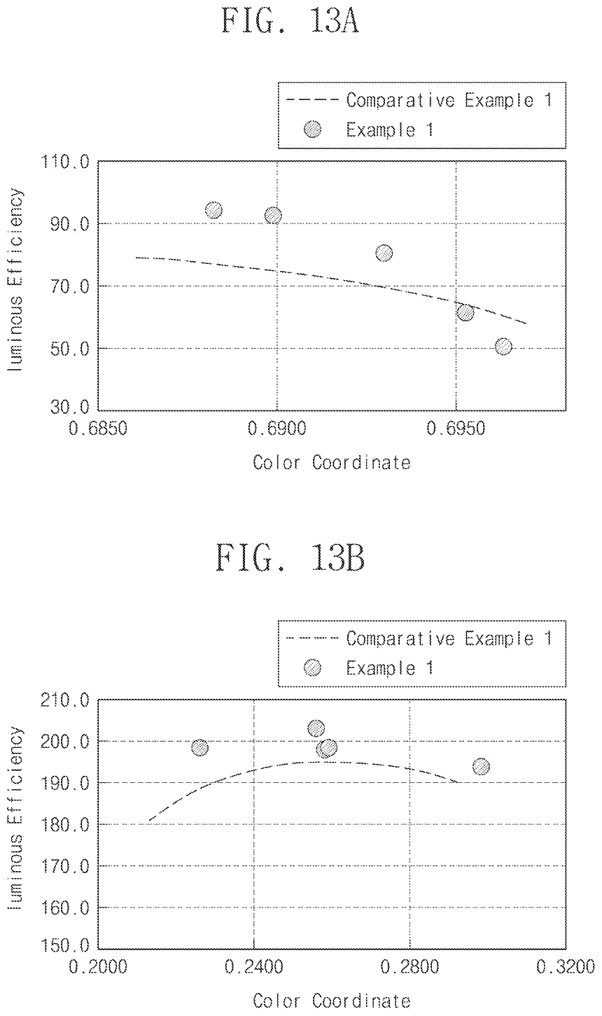

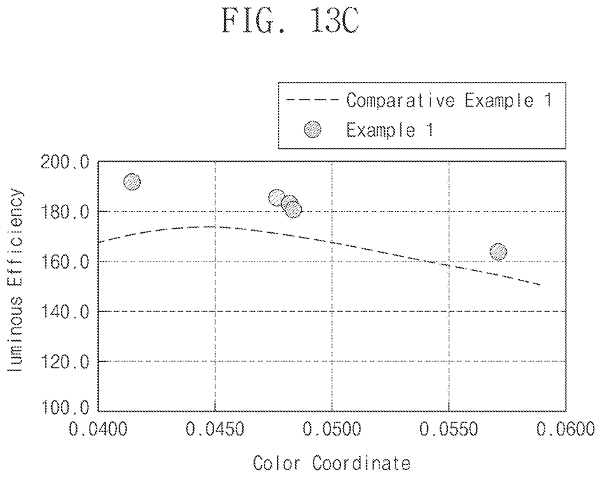

FIGS. 13A, 13B, and 13C are graphs each showing luminous efficiency versus color coordinate.

FIG. 13A shows the color coordinate and luminous efficiency of red light in each of the light emitting element of Example 1 and the light emitting element of Comparative Example 1. FIG. 13B shows the color coordinate and luminous efficiency of green light in each of the light emitting element of Example 1 and the light emitting element of Comparative Example 1. FIG. 13C shows the color coordinate and luminous efficiency of blue light in each of the light emitting element of Example 1 and the light emitting element of Comparative Example 1.

Referring to FIGS. 13A to 13C, it may be confirmed that the light emitting element of Example 1 has an increase in the luminous efficiency of red light, green light, and blue light as compared with the light emitting element of Comparative Example 1.

### 3. Evaluation of Light Emitting Element (2)

Table 1 shows driving voltages, service lives, and efficiencies of the elements when the light emitting elements of Examples 1 and Comparative Examples 1 to 4 are driven in the low gradation region. Table 1 also shows conductivity of the hole transport layer included in each light emitting element. In Table 1, the conductivity was measured by a transmission line method (TLM). The driving voltage shown in Table 1 was measured using OLED IVL measurement equipment. The efficiency shows an efficiency value measured at a current density of 10 mA/cm². The service life (T97) means a time taken to reduce the brightness by 3% relative to an initial brightness value at a current density of mA/cm².

TABLE 1

| | Conductivity | | | | Occurrence of |
|---|---|---|---|---|---|
| | of hole | | | | brightness |
| | transport | Driving | Service | | reduction in |
| | layer | voltage | life | Effi- | low gradation |
| Division | cm/(V · s) | (V) | (T97) | ciency | region |
| Example 1 | 6.37 × 10⁻⁵ | 3.4 | 180 | 120% | X |
| Comparative | 3.3 × 10⁻³ | 3.4 | 180 | 100% | ◯ |
| Example 1 | | | | | |
| Comparative | 1.78 × 10⁻⁶ | 4.1 | 12 | 120% | X |
| Example 2 | | | | | |
| Comparative | 2.87 × 10⁻⁷ | 4.2 | 10 | 120% | X |
| Example 3 | | | | | |
| Comparative | 1.26 × 10⁻⁷ | 4.4 | 7 | 120% | X |
| Example 4 | | | | | |

### Example 4

Referring to Table 1, the light emitting element of Example 1 does not have a problem of brightness reduction in the low gradation region but exhibits excellent efficiency as compared with the light emitting element of Comparative Example 1. In addition, the light emitting element of Example 1 has a lower driving voltage and a significantly longer service life characteristics than the light emitting elements of Comparative Examples 2 to 4.

The light emitting element of Example 1 includes the hole transport layer having a conductivity of about 6.0×10⁻⁵ cm/(V·s) to about 10.0×10⁻⁴ cm/(V·s), and thus has good driving voltage, service life, and efficiency, and the brightness reduction does not occur in the low gradation region.

The light emitting element of Comparative Example 1 includes the hole transport layer having a conductivity of greater than about 10.0×10⁻⁴ cm/(V·s), and thus the brightness reduction occurs in the low gradation region. This may cause defects in color visibility.

The light emitting elements of Comparative Examples 2 to 4 each include the hole transport layer having a conductivity of less than about 6.0×10⁻⁵ cm/(V·s), and thus it is believed the driving voltages increase and the service life characteristics are significantly reduced.

### 4. Evaluation of Light Emitting Element (3)

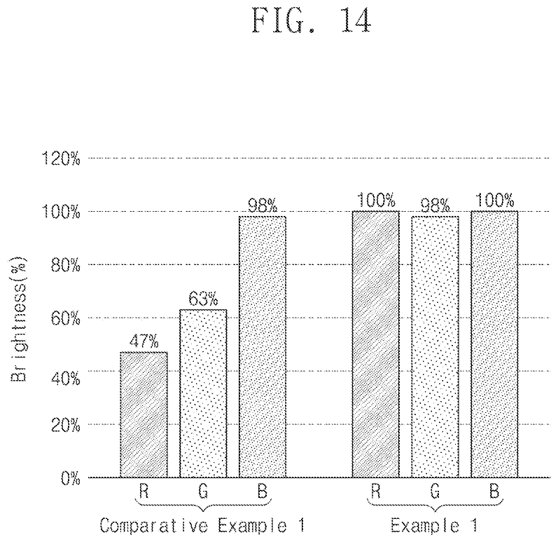

FIG. 14 is a graph showing brightnesses of red light (R), green light (G), and blue light (B) in each of the light emitting element of Example 1 and the light emitting element of Comparative Example 1.

The conductivity of the hole transport layer included in the light emitting element of Example 1 is about 5.70×10⁻⁴ cm/(V·s), and the conductivity of the hole transport layer included in the light emitting element of Comparative Example 1 is about 3.30×10⁻³ cm/(V·s).

Referring to FIG. 14, the light emitting element of Example 1 exhibits the brightnesses of about 100%, about 98%, and about 100% in red light (R), green light (G), and blue light (B), respectively. In contrast, it may be confirmed that the light emitting element of Comparative Example 1 exhibits the brightnesses of about 47%, about 63%, and about 98% in red light (R), green light (G), and blue light (B), respectively. It is believed, without being bound by any particular theory, that the light emitting element of Comparative Example 1 includes the hole transport layer having a conductivity of greater than about 10.0×10⁻⁴ cm/(V·s), and thus the brightness is reduced when the element is driven in the low gradation region. For example, it is believed that in the case of the light emitting element of Comparative Example 1, when a first color pixel, which is any one selected from red, green, and blue, is driven in the low gradation region, a leakage current occurs, and thus a second color pixel, which is adjacent to and different from the first color, is driven together, and a color tone of the first color changes so that gray crushing occurs.

Referring to Table 1, FIGS. 13A to 13C and 14 as described, the light emitting element of the present disclosure includes the amine compound represented by Formula 1 and the hole transport layer having a conductivity of about 6.0×10⁻⁵ cm/(V·s) to about 10.0×10⁻⁴ cm/(V·s), and thus the occurrence of leakage current during driving of the element may be prevented or reduced, and the brightnesses of red light, green light, and blue light may be improved.

In some embodiments, the light emitting element of one or more embodiments may include the first hole transport layer including the first amine compound and having a lower refractive index, the second hole transport layer having a higher refractive index, the third hole transport layer including the second amine compound and having a lower refractive index, and the fourth hole transport layer including the third amine compound and having a lower refractive index, thereby exhibiting high efficiency characteristics.

The light emitting element of one or more embodiments and the display device including the same include the hole transport layer having excellent or improved conductivity characteristics and a low refractive index, thereby exhibiting high efficiency and long lifetime characteristics.

Although the present disclosure has been described with reference to certain embodiments of the present disclosure, it will be understood that the present disclosure should not be limited to these embodiments but various changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims and their equivalents.

What is claimed is:

1. A light emitting element comprising:
a first electrode;
a hole transport region on the first electrode;
an emission layer on the hole transport region;
an electron transport region on the emission layer; and
a second electrode on the electron transport region,
wherein the hole transport region comprises:
a first hole transport layer adjacent to the first electrode and comprising a first amine compound represented by Formula 1, and
a second hole transport layer between the first hole transport layer and the emission layer, and having a refractive index larger than that of the first hole transport layer, and
the first hole transport layer has a conductivity of about 6.0×10⁻⁵ cm/(V·sec) to about 10.0×10⁻⁴ cm/(V·sec): 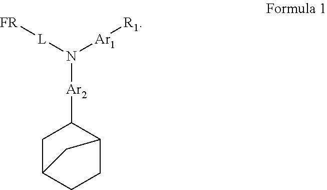
wherein, in Formula 1,
R₁ is a substituted or unsubstituted cycloalkyl group having 6 to 12 ring-forming carbon atoms,
Ar₁ and Ar₂ are each independently a substituted or unsubstituted arylene group having 6 to 30 ring-forming carbon atoms, or a substituted or unsubstituted heteroarylene group having 2 to 30 ring-forming carbon atoms,
L is a direct linkage, a substituted or unsubstituted arylene group having 6 to 30 ring-forming carbon atoms, or a substituted or unsubstituted heteroarylene group having 2 to 30 ring-forming carbon atoms, and
FR is represented by Formula 2-1 or Formula 2-2: 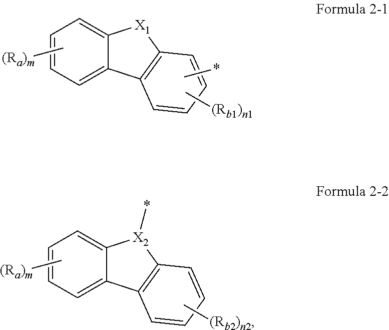
and
wherein in Formula 2-1 and Formula 2-2,
X₁ is CR_{c}R_{d}, NRₑ, O, or S,
X₂ is CR_{f} or N,
Rₐ, R_{b1}, R_{b2}, and R_{c} to R_{f} are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
m is an integer of 0 to 4,
n1 is an integer of 0 to 3,
n2 is an integer of 0 to 4, and
in Formula 2-1 and Formula 2-2, “˜” means a position linked to L in Formula 1.

2. The light emitting element of claim 1, wherein the first hole transport layer has a refractive index of about 1.4 to about 1.75.

3. The light emitting element of claim 1, wherein the second hole transport layer has a refractive index of about 1.8 to about 2.0.

4. The light emitting element of claim 1, further comprising a third hole transport layer between the second hole transport layer and the emission layer, and comprising a second amine compound represented by Formula 1.

5. The light emitting element of claim 4, wherein the third hole transport layer has a refractive index of about 1.4 to about 1.75.

6. The light emitting element of claim 4, wherein the hole transport region further comprises a fourth hole transport layer, between the first hole transport layer and the second hole transport layer, or between the second hole transport layer and the third hole transport layer, or both between the first hole transport layer and the second hole transport layer and between the second hole transport layer and the third hole transport layer, and
wherein the fourth hole transport layer comprises a third amine compound represented by Formula 1.

7. The light emitting element of claim 6, wherein a refractive index of the fourth hole transport layer is larger than that of the first hole transport layer and smaller than that of the second hole transport layer.

8. The light emitting element of claim 6, wherein at least one among the first hole transport layer to the fourth hole transport layer further comprises a compound represented by Formula H-1: 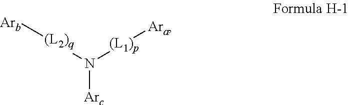
and
wherein, in Formula H-1,
Arₐ and Ar_{b} are each independently a substituted or unsubstituted aryl group having 6 to 30 ring-forming carbon atoms, or a substituted or unsubstituted heteroaryl group having 2 to 30 ring-forming carbon atoms,
Ar_{c} is a substituted or unsubstituted aryl group having 6 to 30 ring-forming carbon atoms,
L₁ and L₂ are each independently a direct linkage, a substituted or unsubstituted arylene group having 6 to 30 ring-forming carbon atoms, or a substituted or unsubstituted heteroarylene group having 2 to 30 ring-forming carbon atoms, and
p and q are each independently an integer of 0 to 10.

9. The light emitting element of claim 1, further comprising a fourth hole transport layer, between the first hole transport layer and the second hole transport layer, or between the second hole transport layer and the emission layer, or both between the first hole transport layer and the second hole transport layer and between the second hole transport layer and the emission layer, and
wherein the fourth hole transport layer comprises a third amine compound represented by Formula 1.

10. The light emitting element of claim 9, wherein a refractive index of the fourth hole transport layer is larger than that of the first hole transport layer and smaller than that of the second hole transport layer.

11. The light emitting element of claim 1, wherein the first hole transport layer is doped with p-dopant in an amount of about 1% to about 3%, and
the p-dopant comprises at least one of a halogenated metal compound, a quinone derivative, a tungsten oxide, a metal oxide, or a cyano group-containing compound.

12. The light emitting element of claim 1, wherein the first amine compound represented by Formula 1 is represented by any one among Formula 1-1 to Formula 1-5: 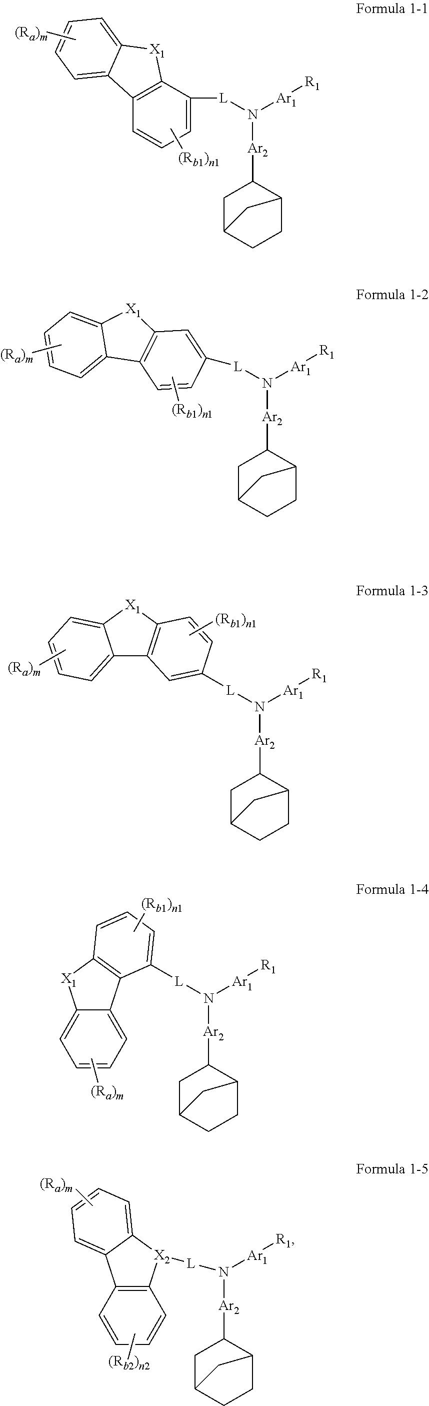
and
wherein, in Formula 1-1 to Formula 1-5, R₁, L, Ar₁, and Ar₂ are the same as defined in Formula 1, and X₁, X₂, Rₐ, R_{b1}, R_{b2}, m, n1, and n2 are the same as defined in Formula 2-1 and Formula 2-2.

13. The light emitting element of claim 1, wherein the first amine compound represented by Formula 1 is represented by Formula 3: 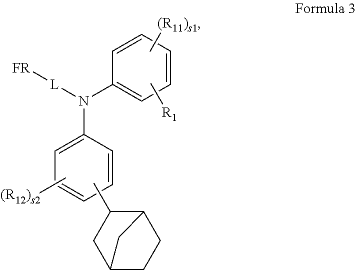
and
wherein, in Formula 3,
R₁₁ and R₁₂ are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
s1 and s2 are each independently an integer of 0 to 4, and
R₁, L, and FR are the same as defined in Formula 1.

14. The light emitting element of claim 1, wherein R₁ is a substituted or unsubstituted cyclohexyl group, a substituted or unsubstituted bicycloheptyl group, a substituted or unsubstituted bicyclooctyl group, a substituted or unsubstituted bicyclononyl group, or a substituted or unsubstituted adamantyl group.

15. The light emitting element of claim 1, wherein R_{c} and R_{d} are each independently a substituted or unsubstituted methyl group, a substituted or unsubstituted heptyl group, a substituted or unsubstituted cyclohexyl group, or a substituted or unsubstituted phenyl group, and/or are bonded to each other to form a cyclopentane or fluorene ring.

16. The light emitting element of claim 1, wherein R_{f} is a substituted or unsubstituted aryl group having 6 to 30 ring-forming carbon atoms.

17. The light emitting element of claim 1, wherein the first amine compound represented by Formula 1 is represented by any one among compounds in Compound Group 1:

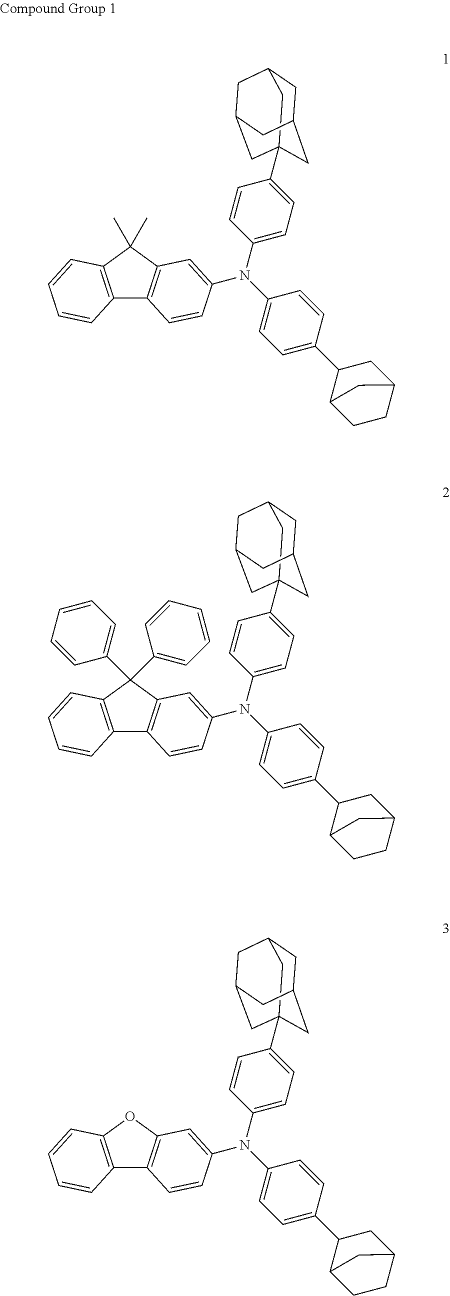 [SMILES: CC1(C)c2ccccc2-c2ccc(N(c3ccc(C4CC5CCC4C5)cc3)c3ccc(C45CC6CC(CC(C6)C4)C5)cc3)cc21 ; c1ccc(C2(c3ccccc3)c3ccccc3-c3ccc(N(c4ccc(C5CC6CCC5C6)cc4)c4ccc(C56CC7CC(CC(C7)C5)C6)cc4)cc32)cc1 ; c1ccc2c(c1)oc1cc(N(c3ccc(C4CC5CCC4C5)cc3)c3ccc(C45CC6CC(CC(C6)C4)C5)cc3)ccc12]

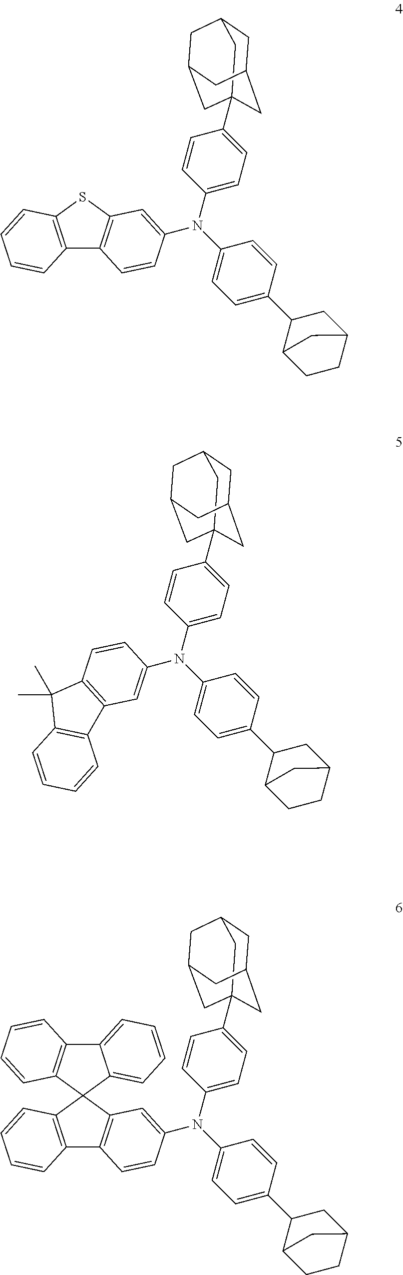 [SMILES: c1ccc2c(c1)sc1cc(N(c3ccc(C4CC5CCC4C5)cc3)c3ccc(C45CC6CC(CC(C6)C4)C5)cc3)ccc12 ; CC1(C)c2ccccc2-c2cc(N(c3ccc(C4CC5CCC4C5)cc3)c3ccc(C45CC6CC(CC(C6)C4)C5)cc3)ccc21 ; c1ccc2c(c1)-c1ccccc1C21c2ccccc2-c2ccc(N(c3ccc(C4CC5CCC4C5)cc3)c3ccc(C45CC6CC(CC(C6)C4)C5)cc3)cc21]

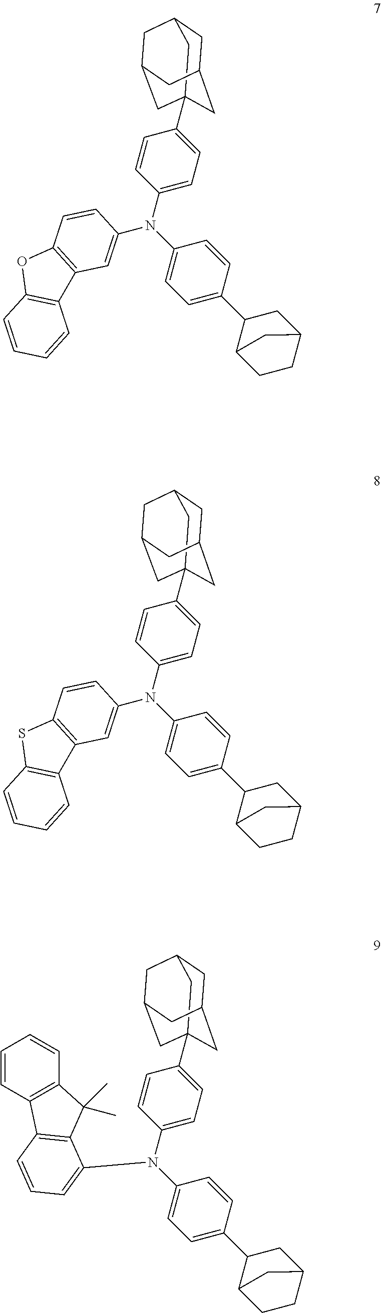 [SMILES: c1ccc2c(c1)oc1ccc(N(c3ccc(C4CC5CCC4C5)cc3)c3ccc(C45CC6CC(CC(C6)C4)C5)cc3)cc12 ; c1ccc2c(c1)sc1ccc(N(c3ccc(C4CC5CCC4C5)cc3)c3ccc(C45CC6CC(CC(C6)C4)C5)cc3)cc12 ; CC1(C)c2ccccc2-c2cccc(N(c3ccc(C4CC5CCC4C5)cc3)c3ccc(C45CC6CC(CC(C6)C4)C5)cc3)c21]

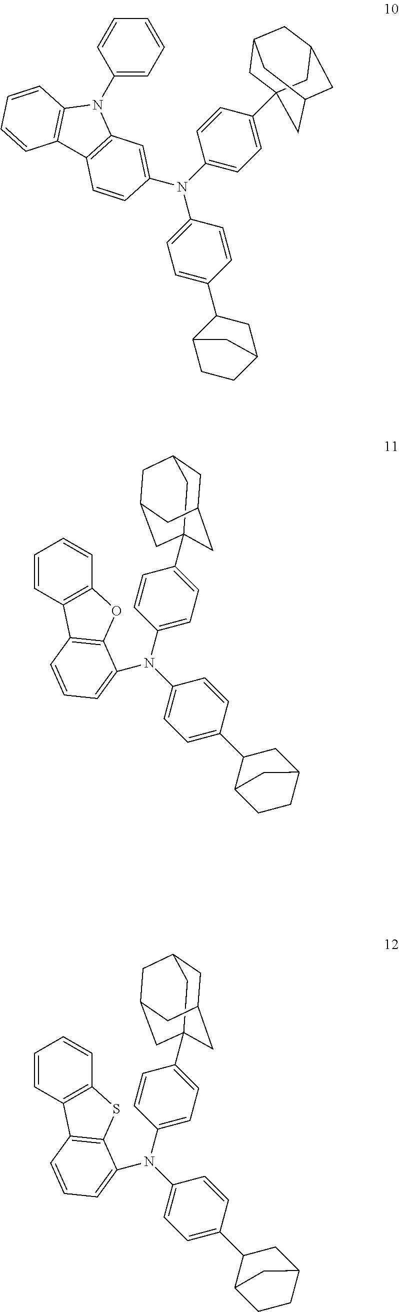 [SMILES: c1ccc(-n2c3ccccc3c3ccc(N(c4ccc(C5CC6CCC5C6)cc4)c4ccc(C56CC7CC(CC(C7)C5)C6)cc4)cc32)cc1 ; c1ccc2c(c1)oc1c(N(c3ccc(C4CC5CCC4C5)cc3)c3ccc(C45CC6CC(CC(C6)C4)C5)cc3)cccc12 ; c1ccc2c(c1)sc1c(N(c3ccc(C4CC5CCC4C5)cc3)c3ccc(C45CC6CC(CC(C6)C4)C5)cc3)cccc12]

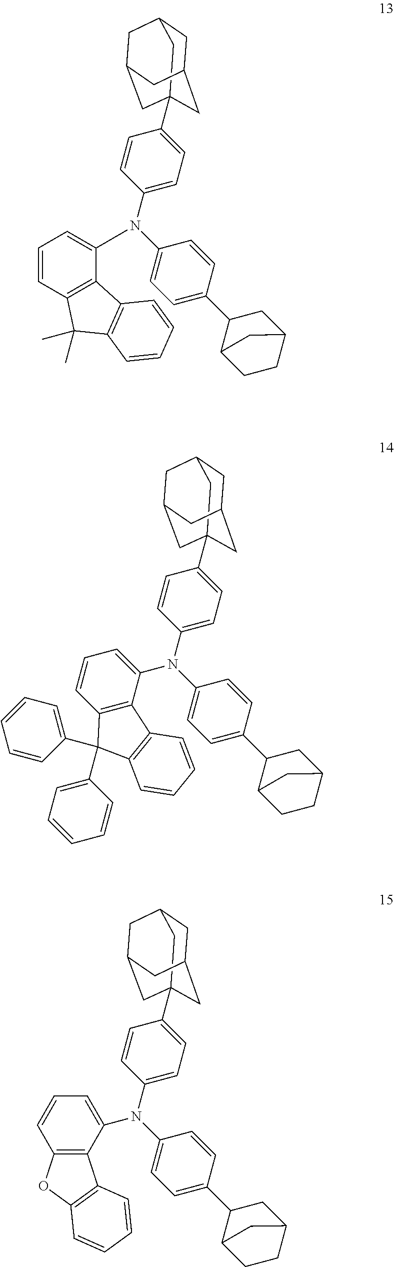 [SMILES: CC1(C)c2ccccc2-c2c(N(c3ccc(C4CC5CCC4C5)cc3)c3ccc(C45CC6CC(CC(C6)C4)C5)cc3)cccc21 ; c1ccc(C2(c3ccccc3)c3ccccc3-c3c(N(c4ccc(C5CC6CCC5C6)cc4)c4ccc(C56CC7CC(CC(C7)C5)C6)cc4)cccc32)cc1 ; c1ccc2c(c1)oc1cccc(N(c3ccc(C4CC5CCC4C5)cc3)c3ccc(C45CC6CC(CC(C6)C4)C5)cc3)c12]

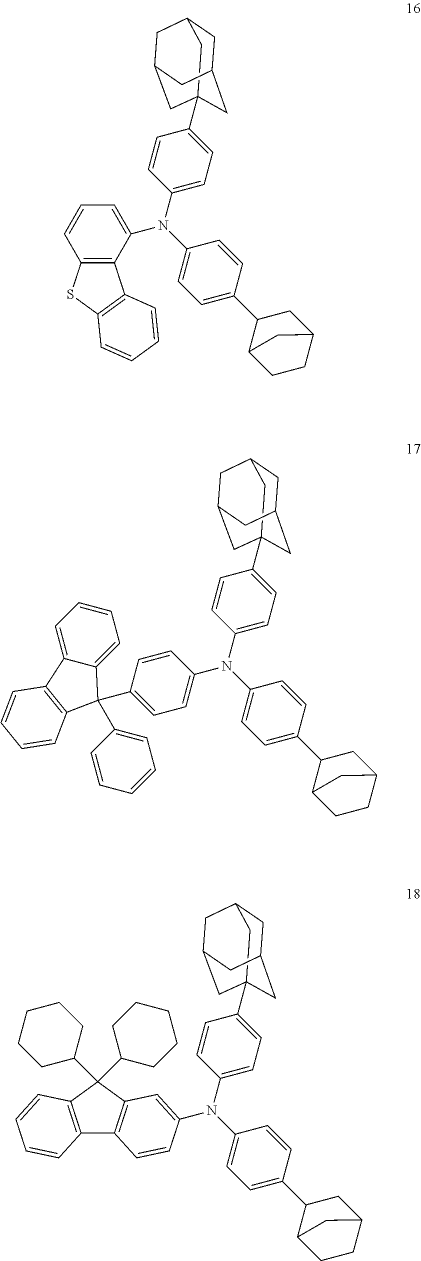 [SMILES: c1ccc2c(c1)sc1cccc(N(c3ccc(C4CC5CCC4C5)cc3)c3ccc(C45CC6CC(CC(C6)C4)C5)cc3)c12 ; c1ccc(C2(c3ccc(N(c4ccc(C5CC6CCC5C6)cc4)c4ccc(C56CC7CC(CC(C7)C5)C6)cc4)cc3)c3ccccc3-c3ccccc32)cc1 ; c1ccc2c(c1)-c1ccc(N(c3ccc(C4CC5CCC4C5)cc3)c3ccc(C45CC6CC(CC(C6)C4)C5)cc3)cc1C2(C1CCCCC1)C1CCCCC1]

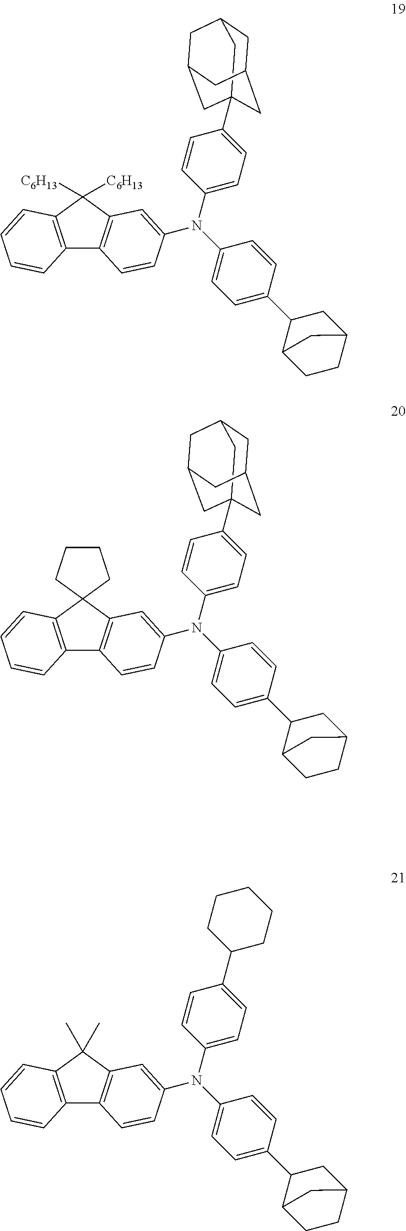

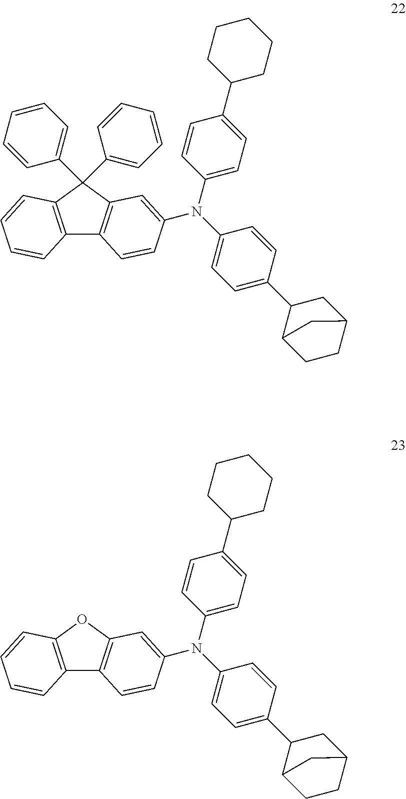 [SMILES: c1ccc(C2(c3ccccc3)c3ccccc3-c3ccc(N(c4ccc(C5CCCCC5)cc4)c4ccc(C5CC6CCC5C6)cc4)cc32)cc1 ; c1ccc2c(c1)oc1cc(N(c3ccc(C4CCCCC4)cc3)c3ccc(C4CC5CCC4C5)cc3)ccc12]

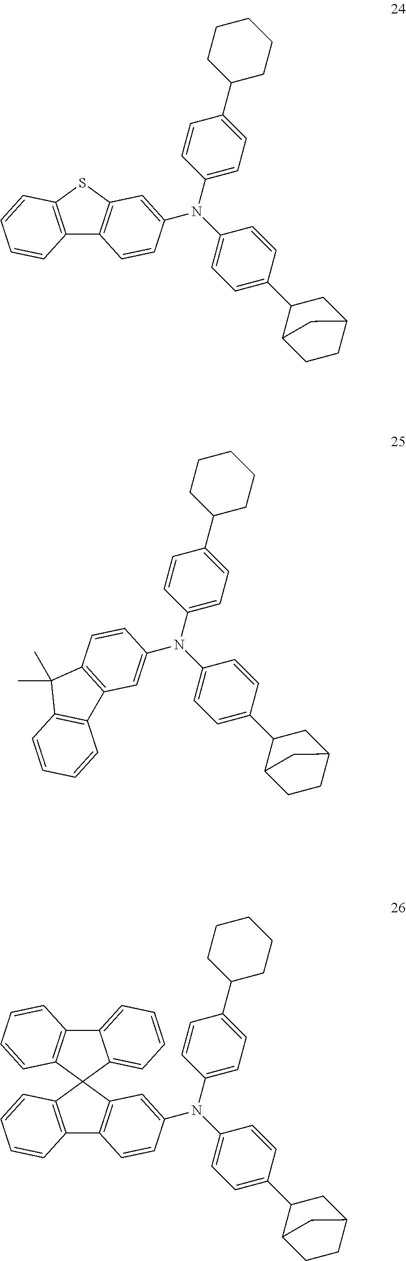 [SMILES: c1ccc2c(c1)sc1cc(N(c3ccc(C4CCCCC4)cc3)c3ccc(C4CC5CCC4C5)cc3)ccc12 ; CC1(C)c2ccccc2-c2cc(N(c3ccc(C4CCCCC4)cc3)c3ccc(C4CC5CCC4C5)cc3)ccc21 ; c1ccc2c(c1)-c1ccccc1C21c2ccccc2-c2ccc(N(c3ccc(C4CCCCC4)cc3)c3ccc(C4CC5CCC4C5)cc3)cc21]

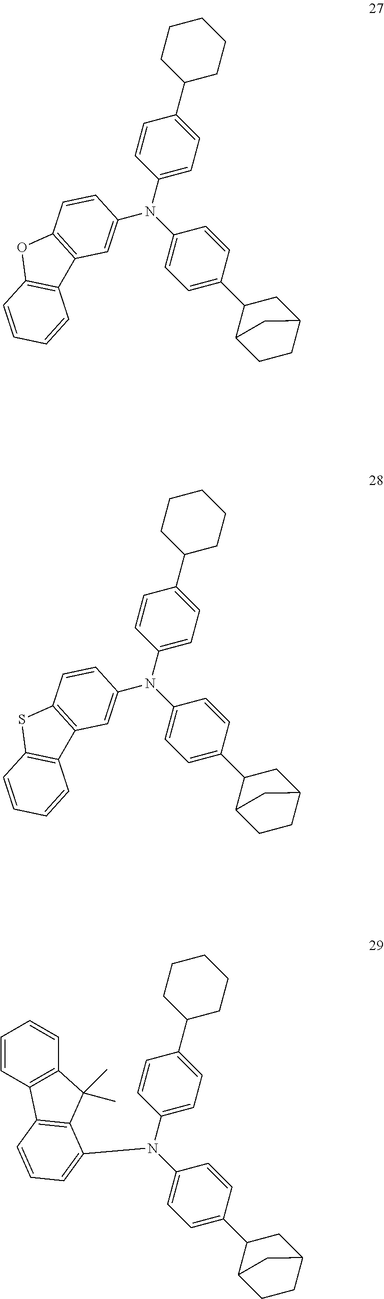 [SMILES: c1ccc2c(c1)oc1ccc(N(c3ccc(C4CCCCC4)cc3)c3ccc(C4CC5CCC4C5)cc3)cc12 ; c1ccc2c(c1)sc1ccc(N(c3ccc(C4CCCCC4)cc3)c3ccc(C4CC5CCC4C5)cc3)cc12 ; CC1(C)c2ccccc2-c2cccc(N(c3ccc(C4CCCCC4)cc3)c3ccc(C4CC5CCC4C5)cc3)c21]

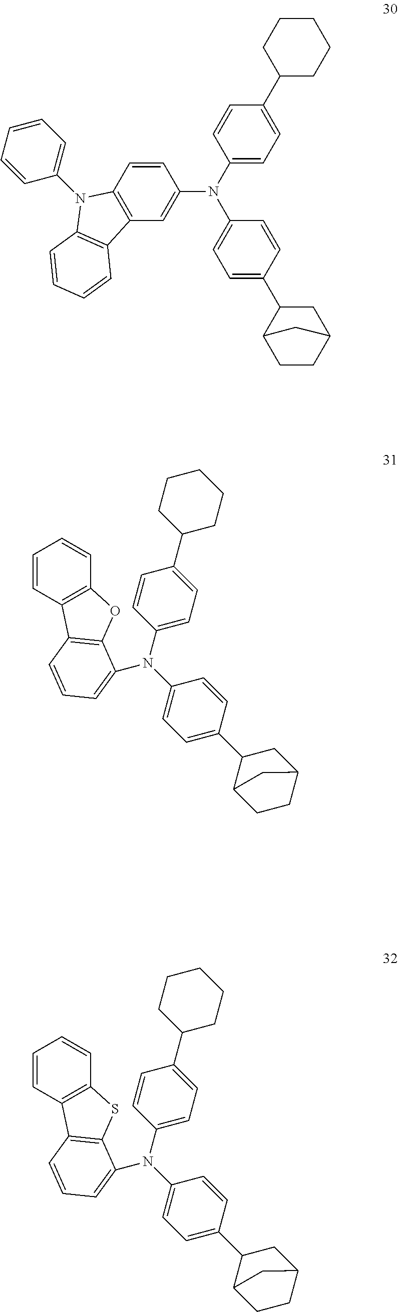 [SMILES: c1ccc(-n2c3ccccc3c3cc(N(c4ccc(C5CCCCC5)cc4)c4ccc(C5CC6CCC5C6)cc4)ccc32)cc1 ; c1ccc2c(c1)oc1c(N(c3ccc(C4CCCCC4)cc3)c3ccc(C4CC5CCC4C5)cc3)cccc12 ; c1ccc2c(c1)sc1c(N(c3ccc(C4CCCCC4)cc3)c3ccc(C4CC5CCC4C5)cc3)cccc12]

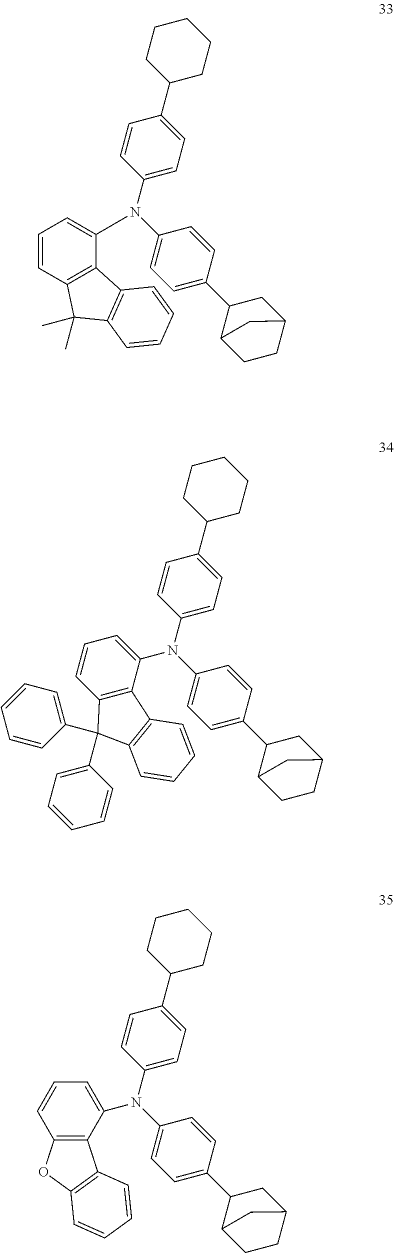 [SMILES: CC1(C)c2ccccc2-c2c(N(c3ccc(C4CCCCC4)cc3)c3ccc(C4CC5CCC4C5)cc3)cccc21 ; c1ccc(C2(c3ccccc3)c3ccccc3-c3c(N(c4ccc(C5CCCCC5)cc4)c4ccc(C5CC6CCC5C6)cc4)cccc32)cc1 ; c1ccc2c(c1)oc1cccc(N(c3ccc(C4CCCCC4)cc3)c3ccc(C4CC5CCC4C5)cc3)c12]

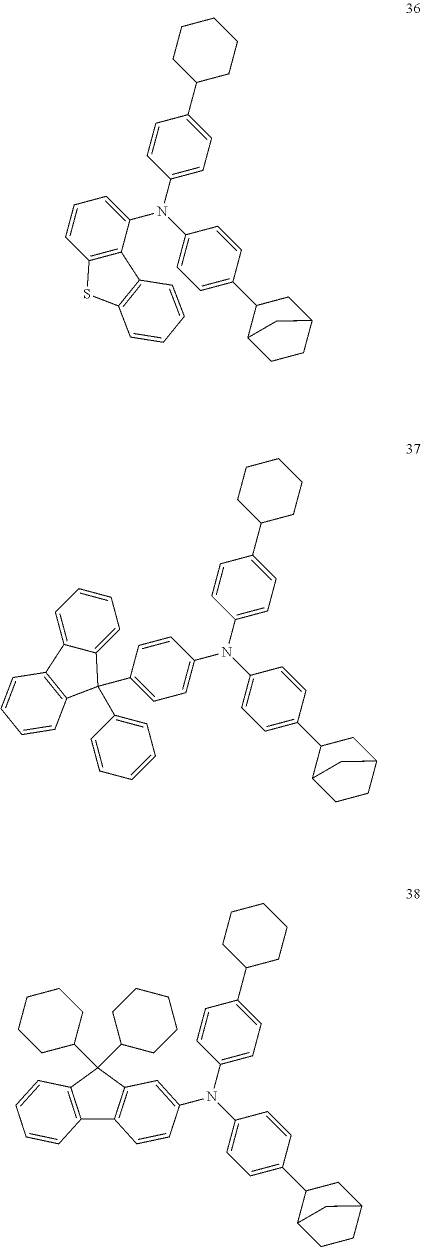 [SMILES: c1ccc2c(c1)sc1cccc(N(c3ccc(C4CCCCC4)cc3)c3ccc(C4CC5CCC4C5)cc3)c12 ; c1ccc(C2(c3ccc(N(c4ccc(C5CCCCC5)cc4)c4ccc(C5CC6CCC5C6)cc4)cc3)c3ccccc3-c3ccccc32)cc1 ; c1ccc2c(c1)-c1ccc(N(c3ccc(C4CCCCC4)cc3)c3ccc(C4CC5CCC4C5)cc3)cc1C2(C1CCCCC1)C1CCCCC1]

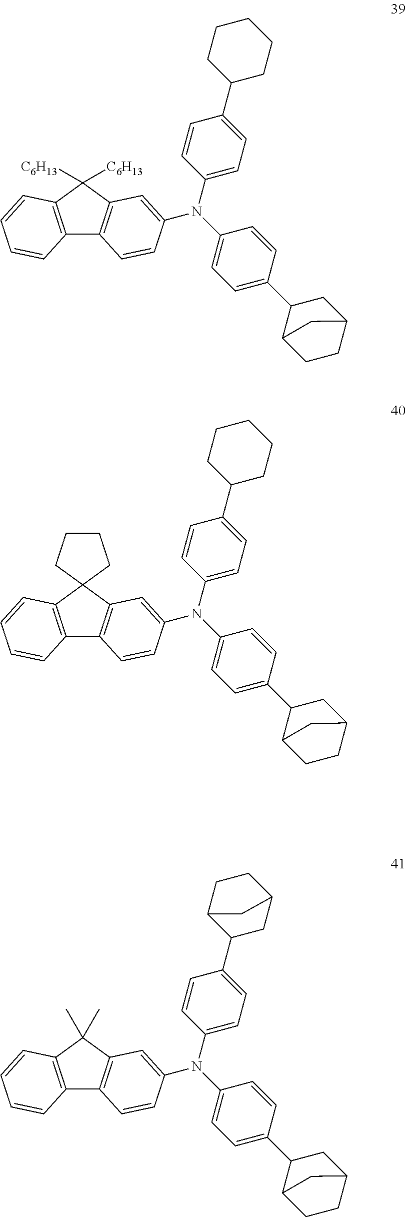

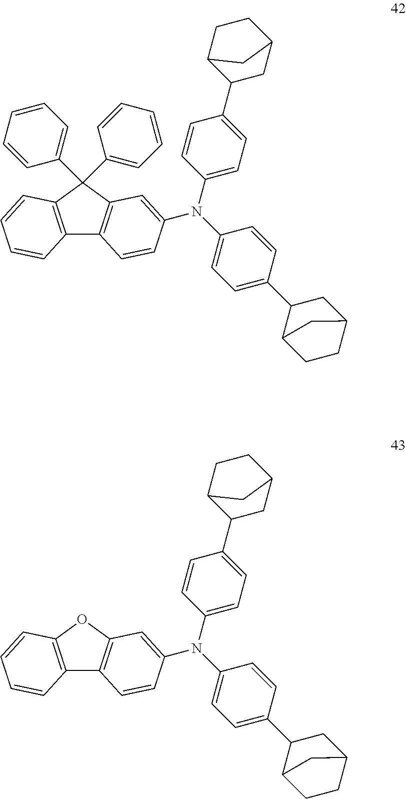 [SMILES: c1ccc(C2(c3ccccc3)c3ccccc3-c3ccc(N(c4ccc(C5CC6CCC5C6)cc4)c4ccc(C5CC6CCC5C6)cc4)cc32)cc1 ; c1ccc2c(c1)oc1cc(N(c3ccc(C4CC5CCC4C5)cc3)c3ccc(C4CC5CCC4C5)cc3)ccc12]

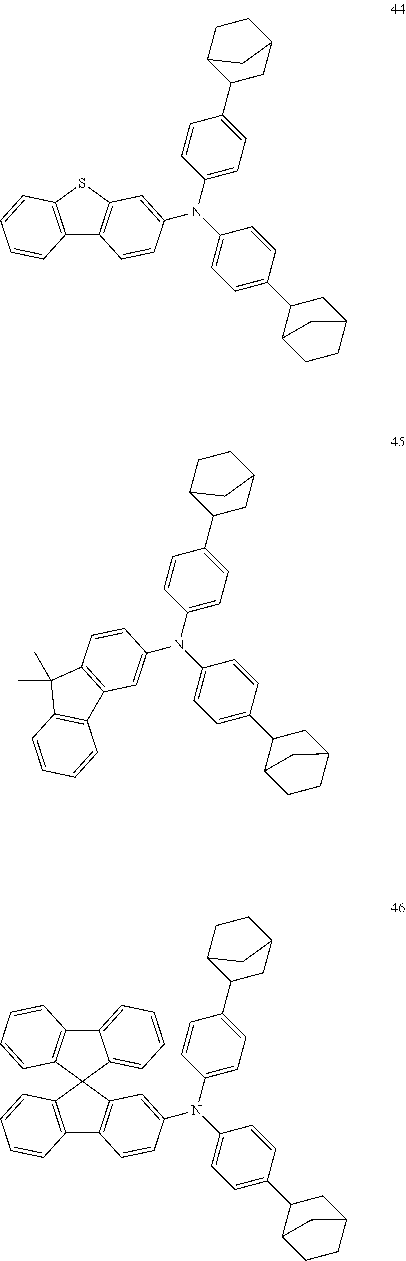 [SMILES: c1ccc2c(c1)sc1cc(N(c3ccc(C4CC5CCC4C5)cc3)c3ccc(C4CC5CCC4C5)cc3)ccc12 ; CC1(C)c2ccccc2-c2cc(N(c3ccc(C4CC5CCC4C5)cc3)c3ccc(C4CC5CCC4C5)cc3)ccc21 ; c1ccc2c(c1)-c1ccccc1C21c2ccccc2-c2ccc(N(c3ccc(C4CC5CCC4C5)cc3)c3ccc(C4CC5CCC4C5)cc3)cc21]

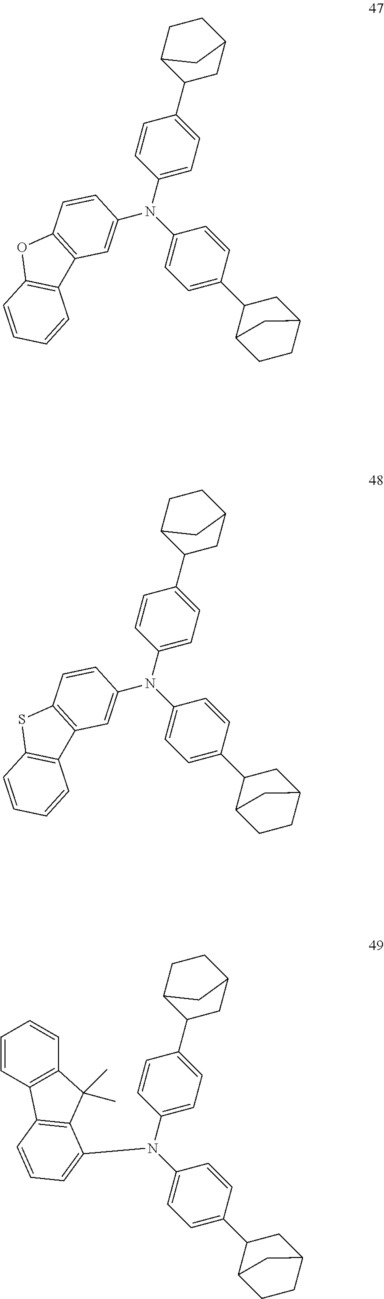 [SMILES: c1ccc2c(c1)oc1ccc(N(c3ccc(C4CC5CCC4C5)cc3)c3ccc(C4CC5CCC4C5)cc3)cc12 ; c1ccc2c(c1)sc1ccc(N(c3ccc(C4CC5CCC4C5)cc3)c3ccc(C4CC5CCC4C5)cc3)cc12 ; CC1(C)c2ccccc2-c2cccc(N(c3ccc(C4CC5CCC4C5)cc3)c3ccc(C4CC5CCC4C5)cc3)c21]

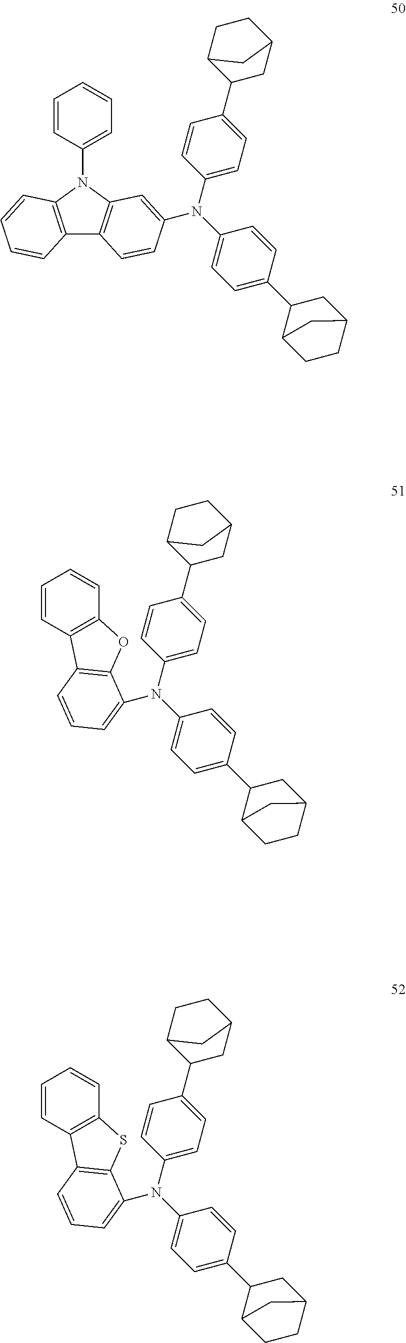 [SMILES: c1ccc(-n2c3ccccc3c3ccc(N(c4ccc(C5CC6CCC5C6)cc4)c4ccc(C5CC6CCC5C6)cc4)cc32)cc1 ; c1ccc2c(c1)oc1c(N(c3ccc(C4CC5CCC4C5)cc3)c3ccc(C4CC5CCC4C5)cc3)cccc12 ; c1ccc2c(c1)sc1c(N(c3ccc(C4CC5CCC4C5)cc3)c3ccc(C4CC5CCC4C5)cc3)cccc12]

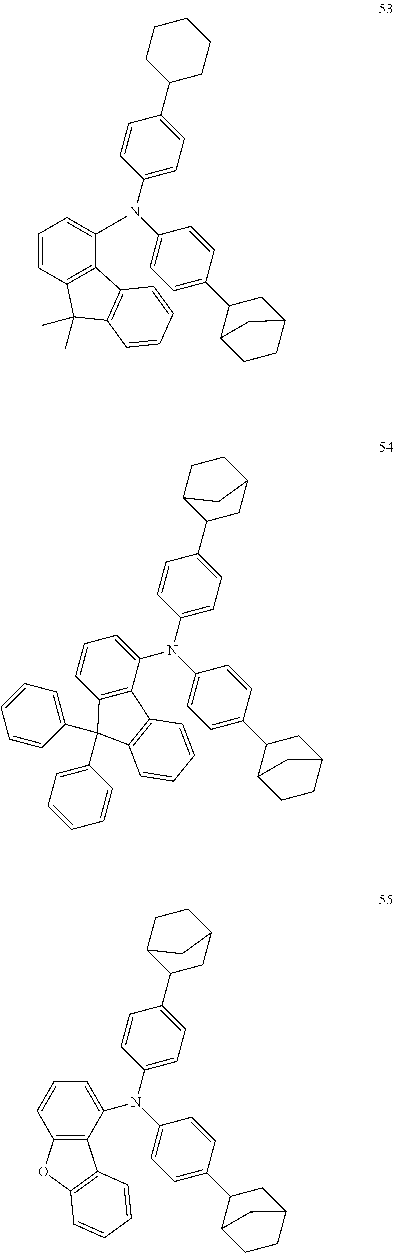 [SMILES: CC1(C)c2ccccc2-c2c(N(c3ccc(C4CCCCC4)cc3)c3ccc(C4CC5CCC4C5)cc3)cccc21 ; c1ccc(C2(c3ccccc3)c3ccccc3-c3c(N(c4ccc(C5CC6CCC5C6)cc4)c4ccc(C5CC6CCC5C6)cc4)cccc32)cc1 ; c1ccc2c(c1)oc1cccc(N(c3ccc(C4CC5CCC4C5)cc3)c3ccc(C4CC5CCC4C5)cc3)c12]

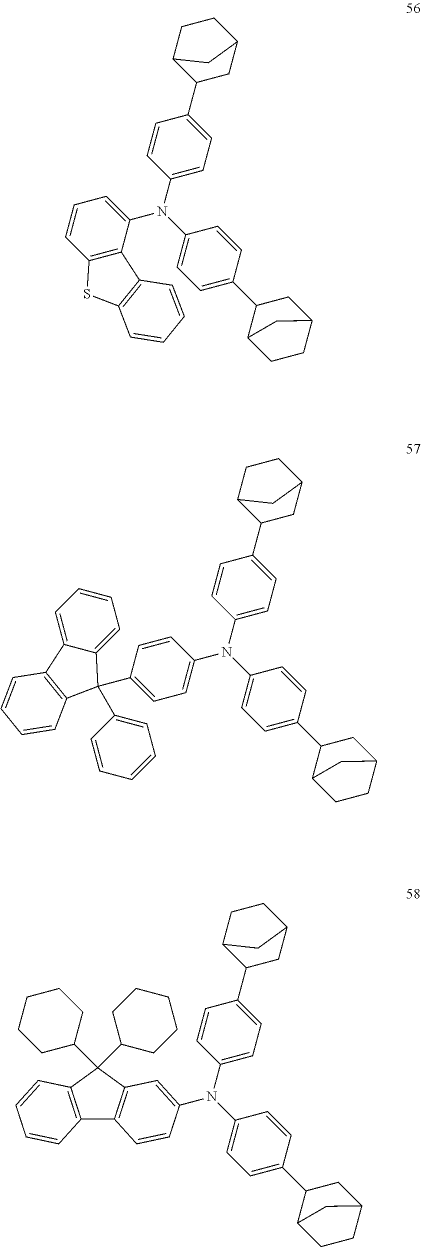 [SMILES: c1ccc2c(c1)sc1cccc(N(c3ccc(C4CC5CCC4C5)cc3)c3ccc(C4CC5CCC4C5)cc3)c12 ; c1ccc(C2(c3ccc(N(c4ccc(C5CC6CCC5C6)cc4)c4ccc(C5CC6CCC5C6)cc4)cc3)c3ccccc3-c3ccccc32)cc1 ; c1ccc2c(c1)-c1ccc(N(c3ccc(C4CC5CCC4C5)cc3)c3ccc(C4CC5CCC4C5)cc3)cc1C2(C1CCCCC1)C1CCCCC1]

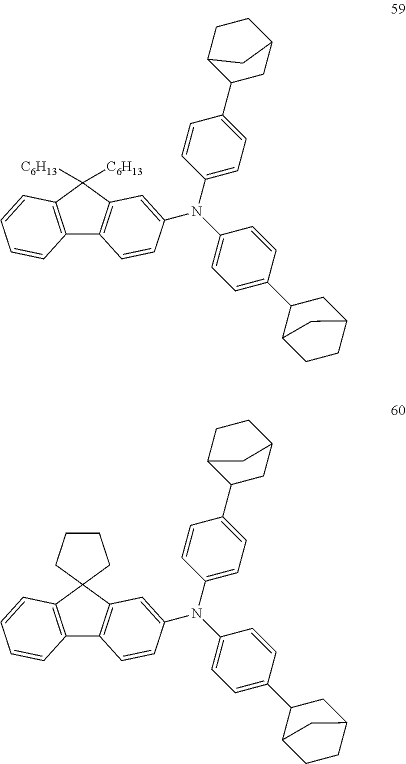

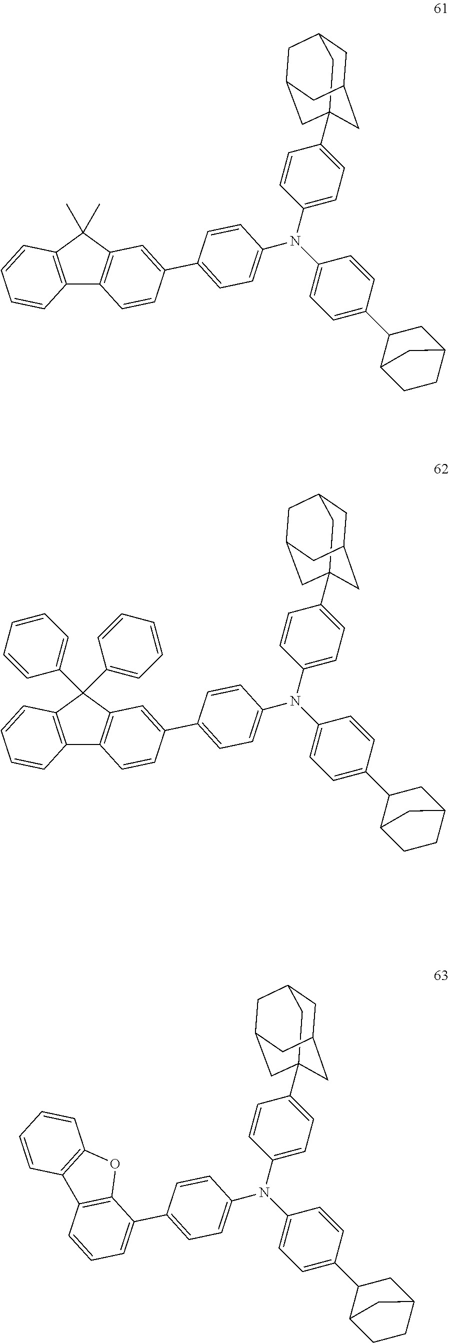 [SMILES: CC1(C)c2ccccc2-c2ccc(-c3ccc(N(c4ccc(C5CC6CCC5C6)cc4)c4ccc(C56CC7CC(CC(C7)C5)C6)cc4)cc3)cc21 ; c1ccc(C2(c3ccccc3)c3ccccc3-c3ccc(-c4ccc(N(c5ccc(C6CC7CCC6C7)cc5)c5ccc(C67CC8CC(CC(C8)C6)C7)cc5)cc4)cc32)cc1 ; c1ccc2c(c1)oc1c(-c3ccc(N(c4ccc(C5CC6CCC5C6)cc4)c4ccc(C56CC7CC(CC(C7)C5)C6)cc4)cc3)cccc12]

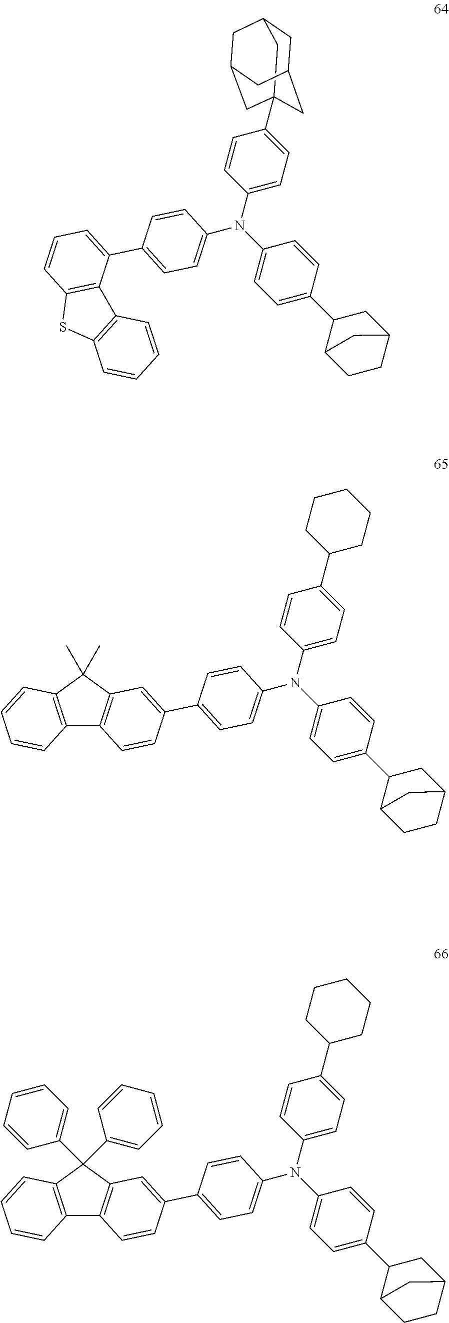 [SMILES: c1ccc2c(c1)sc1cccc(-c3ccc(N(c4ccc(C5CC6CCC5C6)cc4)c4ccc(C56CC7CC(CC(C7)C5)C6)cc4)cc3)c12 ; CC1(C)c2ccccc2-c2ccc(-c3ccc(N(c4ccc(C5CCCCC5)cc4)c4ccc(C5CC6CCC5C6)cc4)cc3)cc21 ; c1ccc(C2(c3ccccc3)c3ccccc3-c3ccc(-c4ccc(N(c5ccc(C6CCCCC6)cc5)c5ccc(C6CC7CCC6C7)cc5)cc4)cc32)cc1]

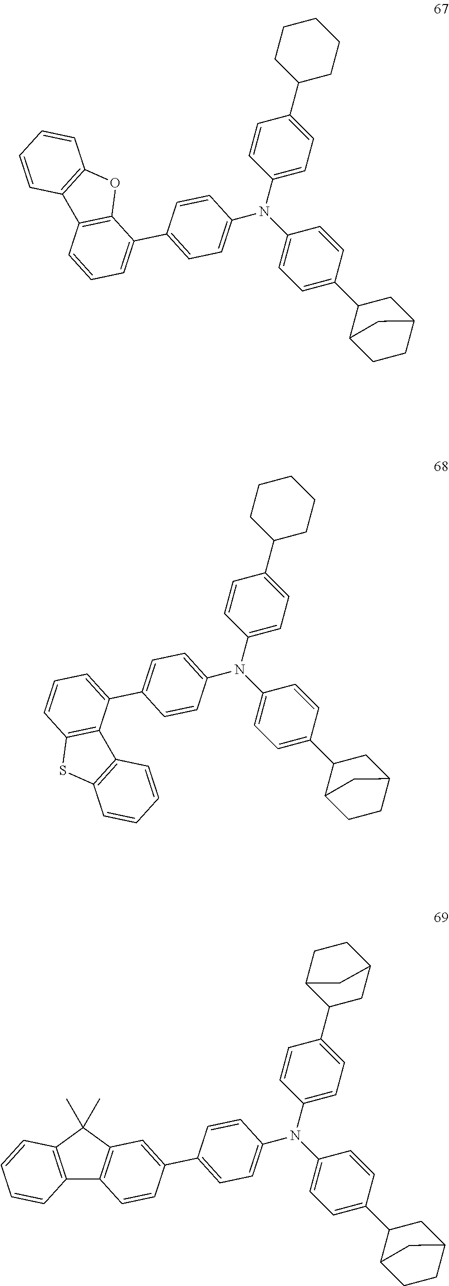 [SMILES: c1ccc2c(c1)oc1c(-c3ccc(N(c4ccc(C5CCCCC5)cc4)c4ccc(C5CC6CCC5C6)cc4)cc3)cccc12 ; c1ccc2c(c1)sc1cccc(-c3ccc(N(c4ccc(C5CCCCC5)cc4)c4ccc(C5CC6CCC5C6)cc4)cc3)c12 ; CC1(C)c2ccccc2-c2ccc(-c3ccc(N(c4ccc(C5CC6CCC5C6)cc4)c4ccc(C5CC6CCC5C6)cc4)cc3)cc21]

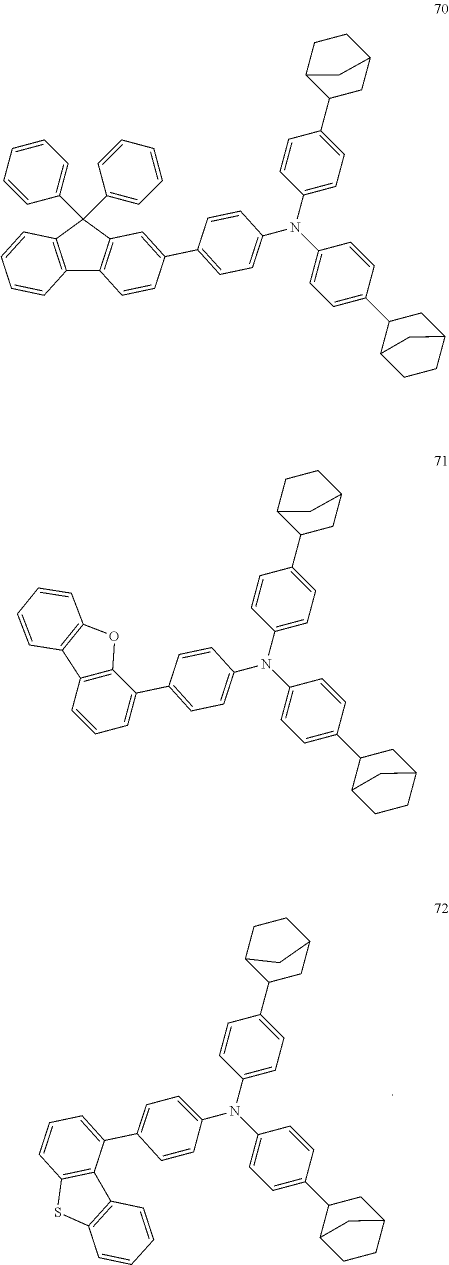 [SMILES: c1ccc(C2(c3ccccc3)c3ccccc3-c3ccc(-c4ccc(N(c5ccc(C6CC7CCC6C7)cc5)c5ccc(C6CC7CCC6C7)cc5)cc4)cc32)cc1 ; c1ccc2c(c1)oc1c(-c3ccc(N(c4ccc(C5CC6CCC5C6)cc4)c4ccc(C5CC6CCC5C6)cc4)cc3)cccc12 ; c1ccc2c(c1)sc1cccc(-c3ccc(N(c4ccc(C5CC6CCC5C6)cc4)c4ccc(C5CC6CCC5C6)cc4)cc3)c12]

18. A light emitting element comprising:
a first electrode;
a hole transport region on the first electrode;
an emission layer on the hole transport region;
an electron transport region on the emission layer; and
a second electrode on the electron transport region,
wherein the hole transport region comprises a first hole transport layer adjacent to the first electrode, the first hole transport layer comprising a first amine compound represented by Formula 1 and having a refractive index of about 1.4 to about 1.75, and
the first hole transport layer has a conductivity of about 6.0×10⁻⁵ cm/(V·sec) to about 10.0×10⁻⁴ cm/(V·sec): 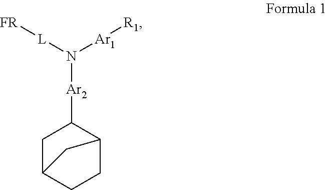
wherein, in Formula 1,
R₁ is a substituted or unsubstituted cycloalkyl group having 6 to 12 ring-forming carbon atoms,
Ar₁ and Ar₂ are each independently a substituted or unsubstituted arylene group having 6 to 30 ring-forming carbon atoms, or a substituted or unsubstituted heteroarylene group having 2 to 30 ring-forming carbon atoms,
L is a direct linkage, a substituted or unsubstituted arylene group having 6 to 30 ring-forming carbon atoms, or a substituted or unsubstituted heteroarylene group having 2 to 30 ring-forming carbon atoms, and
FR is represented by Formula 2-1 or Formula 2-2: 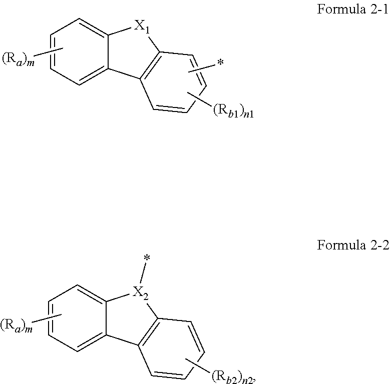
and
wherein, in Formula 2-1 and Formula 2-2,
X₁ is CR_{c}R_{d}, NRₑ, O, or S,
X₂ is CR_{f} or N,
Rₐ, R_{b1}, R_{b2}, and R_{c} to R_{f} are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
m is an integer of 0 to 4,
n1 is an integer of 0 to 3,
n2 is an integer of 0 to 4, and
in Formula 2-1 and Formula 2-2, “-*” means a position linked to L in Formula 1.

19. The light emitting element of claim 18, wherein the hole transport region further comprises a second hole transport layer between the first hole transport layer and the emission layer, the second hole transport layer having a refractive index larger than that of the first hole transport layer and comprising a compound represented by Formula H-1: 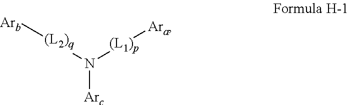
and
wherein, in Formula H-1,
Arₐ and Ar_{b} are each independently a substituted or unsubstituted aryl group having 6 to 30 ring-forming carbon atoms, or a substituted or unsubstituted heteroaryl group having 2 to 30 ring-forming carbon atoms,
Ar_{c} is a substituted or unsubstituted aryl group having 6 to 30 ring-forming carbon atoms,
L₁ and L₂ are each independently a direct linkage, a substituted or unsubstituted arylene group having 6 to 30 ring-forming carbon atoms, or a substituted or unsubstituted heteroarylene group having 2 to 30 ring-forming carbon atoms, and
p and q are each independently an integer of 0 to 10.

20. A display device comprising a plurality of light emitting elements, wherein each of the light emitting elements comprises:
a first electrode;
a hole transport region on the first electrode;
an emission layer on the hole transport region;
an electron transport region on the emission layer; and
a second electrode on the electron transport region,
wherein the hole transport region comprises:
a first hole transport layer adjacent to the first electrode and comprising a first amine compound represented by Formula 1, and
a second hole transport layer between the first hole transport layer and the emission layer, and having a refractive index larger than that of the first hole transport layer, and
the first hole transport layer has a conductivity of about 6.0×10⁻⁵ cm/(V·sec) to about 10.0×10⁻⁴ cm/(V·sec): 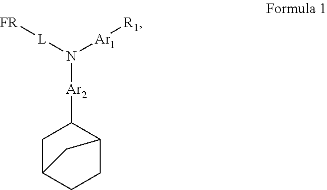
wherein, in Formula 1,
R₁ is a substituted or unsubstituted cycloalkyl group having 6 to 12 ring-forming carbon atoms,
Ar₁ and Ar₂ are each independently a substituted or unsubstituted arylene group having 6 to 30 ring-forming carbon atoms, or a substituted or unsubstituted heteroarylene group having 2 to 30 ring-forming carbon atoms,
L is a direct linkage, a substituted or unsubstituted arylene group having 6 to 30 ring-forming carbon atoms, or a substituted or unsubstituted heteroarylene group having 2 to 30 ring-forming carbon atoms, and
FR is represented by Formula 2-1 or Formula 2-2: 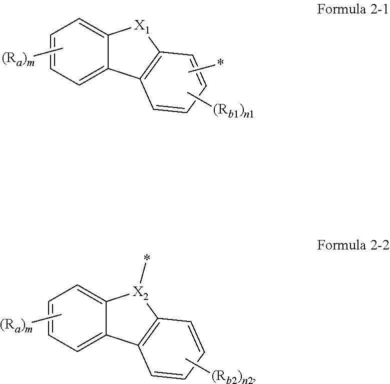
and
wherein, in Formula 2-1 and Formula 2-2,
X₁ is CR_{c}R_{d}, NRₑ, O, or S,
X₂ is CR_{f} or N,
Rₐ, R_{b1}, R_{b2}, and R_{c} to R_{f} are each independently a hydrogen atom, a deuterium atom, a halogen atom, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
m is an integer of 0 to 4,
n1 is an integer of 0 to 3,
n2 is an integer of 0 to 4, and
in Formula 2-1 and Formula 2-2, “-*” means a position linked to L in Formula 1.

21. The display device of claim 20, wherein the first hole transport layer has a refractive index of about 1.4 to about 1.75, and
the second hole transport layer has a refractive index of about 1.8 to about 2.0.

22. The display device of claim 20, wherein the plurality of light emitting elements comprises:
a first light emitting element comprising a first emission layer that is configured to emit light having a first wavelength;
a second light emitting element comprising a second emission layer that is configured to emit light having a second wavelength different from the first wavelength, the second emission layer being apart from the first emission layer in a plan view and
a third light emitting element comprising a third emission layer that is configured to emit light having a third wavelength different from the first wavelength and the second wavelength, the third emission layer being apart from the first emission layer and the second emission layer in a plan view.

23. The display device of claim 22, wherein the first wavelength is longer than the second wavelength,
the second wavelength is longer than the third wavelength, and
the display device further comprises:
a first resonance auxiliary layer between the first emission layer and the hole transport region;
a second resonance auxiliary layer between the second emission layer and the hole transport region, and having a thickness smaller than that of the first resonance auxiliary layer; and
a third resonance auxiliary layer between the third emission layer and the hole transport region, and having a thickness smaller than that of the second resonance auxiliary layer.

24. The display device of claim 23, wherein the first electrode is a reflective electrode, and the second electrode is a transflective electrode or a transmissive electrode.
